(19) United States
(12) Patent Application Publication
(10) Pub. No.: US 2010/0163298 A1
(43) Pub. Date: Jul. 1, 2010

(54) Electromagnetically-countered power grid systems and methods

(76) Inventor: Youngtack Shim, Port Moody (CA)

Correspondence Address: Youngtack Shim, 155 Aspenwood Drive, Port Moody, BC, V3H 5A5, CA

(21) Appl. No.: 12/318,540

(22) Filed: Dec. 31, 2008

(51) Int. Cl. H05K 9/00

(52) U.S. Cl. 174/350

(57) ABSTRACT

The present invention generally relates to an electromagnetically-countered power grid system with multiple wave sources and at least one counter unit, where each wave source irradiates harmful electromagnetic waves, while the counter unit emits counter electromagnetic waves and counters the harmful waves therewith. More particularly, the present invention relates to such electromagnetically-countered power grid systems and to various mechanisms for countering the harmful waves with the counter units, e.g., by matching configurations of the wave sources with those of such counter units and/or by matching wavefronts of the harmful waves with those of such counter waves. In addition, the present invention relates to such electromagnetically-countered power grid systems with multiple power transmission lines each operating as the counter unit of the rest of the transmission lines. The present invention relates to various methods of countering the harmful waves by the counter waves by the above mechanisms and further relates to various processes for providing power grid systems and their counter units.

### CROSS-REFERENCES TO RELATED APPLICATIONS

The present application claims an earlier filing date of the U.S. Utility Patent Application which is entitled “Generic electromagnetically-countered systems and methods,” which was filed on Aug. 28, 2006, and which bears the Ser. No. 11/510,667, an entire portion of which is incorporated herein by reference. The present application also claims an earlier invention date of the Disclosure Document which is entitled the same, which was deposited in the U.S. Patent and Trademark Office (the “Office”) on Jan. 3, 2007 under the Disclosure Document Deposit Program (the “DDDP”) of the Office, and which bears the Ser. No. 610,803 an entire portion of which is incorporated herein by reference.

### FIELD OF THE INVENTION

The present invention generally relates to an electromagnetically-countered power grid system with multiple wave sources and at least one counter unit, where each wave source irradiates harmful electromagnetic waves, while the counter unit emits counter electromagnetic waves and counters the harmful waves therewith. More particularly, the present invention relates to such electromagnetically-countered power grid systems and to various mechanisms for countering the harmful waves with the counter units, e.g., by matching configurations of the wave sources with those of such counter units and/or by matching wavefronts of the harmful waves with those of such counter waves. In addition, the present invention relates to such electromagnetically-countered power grid systems with multiple power transmission lines each operating as the counter unit of the rest of the transmission lines. The present invention relates to various methods of countering the harmful waves by the counter waves by the above mechanisms and further relates to various processes for providing power grid systems and their counter units.

### BACKGROUND OF THE INVENTION

It is now well established in the scientific community that electromagnetic waves with varying frequencies irradiated by various devices may be hazardous to human health. In some cases, such electromagnetic waves in mega- and giga-hertz range may be the main culprit, whereas the 60-hertz electromagnetic waves may be the main health concern in other cases. It cannot be too emphasized that it is very difficult to shield against magnetic waves of the 60-hertz electromagnetic waves which have wavelengths amounting to thousands of kilometers and that such 60-hertz magnetic waves are omnipresent in any corner of the current civilization.

However, intensity of such electromagnetic waves typically decreases inversely proportional to a square of a distance from a source of such waves to a target. Accordingly, potentially adverse effects from such electromagnetic waves may be minimized by maintaining a safe distance from such a source. Some electrical devices, however, carry electric currents with enormous amplitudes, while keeping a safe therefrom may not be feasible, where a typical example of such conventional electrical devices is various power transmission lines intended to transmit electrical power generated by power plants to individual customers therethrough. As a matter of fact, there has been concerns of several decades about power transmission lines and health and many studies have revealed that people living near the power transmission lines and people working in electrical occupations have developed more cancers than those who are not. Debates as to potential health hazards from the power transmission lines are well documented in an essay entitled “Power Lines and Cancer FAQs” which is provided by Prof. John Moulder at the Medical College of Wisconsin in Milwaukee, Wis., and available in the website http://www.mcw.edu/gcrc/cop/powerlines-cancer-faq/toc.html. Despite the ongoing controversy, all power transmission lines have failed to provide remedies to such potential hazards.

Therefore, there is an urgent need for various counter units capable of being incorporated into a conventional power transmission line and converting such a line to an electromagnetically-countered power transmission system while minimizing the harmful electromagnetic waves irradiated therefrom. There also is a need to provide a feasible solution to counter the harmful waves irradiated by various waves sources of the power transmission lines which have different shapes and/or sizes and carry electric currents of different amplitudes and/or phases. There further is a need to provide a feasible solution for countering the harmful waves which are irradiated from such wave sources and defining wavefronts of various characteristics by matching such harmful wavefronts.

### SUMMARY OF THE INVENTION

The present invention generally relates to an. electromagnetically-countered power grid system which includes multiple wave sources such as multiple power transmission lines irradiating therefrom harmful electromagnetic waves but provided in various self-countering dispositions in each of which at least substantial portions of such harmful waves cancel each other. Therefore, such power lines preferably extend in various dispositions in which the power lines are spaced away from each other by similar distances, spaced around a center of a circle by similar angles on a plane defined normal to the lines, and the like. More particularly, the present invention relates to various electromagnetically-countered power grid system including at least three waves sources such as, e.g., three three-phase power transmission lines provided in various self-countering dispositions in each of which the harmful waves irradiated from one of such lines are at least substantially canceled by such waves irradiated from the rest of such lines. Accordingly, such power lines are preferably provided in an equilateral disposition in a plane which is defined perpendicular to such lines. The present invention also relates to various retainers which are disposed along such power lines and couple therewith for maintaining the self-countering dispositions. Alternatively, the present invention relates to an electromagnetically-countered power grid system which includes multiple wave sources such as multiple power lines and which also includes at least one counter unit for emitting counter electromagnetic waves in order to counter the harmful waves by the counter waves, e.g., by canceling at least a portion of the harmful waves with the counter waves in a target space, suppressing such harmful waves from propagating toward the target space with the counter waves, and the like. More particularly, the present invention relates to various counter units for the electromagnetically-countered power grid systems and also to various mechanisms for countering the harmful waves irradiated from various base units of the wave sources with the counter units. Accordingly, the counter unit may be shaped, sized, and/or arranged for matching its configuration with that of at least one of the base units of the wave sources, thereby emitting such counter waves which automatically match wave characteristics of the harmful waves. In the alternative, the counter unit may be shaped, sized, and/or disposed in an arrangement which is defined along one or more wavefronts of such harmful waves, thereby emitting such counter waves automatically matching wave characteristics of the harmful waves. The present invention also relates to various countering modes in which a single counter unit may counter a single base unit or all (or at least two but not all) of multiple base units, in which multiple counter units may counter a single base unit, a greater number of multiple base units, a less number of multiple base units, and so on. At least one of the wave sources such as the transmission line may serve as the counter unit, while the rest of the wave sources such as the rest of the power lines may serve as the base units. Alternatively, at least one of the wave sources such as the transmission line may serve as the base unit, while the rest of the wave sources such as the rest of such power lines may serve as the counter units. The present invention relates to various electric and/or magnetic shields which may be used either alone or in conjunction with at least one of the counter units to minimize irradiation of the harmful waves by at least one of the base units.

The present invention also relates to various methods of countering the harmful waves which are irradiated by an electromagnetically-countered power grid system by providing its wave sources (i.e., its transmission lines) and base units thereof (i.e., their conductive elongated wires) in the self-countering dispositions and canceling each other at least substantial portions of such harmful waves. To this end, this invention relates to various methods of spacing such power transmission lines away from each other by similar distances, spacing such lines around a center of a circle by similar angles on a plane defined perpendicular to such lines, and the like. More particularly, this invention relates to various methods of countering the harmful waves irradiated from at least three transmission lines of a three-phase electromagnetically-countered power grid system by providing such transmission lines in the self-countering dispositions and canceling at least substantial portions of the harmful waves each other. To this end, the present invention relates to various methods of disposing such power lines in the equilateral triangular dispositions defined on a plane normal to such lines and then maintaining the dispositions in the target space. In the alternative, the present invention relates to various methods of countering the harmful waves irradiated from multiple base units of the electromagnetically-countered power grid system with the counter waves by source and/or wave matchings. More particularly, the present invention relates to various methods of providing the counter unit as an analog of at least one of the base units and emitting the counter waves matching such harmful waves, various methods of approximating at least one of the base units by the simpler counter unit for the countering, and various methods of approximating at least one of the base units by multiple simpler counter units. The present invention relates to various methods of disposing the counter unit along the wavefronts of the harmful waves and emitting the counter waves matching the wavefronts of such harmful waves, and various methods of disposing multiple counter units along the wavefronts of such harmful waves and emitting by the counter units the counter waves matching the wavefronts. The present invention also relates to various methods of manipulating the wavefronts of the counter waves by disposing such a counter unit closer to or farther from the target space with respect to at least one of such base units, various methods of controlling radii of curvature of the wavefronts of the counter waves by including one or multiple counter units emitting such counter waves of the same or opposite phase angles, and various methods of manipulating such wavefronts of the counter waves by disposing one or multiple counter units defining the shape similar to or different from that of at least one of the base units. The present invention also relates to various methods of countering the harmful waves irradiated from a single or multiple base units with the counter waves emitted by a single or multiple counter units. Accordingly, this invention also relates to various methods of emitting the counter waves by a single counter unit in order to counter the harmful waves irradiated by one or more base units, various methods of emitting the counter waves by two or more counter units in order to counter the harmful waves irradiated by a single or multiple base units. The present invention relates to various methods of minimizing irradiation of such harmful waves by incorporating the electric shields, by incorporating the magnetic shields, by incorporating one or both of such shields in conjunction with the above counter units, and the like.

The present invention relates to various processes for providing various electromagnetically-countered power grid systems capable of countering the harmful waves irradiated from their multiple base units each other in various self-countering mechanisms. More particularly, the present invention relates to various processes for disposing the transmission lines of a multiphase electromagnetically-countered power grid system in the self-countering dispositions. Alternatively, the present invention relates to various processes for providing various counter units for the EMC power grid system and various EMC power grid system incorporating therein one or multiple counter units. More particularly, the present invention relates to various processes for providing such counter units capable of emitting the counter waves defining the wavefronts similar to (or different from) shapes of the counter units, various processes for providing the counter units as such analogs of at least one of such base units, various processes for forming the counter units emitting the counter waves of the similar or opposite phase angles, various processes for providing the counter units emitting the counter waves with the wavefronts shaped similar to such harmful waves, and various processes for disposing the counter units in a preset arrangement and emitting therefrom the counter waves of the wavefronts similar to such an arrangement. The present invention also relates to various processes for assigning a single counter unit for countering the harmful waves irradiated by a single base unit for the local countering or for countering the harmful waves irradiated by multiple base units for the global countering, various processes for assigning multiple counter units for countering the harmful waves irradiated by a single base unit for the global countering, and to counter the harmful waves irradiated by multiple base units for the local and/or global countering based upon numbers of the counter and base units. The present invention also relates to various processes for employing at least one of the base units as the counter units for the rest of such base units or, in the alternative, for incorporating additional counter units for countering the harmful waves irradiated from the base units. The present invention further relates to various processes for incorporating such electric and/or magnetic shields for minimizing the irradiation of the harmful waves and various processes for minimizing the irradiation of such harmful waves by employing such shields and/or the above counter units.

Accordingly, a primary objective of the present invention is to provide an electromagnetically-countered power grid system (which will be abbreviated as an “EMC power grid system,” as an “EMC system,” or simply as a “system” hereinafter) capable of minimizing the harmful waves irradiated from multiple base units of multiple wave sources of the EMC system by countering such harmful waves in various self-countering mechanisms. Accordingly, a related objective of this invention is to assign at least one of such base units as a counter unit and to utilize the harmful waves irradiated therefrom as the counter waves capable of countering the harmful waves irradiated by the rest of such base units. Another related objective of this invention is to assign at least one transmission line of the system as a counter unit and to utilize the harmful waves irradiated therefrom as the counter waves for countering the harmful waves irradiated by the rest of the transmission lines. Another objective of this invention is to counter the harmful waves with the counter waves by, e.g., canceling such harmful waves with the counter waves in a target space, suppressing such harmful waves with the counter waves from propagating toward the target space, and the like. In general, this target space is defined between at least one but preferably multiple (or all) base units and an user of the system. In addition, such self-countering mechanisms can be applied to any conventional multiphase power grids such as the most popular three-phase power grids and other less popular multiphase power grids such as dual-phase power grids, four-phase power grids, five-phase power grids, six-phase power grids, and the like. It is appreciated in these conventional multiphase power grids that their power transmission lines carry electrical energies which have amplitudes identical (or at least similar) to each other and which define phase angles spaced apart from each other by a preset angle obtained by dividing 360° by a number of the transmission lines.

Another objective of the present invention is to provide an EMC power grid system capable of minimizing the harmful waves irradiated by its multiple wave sources such as its power transmission lines by countering such harmful waves each other in the self-countering mechanisms. Accordingly, a related objective of this invention is to adjust configurations (e.g., shapes, sizes, and arrangements) of such transmission lines to accomplish the self-countering mechanisms between such power lines. Another related objective of this invention is to manipulate dispositions (e.g., alignments, orientations, distances, and angles, and the like) of the power transmission lines to accomplish the self-countering mechanisms therebetween.

Another objective of the present invention is to formulate various self-countering mechanisms each guaranteeing the harmful waves irradiated by multiple base units (i.e., power transmission lines) of the system to counter each other and, therefore, to be reduced below preset amplitudes at least in the target space. Accordingly, a related objective of this invention is to develop such self-countering mechanisms by identifying individual base units, assessing propagation patterns of the harmful waves irradiated therefrom, and formulating configurations and/or dispositions of such base units in order to embody the self-countering mechanisms. Another related objective of this invention is to develop the self-countering mechanisms by constructing at least one equivalent base unit (or simply an “equivalent unit” hereinafter) functionally equivalent to at least two base units, assessing propagation patterns of the harmful waves irradiated from the equivalent base unit and those from the rest of such base units, and formulating configurations and/or dispositions of all of the base units for those mechanisms. It is appreciated that constructing the equivalent unit greatly simplifies formulation of such self-countering mechanisms while yielding the same results. It is also appreciated that the equivalent unit may also be constructed regardless of a number of transmission lines, their configurations and/or dispositions, and the like. Another related objective of this invention is to develop such self-countering mechanisms by constructing a hypothetical plane perpendicular to the transmission lines and varying angles between the lines on the plane, varying distances between the lines on the plane, and the like. Another related objective of this invention is to develop the self-countering mechanisms capable of reducing average amplitudes of the harmful waves in the target space and/or reducing peak amplitudes of such harmful waves in such a space. Another related objective of this invention is to develop such self-countering mechanisms based upon a configuration and/or a disposition of the target space with respect to such base units. Another related objective of this invention is to develop such self-countering mechanisms based upon amplitudes of electric voltages and/or current flowing in the base units.

Another objective of the present invention is to develop various criteria for the self-countering mechanisms so that the harmful waves irradiated from such transmission lines of the EMC power grid system are reduced according to such criteria. Accordingly, a related objective of this invention is to describe extents of the self-countering based on temporal and/or spatial averages of absolute bases of such harmful waves (e.g., in terms of total Gausses, Gausses per unit area, Gausses per unit time, and the like) or based on relative bases (e.g., in terms of ratios of such absolute bases or percentages thereof) of the harmful waves. Another related objective of this invention is to describe the temporally and/or spatially averaged extents of the self-countering with respect to (or based upon) the voltages and/or currents flowing through the transmission lines. Another related objective of this invention is to describe such temporally and/or spatially averaged extents of the self-countering with respect to (or based upon) the configuration and/or disposition of the target space, e.g., in terms of such temporally and/or spatially averaged absolute and/or relative bases of the harmful waves across an entire target space, the temporally and/or spatially averaged absolute and/or relative bases of the harmful waves per unit target space, and the like. Another related objective of this invention is to describe extents of the self-countering based upon temporal and/or spatial peaks of the absolute and/or relative bases of the harmful waves, where such bases of the peaks of the harmful waves may also be based on the entire target space or per unit target space.

Another objective of the present invention is to provide a three-phase EMC power grid system with a single set of three three-phase power transmission lines irradiating the harmful waves each of which counter each other in the target space, e.g., by canceling each other in the target space and/or suppressing each other from propagating toward the target space through the above self-countering mechanisms and based upon the above criteria. Accordingly, a related objective of this invention is to provide three power transmission lines of the three-phase EMC power grid system in an isosceles but preferably equilateral triangular disposition when viewed on a plane defined perpendicular to the lines. Another related objective of this invention is to provide three power transmission lines of the system in a disposition in which such lines are spaced away from each other by identical (or at least similar) angles about a center of a circle defined by such lines on the plane. Another related objective of this invention is to provide three power lines of the system in a disposition in which such lines are spaced away from each other by identical (or at least similar) distances when viewed on the plane. Another related objective of this invention is to provide three power lines of the system in a disposition where such lines are spaced away from the target space by at least a preset angle, a preset distance, and the like. Another related objective of this invention is to provide three power transmission lines of the system in a disposition in which such power lines are provided close to each other while maintaining a preset minimum distance (or angle) or, alternatively, spaced away from each other but within or not beyond a preset maximum distance (or angle). Another related objective of this invention is to provide three power transmission lines in any of such dispositions which are also determined by disposition or configuration of the target space, amplitudes of electric voltages applied across such power lines, amplitudes of electric currents flowing in such power lines, and the like.

Another objective of the present invention is to provide a three-phase EMC power grid system with multiple sets of three three-phase power transmission lines, in which the power lines of each set irradiate the harmful waves each of which counters each other in the target space, e.g., by canceling each other in the target space and/or suppressing each other from propagating toward such a target space through the above self-countering mechanisms and based upon the above criteria. Therefore, a related objective of this invention is to arrange the transmission lines of each set in any of the above self-countering dispositions while arranging multiple sets of power lines in any arbitrary dispositions in which each set of lines is spaced away from the rest of such sets of lines. Another related objective of this invention is to arrange such transmission lines of each set in any of the above self-countering dispositions while overlapping at least a portion of at least one of the sets with at least a portion of at least another of such sets. Another related objective of this invention is to group the power lines into multiple sets according to the phase angles of the electrical energy supplied thereto, to construct an equivalent line in each set, and to arrange such multiple equivalent lines of different phase angles of multiple sets based on the above self-countering mechanisms and using the above criteria. Another related objective of this invention is to apply various provisions of the present objective while including different number of transmission lines in at least one of the sets, while including the transmission lines arranged in different dispositions in at least two of such sets, while including the lines transmitting the electrical energies with different amplitudes in at least one of such sets, and the like. Another related objective of this invention is to apply various provisions of this objective to various multiphase power grid systems with different number of power transmission lines such as, e.g., two transmission lines each transmitting the electrical energies of phase angles apart by about 180°, four transmission lines each carrying the energies of phase angles apart by about 90°, five transmission lines each carrying the energies of phase angles apart by about 72°, six transmission lines each carrying the energies of phase angles apart by about 60°, and the like, where such an EMC system may include a single set or multiple sets of such transmission lines, may include a mixture of such sets of transmission lines, and the like.

Another objective of the present invention is to provide a three-phase EMC power grid system with multiple sets of three three-phase power transmission lines, in which the power lines of each set share at least one common line and irradiate the harmful waves each of which counters each other in such a target space, e.g., by canceling each other in the target space and/or suppressing each other from propagating toward the target space through the above self-countering mechanisms and based upon the above criteria. Therefore, a related objective of this invention is to arrange the transmission lines of each set in any of the above self-countering dispositions while arranging multiple sets of lines in any arbitrary dispositions where each set of lines is spaced away from the rest of the sets of lines with respect to the common transmission line. Another related objective of this invention is to arrange such transmission lines of each set in any of the above self-countering dispositions while overlapping at least a portion of at least one of the sets with at least a portion of at least another of such sets with respect to the common line. Another related objective of this invention is to group the power lines into multiple sets according to the phase angles of the electrical energy supplied thereinto, to construct an equivalent line in each set, and to arrange such multiple equivalent lines with different phase angles of multiple sets based on such self-countering mechanisms and according to such criteria while forming the common line from the equivalent transmission lines. Another related objective of this invention is to apply various provisions of this objective while including different number of lines in at least one of the sets, while incorporating the lines arranged in different dispositions in at least two of such sets, while including the lines transmitting the electrical energies of different amplitudes in at least one of the sets, and the like. Another related objective of this invention is to apply various provisions of this objective to various multiphase power grid systems including different number of power transmission lines as described in the previous objective, where the EMC system may include a single set or multiple sets of the transmission lines, may include a mixture of such sets of transmission lines, and the like.

Another objective of the present invention is to provide the EMC power grid system including at least one set of power transmission lines as well as at least one unbalanced power transmission line and capable of minimizing the harmful waves irradiated from all of such transmission lines. Therefore, a related objective of this invention is to arrange such transmission lines of the set in any of the above self-countering dispositions while leaving out the unbalanced line as far away from the target space. Another related objective of this invention is to arrange the transmission lines of multiple sets of such lines in any of the above self-countering dispositions in which each set of lines is spaced away from the rest of such sets of lines or in which at least a portion of at least one set overlaps at least another portion of at least another set. Another related objective of this invention is to dispose the set of lines in any of the above self-countering dispositions while incorporating at least one counter unit capable of countering the harmful waves irradiated from the unbalanced line.

Another objective of the present invention is to formulate various self-countering mechanisms each guaranteeing the harmful waves irradiated by multiple base units (i.e., power transmission lines) of the system to counter each other so that peak amplitudes of the harmful waves are reduced below preset value at least in the target space. Therefore, a related objective of this invention is to develop the self-countering mechanisms by identifying individual base units of such a system, assessing peak planes of the harmful waves irradiated therefrom, and formulating configurations and/or dispositions of such base units in order to embody such self-countering mechanisms. Another related objective of this invention is to develop such self-countering mechanisms in which the peak planes of the harmful waves are disposed as far away from the target space and, therefore, temporal and/or spatial peak amplitudes of the harmful waves are maintained below the preset values, where the peak amplitudes may be instantaneous amplitudes, temporally averaged amplitudes, spatially averaged value, and the like. Another related objective of this invention is to develop the self-countering mechanisms in which the peak planes of the harmful waves irradiated from multiple sets of transmission lines are disposed as far away from each other and/or from the target space such that the temporal and/or spatial peak amplitudes of the harmful waves are maintained below the preset values, where the peak amplitudes may be instantaneous amplitudes, temporally averaged amplitudes, and/or spatially averaged value. It is appreciated that various criteria described hereinabove may also be used to quantify the extents of reduction of the harmful waves in the target space.

Another objective of the present invention is to provide an EMC power grid system capable of maintaining the peak amplitudes of the harmful waves below the preset values in the target space by countering such harmful waves each other in the self-countering mechanisms. Accordingly, a related objective of this invention is to adjust configurations (e.g., shapes, sizes, and arrangements) of such power lines to keep the peak amplitudes of such harmful waves below the preset values by the self-countering mechanisms between the lines. Another related objective of this invention is to manipulate dispositions (e.g., alignments, orientations, distances, and angles, and the like) of such power lines to accomplish the self-countering mechanisms therebetween.

Another objective of the present invention is to provide an EMC power grid system capable of countering such harmful waves irradiated from multiple base units of the system (i.e., its transmission lines) by the self-countering mechanisms while maintaining the self-countering dispositions among the transmission lines at least in such a target space. Therefore, a related objective of this invention is to use retainers capable of keeping such transmission lines in the self-countering dispositions. Another related objective of this invention is to provide such retainers which are shaped and sized to maintain fixed dispositions among the transmission lines or, in the alternative, which may change their shapes and/or sizes to allow variable dispositions among the lines. Another related objective of this invention is to provide such retainers which are fixedly incorporated into preset locations along the system or, in the alternative, which are movably incorporated into the system so that such retainers may movably couple to multiple locations of the system. Another related objective of this invention is to provide the retainers which may retain therein not only the base units (i.e., transmission lines) but also other parts of the system such as, e.g., neutral lines, lines transmitting different voltages and/or currents, and the like. Another related objective of this invention is to form such retainers from preexisting parts of the system, where examples of the preexisting parts may include, but not limited to, neutral lines, holders, mechanical or electrical couplers, electrical bypasses, and the like.

It is appreciated in the above objectives related to the self-countering mechanisms that at least one of the base units of the EMC power grid system (i.e., at least one of the power transmission lines thereof) is to be deemed as a counter unit so that the harmful waves irradiated from such a base unit are also to be deemed as counter electromagnetic waves capable of countering a sum of the harmful waves irradiated by the rest of the base units due to amplitudes of the counter waves identical (or at least similar) to those of the sum of the harmful waves and due to phase angles of the counter waves at least partially opposite to those of the sum of the harmful waves. It is also appreciated in the above objectives related to the self-countering mechanisms that two or more of the base units of the system (i.e., two or more power transmission lines thereof) are similarly deemed as the counter units so that a sum of the harmful waves irradiated from such base units are to be deemed as the counter waves capable of countering the harmful waves irradiated by the last base unit due to amplitudes of the sum of the harmful waves identical (or at least similar) to those of the harmful waves irradiated by the last base unit and due to phase angles of the sum of the counter waves at least partially opposite to those of the harmful waves from the last base unit. It is further appreciated in the above objectives related to the self-countering mechanisms that at least two of the base units are to be deemed as the counter units which emit the counter waves capable of countering the harmful waves irradiated from at least two of the rest of such base units due to similar reasons.

Another objective of the present invention is to form an EMC power grid system incorporating at least one but preferably multiple counter units thereinto and emitting the counter waves capable of countering the harmful waves irradiated from multiple base units of the EMC system in various active countering mechanisms. Accordingly, a related objective of this invention is to provide an EMC power grid system capable of countering the harmful waves by canceling at least a portion of such harmful waves with the counter waves in the target space, suppressing the harmful waves with the counter waves from propagating to the target space, and the like. Another related objective of this invention is to counter the harmful waves by such counter waves not all around at least one base unit of the EMC system but only in the target space (or area) defined on only one side of the system. Another related objective of this invention is to arrange the counter waves to define the phase angles at least partially opposite to those of the harmful waves so that such counter waves may cancel and/or suppress the harmful waves when propagated to the target space. Another related objective of this invention is to arrange the counter waves to define the phase angles at least partially similar to those of the harmful waves so that the counter waves counter such harmful waves when propagated to the target space from opposite sides of the base units. Another related objective of this invention is to emit the counter waves from the same and/or opposite side of at least one of the base units with respect to the target space while manipulating their phase angles such that the counter waves emitted by different counter units counter the harmful waves in the target space.

Another objective of the present invention is to provide the EMC power grid system including at least one counter unit for emitting the counter waves. Therefore, a related objective of this invention is to match at least one feature or configuration (e.g., each meaning a shape, a size, an arrangement, and the like) of the counter unit with the feature or configuration of at least one of the base units such that the counter waves emitted by the counter unit match the harmful waves irradiated from the base unit. Another related objective of this invention is to match the shape of a single counter unit with that of a single base unit so that the counter waves emitted by the counter unit match the harmful waves irradiated by at least one of the base units. Another related objective of this invention is to match the shape of a single counter unit with an arrangement of multiple base units such that the counter waves emitted by the counter unit match a sum of the harmful waves irradiated by such base units. Another related objective of this invention is to dispose multiple counter units in an arrangement matching the shape of a single base unit so that a sum of the counter waves emitted by the counter units match the harmful waves irradiated by at least one of the base units. Another related objective of this invention is to arrange multiple counter units in an arrangement matching an arrangement of multiple base units such that a sum of the counter waves emitted by multiple counter units matches a sum of the harmful waves irradiated by multiple base units. Another related objective of this invention is to provide such counter units while using the least amount of electrically conductive, semiconductive, and/or insulative materials, while minimizing a total volume or a size of the counter units, minimizing a total mass of such counter units, and the like. Another related objective of this invention is to emit the counter waves by such counter units while using the least electrical energy, drawing the least amount of electric current and/or voltage from at least one of the base units or other parts of the EMC system, and the like.

Another objective of the present invention is to provide an EMC Power grid system including at least one counter unit in a disposition (e.g., an orientation, alignment, and/or distance) matching that of at least one of the base units. Accordingly, a related objective of this invention is to orient or align the counter unit along a propagation direction of the harmful waves, along a direction in which the electric current flows in at least one of the base units, along a direction in which the electric voltage is applied thereacross, along a direction of the long and/or short axes of such counter and/or base units for the matching, and the like. Another related objective of this invention is to form multiple counter units all of which are oriented or aligned along the same direction and/or axis, at least two of which are oriented or aligned along different directions and/or axes, all of which are oriented in different directions and/or axes for the above matching, and the like. Another related objective of this invention is to axially align the counter unit with respect to at least one of the base units such that the counter waves emitted by the counter unit axially align with the harmful waves irradiated by at least one of the base units for the matching, where such an arrangement will be referred to as an “axial alignment” hereinafter. Another related objective of this invention is to axially misalign such a counter unit with (or from) at least one of the base units and to dispose the counter unit in a preset arrangement for such matching, where such an arrangement is to be referred to as an “off-axis alignment” hereinafter. Another related objective of this invention is to provide multiple counter units each (or at least two) of which may be disposed in the axial or off-axis alignment relative to a single base unit for the matching. Another related objective of this invention is to form a single or multiple counter units disposed in the axial or off-axis alignment with respect to multiple base units for such matching. Another related objective of this invention is to form multiple counter units all of which are disposed in the axial or off-axis alignment with respect to all of multiple base units or, in the alternative, at least two of which are disposed in different or mixed alignments relative to at least two of multiple base units for such matching. Another related objective of this invention is to dispose the counter unit in a preset distance from at least one of the base units such that at least some wavefronts of the counter waves emitted by the counter unit match at least some wavefronts of the harmful waves irradiated by at least one of the base units for the matching. Another related objective of this invention is to dispose a single counter unit in preset distances from each (or at least two) of multiple base units for such matching. Yet another related objective of this invention is to also dispose multiple counter units in preset distances from a single base unit or, in the alternative, at preset distances from each (or at least two) of multiple base units for the matching.

Another objective of the present invention is to provide an EMC power grid system including at least one counter unit emitting the counter waves capable of matching at least a portion of the harmful waves and, therefore, countering the harmful waves. Therefore, a related objective of this invention is to provide the counter unit for emitting such counter waves defining multiple wavefronts matching at least one of the wavefronts of the harmful waves in the target space. Another related objective of this invention is to dispose the counter unit along at least a portion of at least one of such wavefronts of the harmful waves to emit the counter waves capable of matching such a portion of the wavefront of such harmful waves. Another related objective of this invention is to dispose multiple counter units along at least a portion of at least one of the wavefronts of the harmful waves and to emit the counter waves a sum of which matches the portion of the wavefront of the harmful waves. Another related objective of this invention is to dispose such a counter unit across at least two different wavefronts of the harmful waves but to emit the counter waves capable of matching at least a portion of at least one another of the wavefronts of the harmful waves. Another related objective of this invention is to form multiple counter units at least two of which are disposed across at least two of the wavefronts of the harmful waves but which also emit the counter waves capable of matching such a portion of the wavefront of the harmful waves. Another related objective of this invention is to shape and size the counter unit and to emit the counter waves defining radii of curvature matching those of at least a portion of the harmful waves. Another related objective of this invention is to dispose the counter unit in a preset position and/or in a preset distance from at least one of the base units in which the counter waves have the radii of curvature matching those of at least a portion of the harmful waves. Another related objective of this invention is to shape and size multiple counter units for emitting such counter waves a sum of which has the radii of curvature matching the harmful waves irradiated from a single or multiple base units. Another related objective of this invention is to form the counter unit in a shape of one or multiple wires, strips, sheets, tubes, coils thereof, spirals thereof, meshes thereof, mixtures thereof, combinations thereof, and/or arrays thereof, and then to emit such counter waves capable of matching at least a portion of at least one wavefront of such harmful waves irradiated by at least one of such base units. Another related objective of this invention is to provide the counter unit in a solid shape without forming any openings or holes thereacross for the matching. Another related objective of this invention is to provide the counter units as at least one array defining multiple holes or openings thereacross for such matching.

Another objective of the present invention is to provide an EMC power grid system including at least one counter unit emitting the counter waves and locally countering the harmful waves irradiated by at least one of the base units. Therefore, a related objective of this invention is to provide a single counter unit for locally countering such harmful waves irradiated by single base unit with the counter waves. Another related objective of this invention is to provide multiple counter units each of which locally counters the harmful waves irradiated by only one of the same (or less) number of base units with the counter waves emitted from each of multiple counter units. Another related objective of this invention is to provide a single or multiple counter units defining a feature (or configuration) similar (or identical) to that of a single or multiple base units for the local countering. Another related objective of this invention is to provide a single or multiple counter units for emitting the counter waves defining the wavefronts matching at least one of the wavefronts of the harmful waves irradiated by a single base unit or multiple base units for the local countering. Another related objective of this invention is to form multiple counter units at least one of which defines a feature (or configuration) similar (or identical) to that of at least one of the base units, while at least another of which defines the wavefronts matching at least one of the wavefronts of the harmful waves irradiated from at least one of the base units for the local countering.

Another objective of the present invention is to provide an EMC power grid system including at least one counter unit emitting the counter waves to globally counter the harmful waves irradiated by at least one of the base units. Therefore, a related objective of this invention is to form one or multiple counter units each emitting the counter waves for globally matching such harmful waves irradiated by only one or a less number of base units. Another related objective of this invention is to form a single counter unit for globally countering a sum of such harmful waves irradiated by multiple base units with such counter waves. Another related objective of this invention is to form multiple counter units each globally countering the harmful waves irradiated by at least two base units with such counter waves emitted by each of multiple counter units. Another related objective of this invention is to form a single or multiple counter units defining a feature (or configuration) which is similar (or identical) to that of at least two or a greater number of base units for the global countering. Another related objective of this invention is to provide a single or multiple counter units emitting the counter waves of the wavefronts matching at least one of the wavefronts of the harmful waves irradiated from at least two or a greater number of base units for the global countering. Another related objective of this invention is to provide multiple counter units at least one of which defines the feature (or configuration) similar (or identical) to those of at least two base units and at least another of which defines the wavefronts matching at least one wavefront of the harmful waves irradiated by at least two of other base units for such local countering.

Another objective of the present invention is to provide an EMC power grid system including at least one counter unit and to supply the electrical energy thereto to counter such harmful waves with the counter waves emitted therefrom. Therefore, a related objective of this invention is to provide the counter unit with the electric current and/or voltage supplied to at least one of the base units. Another related objective of this invention is to provide the counter unit with at least a portion but not an entire portion of the current or voltage supplied to at least one of such base units. Another related objective of this invention is to provide the counter unit with only a portion of the current or voltage of which the amplitudes and/or direction may also be modified before being supplied thereto. In all of the examples, the current or voltage supplied to the counter unit may be automatically synchronized with the current or voltage supplied to at least one of such base units, may define the phase angles in phase with the phase angles of the energy supplied to the base units, may have the phase angles lagging behind the phase angles of the energy supplied to the base units by preset angles, and the like. Another related objective of this invention is to supply the counter unit with electric current or voltage which is not the current or voltage supplied to at least one of the base units but which is at least partially synchronized with the current or voltage supplied to such a base unit. Another related objective of this invention is to manipulate the amplitudes and/or directions of the current or voltage based on configurations and/or dispositions of the counter unit. Another related objective of this invention is to electrically couple the counter unit to at least one of the base units in a parallel mode, a series mode, a hybrid mode, and the like. Another related objective of this invention is to supply the current and/or voltage to the base and counter units in various sequences such as, e.g., first to at least one of the base units and then to the counter unit, first to the counter unit and then to at least one the base units, first to only one of multiple counter units and to the rest of such counter units or base unit thereafter, first to one of multiple base units and then to the rest of such base units or counter unit thereafter, simultaneously to the base and counter units, and the like.

Another objective of the present invention is to provide an EMC power grid system including at least one electric shield and/or at least one magnetic shield capable of minimizing the irradiation of the harmful waves toward the target space. Accordingly, a related objective of this invention is to include the electric and/or magnetic shields in the EMC system capable of countering such harmful waves by various self-countering mechanisms. Another related objective of this invention is to incorporate such electric and/or magnetic shields into the EMC system which in turn includes at least one of the counter units. Another related objective of this invention is to include such electric and/or magnetic shields for shielding the harmful waves irradiated from the unbalanced base units of the system.

Another objective of the present invention is to provide an EMC power grid system capable of minimizing the irradiation of the harmful waves therefrom and/or countering the harmful waves while also modifying least parts of conventional power grids. Therefore, a related objective of this invention is to leave various transmission towers and/or power poles of the grids intact while only rearranging or redisposing the transmission lines in such self-countering dispositions. Another related objective of this invention is to similarly leave the transmission towers and/or power poles of the grids intact while incorporating one or more of such counter units into the transmission lines of such a system. Another related objective of this invention is to rearrange or redispose the transmission lines with the retainers without modifying other parts of the prior art power grids.

It is to be understood in all of the foregoing objectives that various counter units are preferably arranged to not adversely affect intended functions of the EMC power grid systems. For example, the transmission lines of the EMC power grid system are preferably provided in any of the aforementioned self-countering dispositions while minimizing undesirable interference among the transmission lines. In another example, the counter units of the EMC power grid system are preferably provided to counter the harmful waves irradiated from their wave generating base units without adversely affecting their energy-carrying functions. It is appreciated in all of the above objectives that such counter units emit the counter waves defining the phase angles at least partially opposite to those of the harmful waves for proper countering in their normal dispositions but that such counter units emit the counter waves defining the phase angles at least partially similar to those of such harmful waves when disposed on an opposite side of at least one of the base unit with respect to the target space or when the system includes multiple counter units and it is desirable to modify the radii of curvature of the wavefronts of the counter waves. It is also appreciated that various electric and/or magnetic shields disclosed in the co-pending Applications may also be incorporated into any of the above EMC systems either alone or in combination with the above counter units to maximally counter the harmful waves.

The basic principle of various EMC power grid systems of the present invention is to minimize the harmful waves irradiated by their base units in the target space by countering the harmful waves with the counter waves therein, e.g., by canceling the harmful waves with the counter waves in the target space, suppressing the harmful waves with the counter waves from propagating toward the target space, and the like. In one example, all of at least a substantial number of base units of the EMC power grid systems operate in the self-countering mechanisms such that each base unit operates as the counter unit of the rest of the base units, that at least one base unit operates as the counter unit of at least another base unit, and the like. In another example, at least one counter unit is incorporated into the EMC system and emits the counter waves capable of countering the harmful waves irradiated by at least one of the base units. The bottom in en either example is that such counter waves counter the harmful waves in the target space and that such counter and/or base units define configurations and are provided in dispositions allowing such countering. Accordingly, the counter units of the EMC system emit the counter waves of the wavefronts similar (or identical) to those of the harmful waves but defining the phase angles at least partially opposite to those of the harmful waves. Therefore, by propagating the counter waves toward the target space, the counter waves may effectively counter the harmful waves in the target space by, e.g., canceling at least a portion of the harmful waves with the counter waves therein, suppressing the harmful waves with the counter waves from propagating theretoward, and the like. To this end, such counter units preferably emit the counter waves defining the wavefronts matching those of the harmful waves by various mechanisms. In one example, such counter units are shaped similar (or identical) to at least one of the base units of the waves sources, or arranged similar (or identical) to the base unit and, accordingly, emit the counter waves capable of countering the harmful waves in the target space. In another example, the counter units are disposed along or across a single or multiple wavefronts of the harmful waves, emit the counter waves similar (or identical) to the harmful waves and, therefore, counter the harmful waves in the target space. In these examples, the counter units emit the counter waves forming the wavefronts similar (or identical) to the shapes of the counter units themselves, and those counter waves define the phase angles at least partially opposite to the phase angles of the harmful waves. In another example, such counter units are shaped differently from at least one of the base units, but rather disposed in an arrangement in which the counter waves emitted thereby match the harmful waves in the target space. In another example, the counter units are disposed across different wavefronts of such harmful waves but emit the counter waves similar (or identical) to the harmful waves, thereby, countering the harmful waves in the target space. In these last two examples, the counter units may be arranged to emit the counter waves defining such wavefronts which may or may not be similar (or identical) to the shapes of the counter units themselves, while the counter waves have the phase angles which are at least partially opposite to those of the harmful waves.

The above basic principle for various generic counter units of the EMC power grid system of the present invention may be implemented to various prior art power grids for minimizing irradiation of the harmful waves therefrom. For example, the counter units may be provided as (or implemented to any base units as) electrically conductive wires, coils, sheets, and the like or, alternatively, may also be provided as (or implemented into such base units as) any electrically semiconductive or insulative wires, coils, sheets, and the like, to minimize irradiation of the harmful waves through countering such harmful waves with the counter waves, where the counter units may also be made of and/or include at least one electrically conductive, insulative or semiconductive material. Such counter units may be implemented to any of the base units of the shapes which may be formed by including one or multiple wires, coils, and/or sheets, by modifying such shapes of one or multiple wires, coils, and/or sheets, where a few examples of the modified shapes may include a solenoid and toroid each of which may be formed by modifying the shape of such a coil. Therefore, such counter units may be provided as (or implemented to) various parts of the EMC power grid system such as, e.g., their transmission lines, neutral lines, support lines, couplers, bypasses, transformers, transmission towers, power poles, and the like. Therefore, any prior art power grids including the electromagnetically-countered transmission lines may be converted into the EMC power grid systems of this invention.

It is appreciated that various counter units of such EMC power grid systems of this invention may be implemented to any conventional power grids including at least one set of power transmission lines (i.e., a set of the wave sources) each including at least one elongated electric conductor (i.e., a base unit) and, therefore, may irradiate the harmful waves including electric waves (to be abbreviated as “EWs” hereinafter) and magnetic waves (to be abbreviated as “MWs” hereinafter) of frequencies ranging about 50 to 60 Hz and/or other EWs and MWs with higher frequencies. As described above and will be disclosed hereinafter, any of such base units may be arranged to function as the counter unit(s) for the rest of the base units or, in the alternative, an additional counter unit of a set of multiple counter units may be provided in order to counter the harmful waves irradiated by such base units of the wave sources.

Various system, method, and/or process aspects of the EMC power grid systems and various embodiments thereof are now enumerated. It is appreciated, however, that following system, method, and/or process aspects of the present invention may be embodied in many other different forms and, accordingly, should not be limited to such aspects and/or their embodiments which are to be set forth herein. Rather, various exemplary aspects and their embodiments described hereinafter are provided such that this disclosure will be thorough and complete, and fully convey the scope of this invention to one of ordinary skill in the relevant art.

In one aspect of the present invention, an electromagnetically-countered power grid system is arranged to include therein a preset number of multiple wave sources each having therein at least one base unit and to be also capable of countering harmful electromagnetic waves irradiated by the base units by canceling such harmful waves in a target space and/or suppressing the harmful waves from propagating toward the target space, where such base units are arranged to include only portions of the wave sources which are responsible for irradiating the harmful waves and/or affecting paths of propagation of the harmful waves therethrough, where the target space is defined between the base units and an user of the system, and where the system includes at least one power station capable of generating electrical energies each of which defines preset amplitudes and each of which defines phase angles differing from phase angles of at least one of the rest of the energies by about a preset angle obtained by dividing 360° by the preset number.

In one exemplary embodiment of this aspect of the invention, a system may include the preset number of power transmission lines, where each of the transmission lines is arranged to carry each of the energies therealong while serving as one of the wave source with the base unit and irradiating the harmful waves thereby, and to extend at least substantially parallel to the rest of such lines in the target space. Such transmission lines will be referred to as the “first transmission lines” hereinafter. In one example, such transmission lines are arranged to be in a disposition at least partially opposite to each other when viewed upon a hypothetical plane defined perpendicular thereto and to maintain the disposition in the target space, whereby the harmful waves which are irradiated by each of the lines are arranged to define phase angles at least substantially opposite to those of a sum of such harmful waves irradiated by the rest of the lines, to define amplitudes at least substantially similar to those of the sum of the harmful waves and, accordingly, to counter the harmful waves irradiated from the rest of the lines in the target space, where such a disposition is to be referred to as the “first disposition” hereinafter. In another example, the transmission lines are arranged to be in a disposition where the lines are spaced away from each other by at least substantially similar distances when viewed upon a hypothetical plane formed normal to all of the lines and to maintain the disposition in the target space, whereby the harmful waves irradiated from each of the lines are arranged to define phase angles at least substantially opposite to those of a sum of the harmful waves irradiated by the rest of the lines, to define amplitudes which are at least substantially similar to those of the sum of the harmful waves and, therefore, to counter the harmful waves irradiated from the rest of the lines in the target space, where this disposition is to be referred to as the “second disposition” hereinafter. In another example, the transmission lines are arranged to be in a disposition where the lines are spaced from each other by at least substantially similar angles about a center of a circle which is defined by all of the lines on a hypothetical plane formed normal to the all of the lines and to maintain such a disposition in the target space, whereby the harmful waves irradiated by each of the lines are arranged to have phase angles at least substantially opposite to those of a sum of the harmful waves irradiated from the rest of such lines, to define amplitudes at least substantially similar to those of the sum of the harmful waves and, therefore, to counter the harmful waves irradiated by the rest of the lines in the target space, where this disposition is to be referred to as the “third disposition” hereinafter. In another example, the lines are arranged to be in another disposition at least partially opposite to each other when viewed upon a hypothetical plane defined perpendicular to all of the lines, to define multiple peak planes of the harmful waves, and to be in an alignment capable of aligning the peak planes in the target space as far away therefrom, whereby the harmful waves irradiated by each of the lines are arranged to define phase angles at least substantially opposite to those of a sum of the harmful waves irradiated by the rest of the lines, to define amplitudes at least substantially similar to those of the sum of such harmful waves and, accordingly, to counter the harmful waves irradiated by the rest of the lines in the target space, where such a disposition is to be referred to as the “fourth disposition” hereinafter.

In another exemplary embodiment of this aspect of the invention, such a system may include at least one first substation, at least one second substation, at least one transmission tower, at least one power pole, and the first transmission lines. The first substation is arranged to be disposed between the power source and user of the system and to step up such electrical energies to higher amplitudes (to be referred to as the “standard first substation” hereinafter), whereas such a second substation is arranged to be disposed between the first substation and user of the system and to step down the energies to lower amplitudes (to be referred to as the “standard second substation” hereinafter). The transmission tower is arranged to be disposed between the first substation and second substation (to be referred to as the “standard transmission tower” hereinafter), while the power pole is arranged to be disposed between the second substation and user (to be referred to as the “standard power pole” hereinafter). The first transmission lines are further arranged to be mechanically supported by such a transmission tower and/or power pole, and may be in the first disposition, in the second disposition, in the third disposition or in the fourth disposition.

In another aspect of the present invention, another electromagnetically-countered power grid system is arranged to include therein at least three wave sources each including therein at least one base unit and to be also capable of countering harmful electromagnetic waves irradiated by the base units by canceling such harmful waves in a target space and/or suppressing the harmful waves from propagating to the target space, where the base units are arranged to include only those portions of the wave sources responsible for irradiating the harmful waves and/or affecting propagation paths of the harmful waves therealong, where the target space is formed between the base units and an user of the system, and where the system also includes at least one power station capable of generating electrical energies each having preset amplitudes and each also defining phase angles differing from phase angles of at least one of the rest of the energies by about 120°.

In one exemplary embodiment of this aspect of the invention, such a system may have at least three power transmission lines each of which is arranged to transmit therealong each of the energies while serving as one of the wave source including such a base unit and irradiating the harmful waves thereby, and to extend at least partially parallel to the rest of the lines in the target space, where these transmission lines will be referred to as the “second transmission lines” hereinafter. In one example, such lines are arranged to be in an equilateral triangular disposition when viewed upon a hypothetical plane defined normal to all of the lines and to maintain the disposition in the target space, whereby the harmful waves irradiated by each of the lines are arranged to have phase angles at least substantially opposite to those of a sum of the harmful waves irradiated by the rest of the lines, to have amplitudes at least substantially similar to those of the sum of the harmful waves and, accordingly, to counter the harmful waves irradiated from the rest of such lines in the target space, where this disposition will be referred to as the “fifth disposition” hereinafter. In another example, such lines may be in the second disposition. In another example, the transmission lines are in the third disposition. In another example, such lines are arranged to be in an equilateral triangular disposition when viewed upon a hypothetical plane defined perpendicular to all of the lines, to form multiple peak planes of the harmful waves, and to be in an alignment capable of aligning such peak planes in the target space as far away therefrom, whereby the harmful waves irradiated from each of the lines are arranged to define phase angles at least substantially opposite to those of a sum of the harmful waves irradiated by the rest of the lines, to have amplitudes at least substantially similar to those of the sum of the harmful waves and, thus, to counter the harmful waves irradiated by the rest of the transmission lines in the target space, where such a disposition is to be referred to as the “sixth disposition” hereinafter.

In another exemplary embodiment of this aspect of the invention, such a system may have the standard first substation, standard second substation, standard transmission tower, standard power pole, and the second transmission lines. The transmission lines may be arranged to be mechanically supported by the transmission tower and/or power pole, and may also be in the fifth disposition, in the second disposition, in the third disposition or in the sixth disposition.

In another aspect of the present invention, another electromagnetically-countered power grid system is arranged to include therein a preset number of multiple wave sources each having at least one base unit for irradiating harmful electromagnetic waves, to have therein at least one counter unit for emitting counter electromagnetic waves, and to be also capable of countering the harmful waves with the counter waves by canceling the harmful waves with such counter waves in a target space and/or suppressing the harmful waves with such counter waves from propagating toward the target space, where the base units are arranged to include only those portions of the wave sources which are responsible for irradiating the harmful waves and/or affecting paths of propagation of the harmful waves therealong, where the target space is defined between an user of the system and base units, and where the system also includes at least one power station for generating electrical energies each of which has preset amplitudes and each of which defines phase angles differing from phase angles of at least one of the rest of the electrical energies by about a preset angle obtained by dividing 360° by the preset number.

In one exemplary embodiment of this aspect of the invention, a system may include at least one transmission line and at least one counter unit. The transmission line is arranged to carry therealong one of the electrical energies while serving as one of such wave sources including the base unit and irradiating the harmful waves therefrom, and the counter unit is arranged to carry therealong another of the electrical energies while emitting such counter waves therefrom. A total number of the counter unit and transmission line corresponds to the preset number, the transmission line and counter unit are arranged to extend at least substantially parallel to each other in the target space, while the counter unit is arranged to define a configuration identical (or similar) to the base unit of the transmission line. Whereby, the counter waves are arranged to define phase angles at least partially opposite to those of the harmful waves irradiated by the base unit, to have wave characteristics at least partially similar to those of the harmful waves irradiated from the base unit due to the configuration and, accordingly, to counter the harmful waves irradiated by the base unit due to the phase angles in the target space, where such counter waves are to be referred to as the “first counter waves” hereinafter.

In another exemplary embodiment of this aspect of the invention, a system may include multiple transmission lines and at least one counter unit. Each of the transmission lines is arranged to transmit therealong each of the electrical energies while serving as one of the wave sources having the base unit and irradiating the harmful waves thereby, and the counter unit is arranged to transmit therealong another of the electrical energies while emitting such counter waves thereby, where a total number of the transmission lines and counter unit corresponds to the preset number. The transmission lines and counter unit are arranged to extend at least substantially parallel to each other in the target space, and the counter unit is also arranged to define a configuration identical (or similar) to that of at least one of the base units of the transmission lines. Whereby, such counter waves are arranged to define phase angles which are at least partially opposite to those of the harmful waves irradiated by at least one of the base units, to define wave characteristics at least partially similar to those of such harmful waves irradiated by such at least one of the base units due to the configuration and, therefore, to counter the harmful waves irradiated by such at least one of the base units due to the phase angles in the target space, where such counter waves are to be referred to as the “second counter waves” hereinafter.

In another exemplary embodiment of this aspect of the invention, a system may include at least one transmission line and multiple counter units. The transmission line is arranged to carry therealong one of the electrical energies while serving as one of such wave sources including the base unit and irradiating the harmful waves thereby, and each of such counter units is arranged to carry therealong another of the electrical energies while emitting the counter waves thereby, where a total number of the transmission line and counter units corresponds to the preset number. The transmission line and counter units are arranged to run at least substantially parallel to each other in the target space, while at least one of the counter units is arranged to define a configuration identical (or similar) to the base unit of the transmission line. Whereby the counter waves emitted by at least one of the counter units are arranged to have phase angles at least partially opposite to those of the harmful waves irradiated by the base unit, to define wave characteristics at least partially similar to those of the harmful waves irradiated from the base unit due to the configuration and, accordingly, to counter the harmful waves irradiated from the base unit due to the phase angles in the target space.

In another exemplary embodiment of this aspect of the invention, a system may include multiple transmission lines and counter units. Each of the transmission lines is arranged to transmit therealong each of the electrical energies while serving as one of the wave sources including the base unit and irradiating the harmful waves thereby and each of the counter units is arranged to transmit therealong another of the electrical energies while emitting such counter waves thereby, where a total number of such transmission lines and counter units corresponds to the preset number. Such transmission lines and counter units are arranged to run at least partially parallel to each other in the target space, and at least one of the counter units is arranged to have a configuration identical (or similar) to at least one of the base units of the transmission lines. Whereby, the counter waves emitted from at least one of the counter units are arranged to define phase angles at least partially opposite to those of such harmful waves irradiated from at least one of such base units, to define wave characteristics at least partially similar to those of the harmful waves which are irradiated by such at least one of the base units due to the configuration and, accordingly, to counter the harmful waves which are irradiated from such at least one of the base units due to the phase angles in the target space.

In another aspect of the present invention, another electromagnetically-countered power grid system is arranged to have at least one wave sources with at least one base unit irradiating harmful electromagnetic waves, to have at least one counter unit emitting counter electromagnetic waves, and to be capable of countering the harmful waves with the counter waves by suppressing such harmful waves with the counter waves from propagating toward a target space and/or canceling the harmful waves with the counter waves inside the target space, where the base units include only portions of the wave sources responsible for irradiating the harmful waves and/or affecting propagation paths of the harmful waves therealong, where the target space is defined between an user of the system and base unit, and where the system includes at least one power station of generating electrical energies each having preset amplitudes and each defining phase angles differing from phase angles of at least one of the rest of the electrical energies by 120°.

In one exemplary embodiment of this aspect of the invention, such a system may have a single transmission line and at least two counter units. The transmission line is arranged to carry therealong one of the electrical energies while serving as the wave source with the base unit and irradiating the harmful waves therefrom (to be referred to as the “third transmission lines” hereinafter), while each of the counter units is arranged to transmit therealong another of the electrical energies while emitting the counter waves therefrom. The transmission line and counter units are arranged to extend at least partially parallel to each other in the target space, while at least one of the counter units is arranged to define a configuration identical (or similar) to the base unit of the transmission line, thereby emitting the first counter waves.

In another exemplary embodiment of this aspect of the invention, such a system may have two transmission lines and a single counter unit. Each of the transmission lines is arranged to carry each of the electrical energies therealong while serving as one of the wave sources each including such a base unit and irradiating the harmful waves therefrom, while the counter unit is arranged to carry the last of the electrical energies therealong while emitting the counter waves thereby. The transmission lines and counter unit are arranged to extend at least partially parallel to each other in the target space and the counter unit is arranged to define a configuration identical (or similar) to that of at least one of the base units of the transmission lines, thereby emitting the second counter waves.

In another aspect of the present invention, another electromagnetically-countered power grid system is arranged to include a preset number of multiple wave sources each having therein at least one base unit and to be capable of countering harmful electromagnetic waves irradiated by the base units by canceling the harmful waves in a target space and/or suppressing the harmful waves from propagating toward the target space, where such base units are arranged to include only portions of the wave sources responsible for irradiating the harmful waves and/or affecting paths of propagation of the harmful waves therealong, where the target space is defined between such base units and an user of the system, and where the system includes at least one power station capable of generating electrical energies each having preset amplitudes and defining phase angles which differ from phase angles of at least one of the rest of the energies by about a preset angle obtained by dividing 360° by the preset number.

In one exemplary embodiment of this aspect of the invention, such a system may have the first transmission lines which are arranged to be in a preset disposition for countering the harmful waves. In one example, the system includes at least one retainer which is arranged to mechanically couple to the lines and to define a shape and size capable of maintaining the lines in the disposition in the target space. In another example, the system includes the preset number of the retainers each of which is arranged to mechanically couple with each of the lines and to maintain the each of the lines in a preset position with respect to others of the lines, whereby the retainers are arranged to maintain the lines in the disposition in the target space.

In another exemplary embodiment of this aspect of the invention, such a system may have the standard first substation, standard second substation, standard transmission tower, standard power pole, and the first transmission lines. In one example, the system further includes at least one retainer which is arranged to mechanically couple with the lines and to define a shape and size for maintaining the lines in the disposition along the lines extending between the transmission tower and power pole and/or extending along such lines between the power pole and user. In another example, the system include the preset number of the retainers each of which is arranged to mechanically couple to each of the lines and to maintain the each of the lines in a preset position with respect to others of the lines, whereby such retainers are arranged to maintain the lines in the disposition along the lines extending between the transmission tower and power pole and/or along the lines between the pole and user.

In another aspect of the present invention, another electromagnetically-countered power grid system is arranged to include a preset number of multiple wave sources each having therein at least one base unit and to be capable of countering harmful electromagnetic waves irradiated by the base units by canceling such harmful waves in a target space and/or suppressing the harmful waves from propagating toward the target space, where such base units are arranged to include only portions of the wave sources responsible for irradiating the harmful waves and/or affecting paths of propagation of the harmful waves therealong, where the target space is defined between at least one of the base units and an user of the system, where the system includes at least one power station for generating electrical energies each having preset amplitudes and defining phase angles differing from those of at least one of the rest of such energies by about a preset angle obtained by dividing 360° by the preset number, and where such harmful waves define at least one wavefront during propagation thereof.

In one exemplary embodiment of this aspect of the invention, such a system may have the third transmission lines and at least one counter units. In one example, such a system may include a single counter unit which is arranged to have a configuration matching that only one of the base units and to emit counter electromagnetic waves. In another example, such a system may include multiple counter units which are arranged to be in an arrangement matching a configuration of only one of such base units and to emit counter electromagnetic waves. Whereby, the counter waves in both examples are arranged to define phase angles at least partially opposite to those of such harmful waves, to at least partially match at least a portion of the wavefront of such harmful waves due to such a configuration, thereby countering the harmful waves in the target space.

In another exemplary embodiment of this aspect of the invention, a system may include the first transmission lines and at least one counter unit. In one example, the system includes a single counter unit which is arranged to define a configuration matching an arrangement of all (or at least two but not all) of the base units and to emit counter electromagnetic waves. In another example, the system has multiple counter units at least two (or all) of which are in an arrangement matching an arrangement of all (or at least two but not all) of such base units and emit counter electromagnetic waves. Whereby, the counter waves in both examples are arranged to define phase angles at least partially opposite to those of the harmful waves, to at least substantially match at least a portion of the wavefront of such harmful waves due to the arrangement, thereby countering the harmful waves in the target space.

In another exemplary embodiment of this aspect of the invention, a system may have the third transmission lines and at least one counter unit. In one example, the system includes a single counter unit which is arranged to define a preset shape, to be in a preset arrangement relative to at least one of such base units and to emit counter electromagnetic waves, where the shape and/or arrangement may further be arranged to match at least a portion of only one (or multiple portions of at least two) of the wavefronts. In another example, the system includes multiple counter units all (or at least two but not all) of which are arranged to define an overall preset shape, to be in a preset arrangement relative to at least one of the base units, and to emit counter electromagnetic waves, where the overall shape and/or arrangement may be arranged to match at least a portion of only one (or multiple portions of at least two) of the wavefronts. Whereby, the counter waves in both examples are arranged to define multiple wavefronts at least one of which is similar (or identical) to the portion of the wavefront of the harmful waves due to such a shape and/or arrangement, to define phase angles at least substantially opposite to those of such harmful waves and, accordingly, to counter the harmful waves due to such phase angles in the target space.

In another exemplary embodiment of this aspect of the invention, a system may include the first transmission lines and at least one counter unit. In one example, the system includes a single counter unit shaped, sized, and/or disposed for emitting counter electromagnetic waves, where such counter waves are arranged to match at least a portion of only one (or multiple portions of at least two) of the wavefronts of the harmful waves irradiated by only one (or at least two) of the base units. In another example, such a system includes multiple counter units all (or at least two but not all) of which may be disposed, shaped, and/or sized to emit counter electromagnetic waves, where a sum of such counter waves is arranged to match at least a portion of only one (or multiple portions of at least two) of such wavefronts of the harmful waves irradiated by only one (or at least two) of the base units. Whereby, the counter waves in both examples are arranged to define multiple wavefronts at least one of which is at least partially similar to (or identical to) such a portion of only one (or the portions of at least two) of the wavefronts of such harmful waves due to a disposition, a shape, and/or a size of the counter unit(s), to define phase angles at least partially opposite to those of the harmful waves and, therefore, to counter the harmful waves in the target space.

Embodiments of such system aspects of the present invention may include one or more of the following features, and configurational and/or operational variations and/or modifications of the above systems also fall within the scope of the present invention.

The power source may generate the energies each of which may define its peak and valley in an alternating mode while maintaining differences between the peak and valley as the amplitudes in a carrier frequency of about 50 Hz, 60 Hz, and the like. The power source may generate two energies which may have at least substantially identical amplitudes and phase angles differing from each other by about 180°, may generate three energies which may define at least substantially similar amplitudes and phase angles differing from each other by about 120°, may instead generate four energies which may have at least substantially identical amplitudes and phase angles differing from at least one of the rest thereof by about 90°, and the like. The portion of the distance may include only a portion near the target space, may include at least a substantial portion thereof, and the like.

Such electrical energy may be electric current and/or electric voltage. Such transmission lines may carry the electric voltage which may exceed 150,000 AC volts, which may be between 100,000 and 150,000 AC volts, which may be between 50,000 and 100,000 AC volts, which may be between 5,000 and 50,000 AC volts, which may be between 1,000 and 5,000 AC volts, which may be between 500 and 1,000 AC volts, which may be less than 500 AC volts, and the like. The system may include at least one ground line along with the transmission lines. The similar distances may differ from each other by no more than 1%, 2%, 3%, 5%, and the like or, alternatively, may differ from each other by no more than 1 cm, 3 cm, 5 cm, 10 cm, 15 cm, and the like. The similar distances may differ from each other by no more than 6%, 7%, 8%, 9%, and the like or, alternatively, may differ from each other by no more than 20 cm, 30 cm, 50 cm, and the like. The similar distances may differ from each other by no more than 10%, 15%, 20%, 25%, 30%, and the like or, alternatively, may differ from each other by no more than 20 cm, 30 cm, 0.5 m, 1 m, 1.5 m, 2 m, 3 m, 5 m, and so on. The similar distances may be determined based on the voltages of the energies transmitted along the lines, a number of the lines in the system, a presence or absence of the ground line in the system, and the like. The similar angles may differ from each other by no more than 10, 30, 50, 70, 90, and so on or, alternatively, may differ from each other by no more than 1%, 2%, 3%, 5%, and the like. The similar angles may differ from each other by no more than 10°, 12°, 15°, and the like or, in the alternative, may differ from each other by no more than 6%, 7%, 8%, 9%, and the like. The similar angles may also differ from each other by no more than 17°, 20°, 25°, 30°, and the like or, alternatively, may differ from each other by no more than 10%, 15%, 20%, 25%, 30%, and the like. The similar angles may also be determined based on the voltages of the energies transmitted along the lines, a number of the lines in the system, a presence or an absence of the ground line in the system, and the like.

The system may include a single set of the transmission lines each of which defines different phase angles and all of which are arranged to counter each other in the target space. Such a system may include multiple sets of such transmission lines, where each set of the lines may include a preset number of the lines and where the lines of one of the sets may counter each other in the target space but may not counter the lines of other sets. At least two of the sets of the lines may include different number of transmission lines. The lines of at least one of the sets may have the phase angles which are identical to those of at least one of the rest of the sets or, alternatively, the lines of at least one of the sets may define the phase angles different from those of at least one of the rest of the sets. The sets of the lines may be in any arbitrary disposition or, in the alternative, at least two of the sets of the lines may instead be in a preset disposition in which adjacent lines of different sets may be arranged to at least partially counter each other. At least two of the sets of the lines may be in at least partially similar or identical disposition or, in the alternative, may be in different dispositions. At least two of the sets of such lines may contain therein the same number of lines or, alternatively, may contain different numbers of the lines. At least two lines of different sets of the lines may carry the electrical energies of identical electric voltage or, alternatively, may transmit such energies of different electric voltages. At least two of the sets of the lines may include at least one common line which may be a part of the at least two of the sets. Such a common line may transmit the electric energy of the voltage different from the voltage transmitted by at least one another line of the set of the common line. A first of such sets of lines may carry the energy of higher voltage and a second of such sets of lines may transmit the energy of lower voltage, where the first set of such lines may be disposed farther away from the target space than the second set of such lines, where the second set of such lines may be disposed around the first set of such lines, and the like. The system may include multiple sets of lines, where at least one of such sets may serve as the counter unit of at least one another of the rest of the sets of such lines.

The counter unit may receive the electric energy and actively emit the counter waves or, in the alternative, may not receive the electric energy but rather passively emit the counter waves due to an electromagnetic induction caused by such magnetic flux flowing therein. The counter unit may include at least one electric conductor in which the electric current may flow, at least one electric conductor and/or insulator across which the electric voltage may be applied, and the like. The counter unit may counter the harmful waves by the local countering in which the counter unit may counter only one of the base units or, in the alternative, may counter the harmful waves in the global countering in which the counter unit may counter at least two of the base units.

The counter unit may be disposed side by side or stacked with at least one of such base units, may wind around at least one of such base units along a preset length, may concentrically enclose at least one of such base units, may be enclosed in at least one of the base units, may be axially aligned with at least one of the base units, and the like. The counter unit may be spaced from at least one of the base units at a preset distance, may mechanically, electrically, and/or magnetically couple with at least one of the base units, may form an unitary article with at least one of the base units, and the like. The counter unit may also be retained by at least one support and maintain its shape while emitting the harmful waves or, alternatively, may vary its shape while emitting the counter waves.

The configuration and/or disposition of the counter unit may be determined based on whether the counter unit is to match a configuration of at least one of the base units or to match at least one of the wavefronts of the harmful waves. The counter unit may define the shape identical to, similar to or different from that of at least one of the base units, that of the wave source, and the like. The counter unit may define a shape of the wire, strip, sheet, tube, coil, spiral, mesh, mixture of at least one of the shapes, combination thereof, array thereof, and the like. The array may have a bundle of at least two of such shapes, a braid thereof, a coil thereof, a mesh thereof, and the like. The shape of the counter unit may (or not) conform to that of at least one of the base units, that of the wave source, and so on. The counter unit may form the 1-D, 2-D, and/or 3-D analogs of at least one of such base units, of such wave sources, and the like. The counter unit may form only one of the analogs or at least two of the analogs. Multiple counter units may define only one of the analogs or at least two of the analogs. The analog may maintain a similarity with at least one of the base units, of the source, and so on. At least two of the analogs as a whole may also maintain a similarity with at least one of the base units, of the wave source, and the like. At least two portions of the counter unit and/or at least two counter units may also define the same shape of different sizes, different shapes of similar or different sizes, and the like. The counter unit may define at least substantially uniform shape and/or size along at least a substantial portion thereof along its longitudinal axis, may define the shape and/or size varying along the portion and/or axis, and so on. The size of the counter unit may (or not) conform to that of at least one of the base units, to the wave source, and the like. The counter units may also be disposed in the arrangement identical to, similar to or different from the shape of at least one of the base units, shape of the wave source, arrangement of at least two of multiple base units, arrangement of multiple wave sources, and so on. At least two of the counter units may be disposed in an arrangement conforming (or not) to the shape of at least one of the base units, the shape of the wave source, the arrangement of at least two of the base units, the arrangement of the wave sources, and so on. The counter units may be disposed in a symmetric (or asymmetric) arrangement with respect to each other, at least one of the base units, the wave source, and the like.

The counter unit may be aligned with (or misaligned from) the direction of propagation of such harmful waves, the direction of the electric energy (i.e., current or voltage), the longitudinal axis of at least one of the base units, the short axis of at least one of the base units, and/or one of the axes of the wave source. All of (or only some of, one of, none of) the counter units may be aligned with (or misaligned from) at least one of the directions and/or axes. The counter unit and at least one of such base units may be disposed at an identical (or similar) distance from the target space. Such counter units may be in an angular arrangement defined around the longitudinal axis of at least one of the base units, the wave source, and the like. The counter unit may be movably or stationarily disposed closer to (or farther away from) the target space than at least one of the base units, the wave source, and the like. The counter unit and at least one of the base units may be disposed on the same side of the target space or, alternatively, the counter unit may be disposed on opposite sides of the target space. The counter unit may conform to only one of the base units or at least two of the base units or, in the alternative, at least two of the counter units may conform to only one of the base units or at least two of the base units. The counter unit and at least one of the base units may be made of and/or include at least one common material, may be made of and/or include at least one same materials, or may not include any common material. Such a counter unit may be arranged to emit the counter waves with a least amount of material, while consuming a least amount of the current and/or voltage, and the like. At least one of the base units may include at least one wire and/or strip which may be made of and/or include at least one conductive, semiconductive, and/or insulative material. At least one of such base units may also include at least one winding of a wire and/or a strip which may also be made of and/or include at least one conductive, semiconductive, and/or insulative material.

Such harmful waves may include carrier-frequency waves having frequencies less than from about 50 Hz to 60 Hz, extremely low-frequency waves of frequencies less than about 300 Hz, other waves having frequencies less than about 1 kHz, 5 kHz, 10 kHz, 20 kHz, 50 kHz, 100 kHz, 500 kHz, 1 MHz, 10 MHz, 50 MHz, 100 MHz, 500 MHz, 1 GHz, 5 GHz, 10 GHz, 50 GHz, 100 GHz, 500 GHz, 1 THz, and the like, where such counter waves may define frequencies similar to (or greater than, less than) those of the harmful waves. The harmful waves may also include ultra low-frequency waves which have frequencies less than about 3 kHz, very low-frequency waves of frequencies less than about 30 kHz, low-frequency waves having frequencies less than about 300 kHz, and the like. The counter waves may also have frequencies similar to (or greater than, less than) those of the harmful waves. The target space may be defined on one side of all (or at least some but not all) of such transmission lines or about a preset angle around all (or at least some but not all) of the lines. The countering may include the canceling and/or the suppressing.

The retainer may be fixedly coupled to the substation, transmission tower, and/or power pole or, in the alternative, may be movably coupled thereto in order to move therealong. The retainer may define the shape and size which are not adjustable, may define the shape and/or size which may be adjustable, and the like. Such transmission lines, base units, and/or counter units may define at least substantially identical, similar or different resonance frequencies or, alternatively, may define identical, similar or different resonance frequencies. At least a portion of a single transmission line, base unit, and/or counter unit and/or at least one of the transmission lines, base units, and/or counter units may have resonance frequencies different from those of the rest thereof.

The system may include at least one of such magnetic shields described hereinabove or in the co-pending Applications. The magnetic shields may be disposed in, on, over, around, and/or through the transmission lines, base units, and/or counter units. The magnetic shields may also define shapes at least partially conforming to the shapes of such transmission lines, base units, and/or counter units or, in the alternative, may define shapes which may be at least partially different from shapes of such transmission lines, base units, and/or counter units. The magnetic shield may define at least one path member with a relative magnetic permeability greater than 1,000, 10,000, 100,000 or 1,000,000. The magnetic shield may include at least one magnet member defining at least one South pole thereon. The magnetic shield may include at least one shunt member which may be directly or indirectly coupling to the magnet member. Such a shunt member may have the relative magnetic permeability which may be greater than 1,000, 10,000, 100,000 or 1,000,000. The magnetic shield described hereinabove and/or disclosed in the co-pending Applications may also be incorporated into any portions of the power grid system described hereinabove. The system may include at least one of the electric shields described hereinabove and/or in the co-pending Applications. The electric shields described hereinabove and/or disclosed in the co-pending Applications may also be incorporated into any portions of the power grid systems described hereinabove. The magnetic and/or electric shields may form shapes and/or sizes which may be maintained uniform along the transmission lines, base units, and/or counter units or, in the alternative, which may vary therealong. The shapes and/or sizes of the magnetic and/or electric shields may also be identical to, similar to or different from those of the transmission lines, base units, and/or counter units. The system may include multiple magnetic and/or electric shields. At least two of the magnetic and/or electric shields may shield against the magnetic waves and/or electric waves of the harmful waves with same or different frequencies in same or different extents. The magnetic and/or electric shields may be disposed over at least a portion (or entire portion) of the transmission lines, base units, and/or counter units.

In another aspect of the present invention, a method may be provided for countering harmful electromagnetic waves which are irradiated from multiple base units of multiple wave sources of an electromagnetically-countered power grid system by canceling the harmful waves in a target space and/or suppressing the harmful waves from propagating toward the target space, where each of the base units is arranged to include only those portions of each of such wave sources responsible for irradiating the harmful waves and/or affecting paths of propagation of the harmful waves therealong while the target space is defined between an user of the system and at least one of such base units.

In one exemplary embodiment of this aspect of the invention, a method may have the steps of: generating multiple electrical energies each having preset amplitudes and each defining phase angles differing from each other by about a preset angle (which is to be referred to as the “first generating” hereinafter); extending multiple transmission lines of the energies at least substantially parallel to each other from a source of the energies to the user while functioning the lines as the wave sources (to be referred to as the “first extending” hereinafter); transmitting each of the electrical energies along each of the lines while irradiating by the base units of the lines the harmful waves having preset amplitudes and defining such different phase angles (to be referred to as the “first transmitting” hereinafter); and disposing. Such disposing may also include one of the steps of: disposing such lines at least partially opposite to each other when viewed upon a hypothetical plane defined perpendicular to such lines in the target space, thereby countering the harmful waves irradiated by one of the lines with the harmful waves irradiated from the rest of the lines due to the extending, disposing, and phase angles in such a target space (which will be referred to as the “first disposing” hereinafter); disposing such lines in about a single distance from each other when viewed on a hypothetical plane defined perpendicular to the lines in the target space, thereby countering the harmful waves irradiated from one of the lines with the harmful waves which are irradiated by the rest of the lines due to the extending, disposing, and such phase angles in the target space (to be referred to as the “second disposing” hereinafter); disposing the lines in about a single angle about a center of a circle which is defined by such lines on a hypothetical plane defined normal to the lines, thereby countering the harmful waves irradiated from one of the lines with the harmful waves which are irradiated by the rest of the lines due to the above extending, disposing, and phase angles in such a target space (which is to be referred to as the “third disposing” hereinafter); disposing the lines at least partially opposite to each other when viewed on a hypothetical plane defined normal to the lines while aligning multiple peak planes of the harmful waves in the target space as far away therefrom, thereby countering the harmful waves irradiated by one of the lines with the harmful waves irradiated from the rest of the lines due to such extending, disposing, and phase angles in the target space (which will be referred to as the “fourth disposing” hereinafter); disposing such lines at least partially opposite to each other when viewed upon a hypothetical plane defined perpendicular to the lines while also aligning multiple peak planes of the harmful waves evenly across the target space, thereby countering the harmful waves irradiated by one of the lines with the harmful waves irradiated by the rest of the lines due to the extending, disposing, and phase angles in the target space (which will be referred to as the “fifth disposing” hereinafter); and disposing the lines in another disposition for countering such harmful waves irradiated by each other while manipulating the disposition so as to minimize electromagnetic interaction among the energies transmitted along the lines (to be referred to as the “sixth disposing” hereinafter).

In another exemplary embodiment of this aspect of the invention, a method may have the steps of: the first generating; the first extending; installing at least one transmission tower and at least one power pole between the source of the energies and the user; mechanically supporting the lines with at least one of the transmission tower and power pole; the first transmitting; and then one of the first disposing, second disposing, third disposing, fourth disposing, fifth disposing, and sixth disposing.

In another aspect of the present invention, a method may be provided for countering harmful electromagnetic waves which are irradiated from multiple base units of multiple wave sources of an electromagnetically-countered three-phase power grid system through at least one of canceling the harmful waves in a target space and suppressing the harmful waves from propagating to the target space, where each of the base units is arranged to include only those portions of each of the wave sources responsible for irradiating the harmful waves and/or affecting paths of propagation of such harmful waves therethrough and where the target space is defined between an user of the system and at least one of the base units.

In one exemplary embodiment of this aspect of the invention, a method may have the steps of: generating at least three electrical energies each having preset amplitudes and defining phase angles differing from each other by about 120°; the first extending; the first transmitting; and one of the first disposing, second disposing, third disposing, fourth disposing, fifth disposing, and sixth disposing.

In another exemplary embodiment of this aspect of the invention, a method may have the steps of: the second generating; the first extending; the first transmitting; and disposing. The disposing may include one of the steps of: the second disposing; the third disposing; the sixth disposing; disposing such lines in vertices of an at least substantially equilateral triangle which is defined on a hypothetical plane defined normal to the lines in the target space, thereby countering the harmful waves irradiated by one of the lines with the harmful waves irradiated from the rest of such lines due to the extending, generating, and phase angles in such a target space; disposing the lines in each vertex of an at least substantially equilateral triangle which is defined on a hypothetical plane formed perpendicular to the lines in the target space while aligning multiple peak planes of the harmful waves in the target space as far away therefrom, thereby countering the harmful waves irradiated by one of the lines with the harmful waves irradiated from the rest of the lines due to the extending, disposing, and phase angles in the target space; and disposing such lines in vertices of an at least substantially equilateral triangle which is defined on a hypothetical plane formed perpendicular to the lines in the target space while aligning multiple peak planes of the harmful waves as evenly as possible in the target space, thereby countering the harmful waves irradiated by one of the lines with the harmful waves irradiated by the rest of the lines due to the extending, disposing, and phase angles in the target space.

In another aspect of the present invention, a method may be provided for countering harmful electromagnetic waves which are irradiated from multiple base units of multiple wave sources of an electromagnetically-countered power grid system by canceling the harmful waves in a target space and/or suppressing the harmful waves from propagating toward the target space, where each of the base units is arranged to include only those portions of each of such wave sources responsible for irradiating the harmful waves and/or affecting propagation paths of the harmful waves therethrough, while the target space is defined between an user of the system and at least one of the base units.

In one exemplary embodiment of this aspect of the invention, a method may have the steps of: the first generating; the first extending; the first transmitting; grouping the lines into at least two sets; disposing the lines of a first set in a first preset disposition capable of countering the harmful waves irradiated by one of the lines of the first set with the harmful waves irradiated by the rest of the lines of the first set due to the extending, disposing, and phase angles in the target space; disposing such lines of a second set in a second preset disposition capable of countering the harmful waves which are irradiated by one of the lines of the second set with the harmful waves irradiated by the rest of the lines of the second set due to the extending, disposing, and phase angles in the target space; and arranging. Such arranging may include one of the steps of: arranging the first set of the lines in any arbitrary arrangement with respect to the second set of the lines while independently countering the harmful waves in each of the sets of the lines (to be referred to as the “first arranging” hereinafter); arranging the first set of the lines in a preset arrangement with respect to the second set of the lines while countering the harmful waves between both of the sets of the lines as well (to be referred to as the “second arranging” hereinafter); arranging at least one of such lines of the first set around at least one of the lines of the second set concentrically while countering the harmful waves between both of the sets of the lines (to be referred to as the “third arranging” hereinafter); and arranging the first set of the lines between the second set of the lines and the target space while countering such harmful waves between both of the first and second sets of the lines (to be referred to as the “fourth arranging” hereinafter).

In another exemplary embodiment of this aspect of the invention, a method may have the steps of: the first generating; the first extending; the first transmitting; grouping a first number of such lines into a first set of the lines; grouping a second different number of the lines in a second set of the lines; disposing the lines of the first set in a first preset disposition to counter the harmful waves irradiated by one of the lines of the first set with the harmful waves irradiated by the rest of the lines of the first set due to such extending, disposing, and phase angles in the target space; disposing the lines of the second set in a second preset disposition to counter the harmful waves irradiated by one of the lines of the second set with the harmful waves irradiated by the rest of such lines of the second set due to the extending, disposing, and phase angles in the target space; and one of the first arranging, second arranging; third arranging; and fourth arranging.

In another exemplary embodiment of this aspect of the invention, a method may have the steps of: the first generating; the first extending; the first transmitting; grouping a first number of such lines carrying lower voltages into a first set of the lines; grouping a second different number of such lines carrying higher voltages in a second set of the lines; disposing the lines of the first set in a first preset disposition to counter the harmful waves irradiated by one of the lines of the first set with the harmful waves irradiated from the rest of the lines of the first set due to the extending, disposing, and phase angles in such a target space; disposing the lines of the second set in a second preset disposition to counter the harmful waves irradiated from one of the lines of the second set with the harmful waves irradiated by the rest of the lines of the second set due to the extending, disposing, and phase angles in the target space; and then one of the first arranging, second arranging, third arranging, and fourth arranging.

In another exemplary embodiment of this aspect of the invention, such a method may have the steps of: the first generating; the first extending; the first transmitting; grouping such lines into at least two sets; disposing the lines of a first set in a first preset disposition while irradiating at least a minimal amount of the harmful waves in such a target space as a result of an interaction between the harmful waves irradiated from the lines of the first set; disposing the lines of a second set in a second preset disposition while irradiating at least a minimal amount of such harmful waves in the target space as a result of another interaction between the harmful waves irradiated from such lines of the second set; arranging the first set of the lines in a preset arrangement with respect to the second set of the lines such that the harmful waves irradiated from one of the sets of the lines counter the harmful waves irradiated by another of the sets of the lines in the target space.

In another aspect of the present invention, a method may be provided for countering harmful electromagnetic waves which are irradiated from multiple base units of multiple wave sources of an electromagnetically-countered power grid system by emitting counter electromagnetic waves and by suppressing the harmful waves from propagating toward a target space and/or canceling the harmful waves in the target space, where each of the base units is arranged to include only portions of each of the wave sources which are responsible for irradiating the harmful waves and/or affecting paths of propagation of the harmful waves therethrough, and where the target space is defined between at least one of the base units and an user of the system.

In one exemplary embodiment of this aspect of the invention, a method may have the steps of: providing a single counter unit to emit such counter waves; configuring the counter waves to define shapes similar to those of the harmful waves and to have at least partially opposite phase angles (to be referred to as the “first configuring” hereinafter); and countering the harmful waves irradiated from only one of the base units by the counter waves.

In another exemplary embodiment of this aspect of the invention, a method may have the steps of: providing a single counter unit for emitting the counter waves; the first configuring; and countering a sum of the harmful waves irradiated from all (or at least two but not all) of the base units of a single wave source with the counter waves. The countering may be replaced by the step of: countering a sum of the harmful waves irradiated by all (or at least two but not all) of the base units of at least two different wave sources with the counter waves.

In another exemplary embodiment of this aspect of the invention, a method may have the steps of: providing multiple counter units to emit the counter waves; the first configuring; and countering the harmful waves irradiated by only one of such base units by a sum of all of the counter waves emitted by all of the counter units.

In another exemplary embodiment of this aspect of the invention, such a method may include the steps of: providing multiple counter units for emitting the counter waves; the first configuring; and countering a sum of the harmful waves irradiated from all (or at least two but not all) of the base units of a single wave source with a sum of the counter waves emitted from at least two of such counter units. The countering may be replaced by the step of: countering a sum of the harmful waves which are irradiated from all (or at least two but not all) of such base units included in at least two different wave sources with a sum of the counter waves emitted from at least two of the counter units.

In another exemplary embodiment of this aspect of the invention, a method may have the steps of: providing at least two counter units for emitting the counter waves; configuring at least one of the counter units to move with respect to the other thereof; the first configuring; and then moving such at least one of the counter units with respect to at least one of such base units in the emitting, thereby countering the harmful waves irradiated by only one of the base units by the counter waves emitted from a different number of the counter units.

Embodiments of such method aspects of the present invention may include one or more of the following features, and configurational and/or operational variations and/or modifications of the above methods also fall within the scope of the present invention.

The generating may include at least one of the steps of: generating the voltage over 150,000 AC volts; generating the voltage less than 150,000 but exceeding 100,000 AC volts; generating the voltage below 100,000 but exceeding 50,000 AC volts; generating the voltage below 50,000 but over 10,000 AC volts; generating the voltage below 10,000 but exceeding 5,000 AC volts; generating the voltage below 5,000 but over 1,000 AC volts; generating the voltage below 1,000 but exceeding 500 AC volts, and the like. The generating may also include one of the steps of: alternating the electrical energy in about 50 Hz, alternating the energy in about 60 Hz; alternating the energy between about 50 Hz and 60 Hz; alternating the energy in another frequency lower than 50 Hz, alternating the energy in a frequency above 60 Hz, and so on. The generating may include one of the steps of: generating the energies of at least partially similar voltages; generating two sets of such energies one of which has first higher voltages and the other of which has second lower voltages, and so on. The differing may include one of the steps of: spacing the phase angles by a constant angle; spacing the phase angles by about 180° when the system includes a pair of the lines; spacing the phase angles by about 120° when the system includes three of the lines; spacing the phase angles by about 90° when the system includes four of the lines, and the like.

The extending may include one of the steps of: maintaining the disposition of the lines along at least substantial portions of lengths of the transmission lines; maintaining the disposition of the lines in preset portions of the lengths of the lines, and the like. The extending may include at least one of the steps of: hanging the lines between the power poles; hanging the lines between the towers; hanging the lines between the tower and pole, and so on. The extending may include at least one of the steps of: bifurcating at least one of such lines to multiple lines; merging at least two of the lines into a single line, and the like.

The transmitting may include at least one of the steps of: transmitting such electrical energy of the voltage exceeding 150,000 AC volts; transmitting such energy of the voltage below 150,000 but over 100,000 AC volts; transmitting the energy of the voltage below 100,000 but exceeding 50,000 AC volts; transmitting the energy of the voltage less than 50,000 but over 10,000 AC volts; transmitting the energy of the voltage less than 10,000 but over 5,000 AC volts; transmitting the energy of the voltage less than 5,000 but exceeding 1,000 AC volts; transmitting the energy of the voltage below 1,000 but exceeding 500 AC volts, and so on. The transmitting may include one of the steps of: transmitting the energy alternating in about 50 Hz, transmitting the energy alternating in about 60 Hz; transmitting such energy alternating between about 50 Hz and 60 Hz; transmitting the energy alternating in a frequency lower than 50 Hz, transmitting the energy alternating in a frequency exceeding 60 Hz, and so on. The transmitting may also include one of the steps of: transmitting such energies of at least partially similar voltages; transmitting two sets of the energies one of which has first higher voltages and the other of which defines second voltages lower than the first voltages, and the like. The irradiating may include one of the steps of: irradiating the harmful waves with extremely low-frequency less than about 300 Hz; irradiating the harmful waves having frequencies less than about 1 kHz, 5 kHz, 10 kHz or 20 kHz; irradiating the harmful waves with frequencies less than about 50 kHz, 100 kHz, 500 kHz, and 1 MHz; irradiating the harmful waves of frequencies less than about 10 MHz, 50 MHz, 100 MHz, 500 MHz, and 1 GHz; irradiating the harmful waves having frequencies less than about 5 GHz, 10 GHz, 50 GHz, 100 GHz, 500 GHz, and 1 THz, and the like.

The grouping may include one of the steps of: including the same number of such lines in each of the sets; and including different numbers of the lines in at least two of the sets. The grouping may also have one of the steps of: including the lines in the same disposition in each of the sets the lines; and including the lines in different dispositions in at least two of the sets of the lines. Such grouping may include one of the steps of: including the lines transmitting the energies of the same amplitudes in each of the sets of the lines; including the lines transmitting such energies of different amplitudes in at least two of the sets of the lines, and the like.

Such countering may include the step of: suppressing and/or canceling the harmful waves by the counter waves while minimizing adverse effects from the countering upon actuating operations of the actuator of the system. The countering may include one of the steps of: countering such harmful waves irradiated by the base units of only one of such wave sources; countering the harmful waves by the base units of at least two but not all of the wave sources; countering the harmful waves from the base units of all of the wave sources, and the like. The countering may include at least one of the steps of: suppressing at least a portion of the harmful waves from propagating toward such a target space with the counter waves; canceling the portion of the harmful waves by the counter waves in the target space, and the like. The countering may include at least one of the steps of: countering the harmful waves defining frequencies less than about 50 Hz to 60 Hz; countering the harmful waves of frequencies less than about 300 Hz; countering the harmful waves with frequencies less than about 1 kHz, and the like. The countering may include at least one of the steps of: countering such harmful waves with frequencies less than about 10 kHz; countering the harmful waves with frequencies less than about 100 kHz; countering the harmful waves with frequencies less than about 1 MHz, 10 MHz, 100 MHz, 1 GHz, 10 GHz, 100 GHz, 1 THz, and the like. The countering may also include at least one of the steps of: countering such harmful waves in only a portion of a preset frequency range while preserving the rest thereof; countering magnetic waves of the harmful waves; countering an entire portion of the harmful waves, and the like. Such countering may include the steps of: functioning at least one of the base units as at least one counter unit; irradiating the harmful waves from the rest of the base units while emitting counter electromagnetic waves from the counter unit; and countering the harmful waves with the counter waves. The countering may include the steps of: providing at least one counter unit in addition to the base units; emitting counter electromagnetic waves by the counter unit; manipulating a configuration of the counter unit to approximate a configuration of at least one of the base units; countering the harmful waves with the counter waves based on the configurations in the target space, and the like. The countering may include the steps of: providing at least one counter unit in addition to the base units; emitting counter electromagnetic waves by the counter unit; defining multiple first wavefronts in the counter waves; defining multiple second wavefronts in such harmful waves; manipulating a disposition of the counter unit to match at least a portion of the first wavefronts of the counter waves to at least a portion of the second wavefronts of the harmful waves which are irradiated by at least one of the base units; and countering the harmful waves by the counter waves based on shapes of the wavefronts of the harmful and counter waves in the target space.

The matching may include one of the steps of: matching such counter waves with the harmful waves irradiated by only one of the base units; matching the counter waves with the harmful waves irradiated from at least two but not all of the base units; matching the counter waves with the harmful waves irradiated by all of the base units, and the like. Such matching may include one of the steps of: matching the counter waves with the harmful waves irradiated from only one of such wave sources; matching the counter waves with the harmful waves irradiated by at least two but not all of the wave sources; matching the counter waves with the harmful waves irradiated by all of the wave sources, and the like. Such affecting may include at least one of the steps of: including at least one permanent magnet; applying the electric voltage; flowing the electric current, and the like.

The providing may include at least one of the steps of: forming the counter unit into a shape of at least one of a wire, a strip, a sheet, a tube, a coil, a spiral, and a mesh; forming the counter unit into one of a mixture of the shapes, a combination of the shapes, and an array of the shapes, and the like. The forming may include at least one of the steps of: enclosing at least a portion of the base unit by an array (or bundle) of multiple wires of the counter unit; enclosing such a portion of the base unit by an array (or bundle) of multiple strips of the counter unit; enclosing such a portion of the base unit by an array (or bundle) of multiple sheets of the counter unit; enclosing such a portion of the base unit by an array (or bundle) of multiple tubes of the counter unit; winding with at least one coil of the counter unit about such a portion of the base unit; winding the portion of the base unit by an array (or bundle) of multiple coils; enclosing the portion of the base unit with at least one annular mesh of the counter unit, and the like. The forming the counter unit may include at least one of the steps of: extending a single wire for at least a portion of the counter unit; extending an array (or bundle) of multiple wires for such a portion; extending a single strip for such a portion; extending an array (or bundle) of multiple strips for the portion; extending a single sheet therefor; extending an array (or bundle) of multiple sheets for the portion; extending a single tube therefor; extending a bundle (or array) of multiple tubes therefor; winding a single coil therefor; winding a bundle (or array) of multiple coils therefor; extending a single annular mesh therefor; and extending an array (or bundle) of multiple annular meshes therefor. Such providing may include one of the steps of: exposing the counter unit through the base unit; hiding the counter unit under (or inside) the base unit, and the like. The providing may include at least one of the steps of: fixedly disposing the counter unit; and movably disposing the counter unit. Such providing may include one of the steps of: forming such base and counter units of a same material; forming the base and counter units of different materials; including at least one but not all of materials in the base and counter units, and the like. The providing may include one of the steps of: arranging the base and counter units to define similar (or identical) resonance frequencies; arranging such base and counter units to define different resonance frequencies, and the like. Such providing may include at least one of the steps of: disposing the counter unit laterally (or side by side) with the base unit; enclosing at least one of the counter and base units with another of the units; axially aligning the base and counter units, and the like. The enclosing may include one of the steps of: disposing the counter unit indirectly over (or around) the base unit (or wave source); disposing the counter unit directly on (or around) the base unit (or source), and the like. The enclosing may include at least one of the steps of: disposing at least two of the counter units concentrically; electrically coupling the counter units in a series mode, parallel mode, and/or hybrid mode, and the like. The aligning may include one of the steps of: aligning the counter unit with the longitudinal axis of the base unit; aligning the counter unit with the short axis of the base unit; aligning the counter unit with the direction of the current flowing in (or voltage applied across) the base unit, aligning the counter unit with the direction of propagation of the harmful waves, and the like. The configuring such a counter unit may include at least one of the steps of: controlling a shape of the counter unit; controlling a size of the counter unit; and controlling an arrangement of the counter unit. The manipulating the disposition may also include at least one of the providing, forming, enclosing, the aligning, and the configuring.

The defining the second wavefronts may also include at least one of the steps of: defining the second wavefronts with the harmful waves irradiated from only one of the base units; defining such second wavefronts with the harmful waves irradiated from at least two but not all of such base units; and forming the second wavefronts with the harmful waves which are irradiated from all of the base units. The defining the second wavefronts may also include at least one of the steps of: defining the second wavefronts with the harmful waves irradiated by only one of the wave sources; forming the second wavefronts with the harmful waves which are irradiated from at least two but not all of such wave sources; forming the second wavefronts with the harmful waves irradiated by all of the wave sources, and the like. The configuring may be performed to the harmful waves irradiated by only one of the base units, irradiated from at least two but not all of the base units, irradiated by all of the base units, and the like. The configuring may be performed to the harmful waves irradiated by only one of the wave sources, irradiated from at least two but not all of the wave sources, irradiated from all of the wave sources, and the like.

The disposing may include at least one of the steps of: controlling an orientation of the counter unit with respect to the base unit (or target space); controlling an alignment of the counter unit with respect thereto; controlling a first distance between the counter unit and base unit (or target space); controlling a second distance between the counter units, and so on. The disposing may be performed to the harmful waves irradiated from only one of the base units, irradiated from at least two but not all of the base units, irradiated by all of the base units, and the like. The disposing may be performed to the harmful waves irradiated from only one of the wave sources, irradiated from at least two but not all of the wave sources, irradiated from all of the wave sources, and the like.

The emitting may also include one of the steps of: manipulating the phase angles of the counter waves to be at least similar (or identical) to those of the harmful waves when the counter and harmful waves propagate in at least partially opposite directions; manipulating the phase angles of the counter waves to be at least opposite to those of the harmful waves when such counter and harmful waves propagate along at least similar directions; and manipulating the phase angles of the counter waves to be transverse to those of the harmful waves when the counter and harmful waves propagate along directions which are transverse to each other. Such emitting may include at least one of the steps of: manipulating amplitudes of the counter waves to be greater (or less) than those of the harmful waves when measured in the target space; manipulating the amplitudes of such counter waves to be similar (or identical) to those of the harmful waves when measured at the base unit, and so on. The emitting may include at least one of the steps of: propagating the counter waves in the same direction as that of the harmful waves; propagating the counter waves in a direction different from that of the harmful waves irradiated from each of base units but along the same direction as that of a sum of the harmful waves by the base units, and so on. The emitting may include the step of: manipulating phase angles of the counter waves to be at least partially (or substantially) opposite to those of the harmful waves.

The method may also include one of the steps of: flowing the current in an entire portion of the base unit; flowing the current in only a portion of the base unit; applying the voltage across an entire portion of the base unit; and applying the voltage across only a portion of the base unit. The method may include one of the steps of: flowing the current in a single direction through the base (or counter) unit; flowing such current in different directions along different portions of the base (or counter) unit; applying the voltage along a single direction through the base (or counter) unit; applying the voltage in different directions along different portions of the base (or counter) unit, and the like. The method may include the step of: providing multiple base units for the harmful waves, and the flowing may include one of the steps of: flowing the currents with the same amplitudes along a same direction in all of the base (or counter) units; flowing the currents of the same amplitudes in different directions along the base (or counter) units; flowing the currents of different amplitudes in the same direction in all of the base (or counter) units; flowing the currents of different amplitudes in different directions in the base (or counter) units, and the like. The method may include the step of: providing multiple base units for such harmful waves, and the applying may include one of the steps of: applying such voltages of the same amplitudes along a same direction in all of the base (or counter) units; applying the voltages of the same amplitudes in different directions along the base (or counter) units; applying the voltages of different amplitudes in the same direction in all of the base (or counter) units; applying the voltages of different amplitudes in different directions in the base (or counter) units, and the like.

The flowings may include one of the steps of: flowing the currents of the same (or different) amplitudes in the counter unit; flowing in the counter unit another current which may not be derived from the current supplied to the base unit but may have a temporal pattern at least partially similar to that of the current supplied to the base unit; flowing along the counter unit another current which may be derived not from the current to the base unit and may have a temporal pattern different from that of the current to the base unit, and the like. The flowing such currents may include one of the steps of: flowing the currents in the base unit and then in the counter unit; flowing the currents in the counter unit and then in the base unit; flowing such currents at least simultaneously in the base and counter units, and the like.

In another aspect of the present invention, another electromagnetically-countered power grid system is arranged to include a preset number of multiple wave sources each having therein at least one base unit and to be capable of countering harmful electromagnetic waves irradiated by the base units by canceling the harmful waves in a target space and/or suppressing the harmful waves from propagating toward the target space, where the base units are arranged to include only portions of the wave sources responsible for irradiating the harmful waves and/or affecting paths of propagation of the harmful waves therealong, where the target space is defined between such base units and an user of the system, and where the system includes at least one power station capable of generating electrical energies each of which defines preset amplitudes and defines phase angles differing from phase angles of at least one of the rest of the energies by about a preset angle obtained from dividing 360° by the preset number.

In one exemplary embodiment of this aspect of the invention, such a system may be made by a process comprising the steps of: installing a power station for generating multiple electrical energies each defining preset amplitudes and having phase angles differing from each other by about a preset angle (to be referred to as the “first installing” hereinafter); extending multiple transmission lines of the energies which are arranged to be at least substantially parallel to each other from the power station to the user while functioning the lines as the wave sources and each of which is arranged to transmit each of the electrical energies while irradiating from the base unit thereof the harmful waves defining the different phase angles (which will be referred to as the “first extending” hereinafter); constructing a hypothetical plane which is perpendicular to at least two of the transmission lines (to be referred to as the “first constructing” hereinafter); and incorporating. Such incorporating may include one of the steps of: incorporating the lines at least partially opposite to each other when viewed on the plane in the target space, thereby matching amplitudes of the harmful waves irradiated from at least one of the lines with those of the waves irradiated by the rest of the lines, matching phase angles of the harmful waves irradiated from at least one of the lines with those of the waves irradiated from the rest of the lines and, therefore, countering the harmful waves irradiated from one of the lines with the harmful waves irradiated by the rest of the lines due to the extending and incorporating in the target space (to be referred to as the “first incorporating” hereinafter); incorporating the lines in about a single distance from each other when viewed upon the plane in the target space, thereby matching amplitudes of the harmful waves irradiated by at least one of the lines with those of the waves irradiated from the rest of the lines, matching phase angles of the harmful waves irradiated from at least one of the lines with those of the waves irradiated from the rest of the lines and, therefore, countering the harmful waves irradiated from one of the lines with the harmful waves irradiated from the rest of the lines due to the above extending and incorporating in the target space (to be referred to as the “second incorporating” hereinafter); incorporating each of the lines about a center of a circle which is defined by the lines on the plane in about a single angle in such a target space, thereby matching amplitudes of such harmful waves irradiated from at least one of the lines with those of the waves irradiated from the rest of the lines, matching phase angles of the harmful waves irradiated from at least one of the lines with those of the waves irradiated from the rest of the lines and, therefore, countering the harmful waves which are irradiated from one of the lines with the harmful waves irradiated from the rest of the lines due to the extending and incorporating in such a target space (to be referred to as the “third incorporating” hereinafter); incorporating the lines at least partially opposite to each other when viewed on the plane while aligning multiple peak planes formed by the harmful waves inside the target space as far away therefrom, thereby countering the harmful waves which are irradiated from one of the lines with the harmful waves irradiated by the rest of the lines due to the extending and incorporating in the target space while minimizing a presence of the peak planes in the target space as well (to be referred to as the “fourth incorporating” hereinafter); incorporating the lines at least partially opposite to each other when viewed on the plane while aligning multiple peak planes formed by the harmful waves as evenly as possible in the target space, thereby countering the harmful waves which are irradiated by one of the lines with the harmful waves which are irradiated by the rest of the lines due to the extending and incorporating in the target space while minimizing a presence of such peak planes in the target space as well (which is to be referred to as the “fifth incorporating” hereinafter); incorporating the lines in a disposition capable of countering the harmful waves irradiated from each other while manipulating the disposition to minimize electromagnetic interaction among the electrical energies transmitted along the lines (to be referred to as the “sixth incorporating” hereinafter).

In another exemplary embodiment of this aspect of the invention, such a system may be made by a process which comprises the steps of: the first installing; the first extending; building at least one transmission tower and at least one power pole between the user and power station; mechanically supporting the lines with at least one of the tower and pole; the first constructing; and one of the first incorporating; second incorporating; third incorporating; fourth incorporating; fifth incorporating; and sixth incorporating;

In another aspect of the present invention, another electromagnetically-countered power grid system is arranged to include therein at least three wave sources each including therein at least one base unit and to be capable of countering harmful electromagnetic waves irradiated by the base units by suppressing the harmful waves from propagating to a target space and/or canceling such harmful waves in the target space, where the base units are arranged to include only portions of such wave sources which are responsible for irradiating the harmful waves and/or affecting propagation paths of the harmful waves therealong, where the target space is defined between the base units and an user of the system, and where the system includes at least one power station capable of generating electrical energies each having preset amplitudes and each also defining phase angles differing from phase angles of at least one of the rest of the energies by about 120°.

In one exemplary embodiment of this aspect of the invention, such a system may be made by a process comprising the steps of: incorporating in the system a power station capable of generating at least three electrical energies each defining preset amplitudes and having phase angles differing from each other by about 120° (to be referred to as the “second installing” hereinafter); extending at least three transmission lines of the energies which are arranged to be at least substantially parallel to each other from the power station to the user while functioning the lines as the wave sources and each of which is arranged to transmit each of the electrical energies while irradiating the harmful waves with the different phase angles from its base unit (to be referred to as the “second extending” hereinafter); the first constructing; and then incorporating. The incorporating may also include one of the steps of: incorporating the lines in an equilateral triangular disposition when viewed upon the plane in the target space, thereby matching amplitudes of the harmful waves irradiated from at least one of the lines with those of the waves irradiated from the rest of the lines, matching phase angles of the harmful waves irradiated by at least one of the lines with those of the waves irradiated from the rest of the lines and, therefore, countering the harmful waves irradiated by one of the lines with the harmful waves which are irradiated by the rest of the lines due to the extending and incorporating in the target space (to be referred to as the “seventh incorporating” hereinafter); the second incorporating; incorporating each of the lines about a center of a circle formed by the lines on the plane in about 60° in the target space, thereby matching amplitudes of the harmful waves irradiated from at least one of the lines with those of the waves which are irradiated from the rest of such lines, matching phase angles of the harmful waves irradiated from at least one of the lines with those of the waves irradiated from the rest of the lines and, accordingly, countering the harmful waves irradiated from one of the lines with the harmful waves irradiated from the rest of the lines due to the extending and incorporating in the target space (which will be referred to as the “eighth incorporating” hereinafter); the fourth incorporating; the fifth incorporating; and the sixth incorporating.

In another exemplary embodiment of this aspect of the invention, a system may be made by a process which comprises the steps of: the second installing; the second extending; building at least one transmission tower and at least one power pole between (or along) the user of the system and power station; mechanically supporting the transmission lines with at least one of the tower and pole; the first constructing; and one of the seventh, second, eighth, fourth, fifth, and sixth incorporating.

In another aspect of the present invention, another electromagnetically-countered power grid system is arranged to include a preset number of multiple wave sources each having therein at least one base unit and to be capable of countering harmful electromagnetic waves irradiated by the base units by canceling the harmful waves in a target space and/or suppressing the harmful waves from propagating toward the target space, where each of the base units is arranged to include therein only portions of each of the wave sources which are responsible for irradiating the harmful waves and/or affecting paths of propagation of the harmful waves therethrough, where the target space is defined between at least one of the base units and an user of the system, where the system has at least one power station for generating electrical energies each having preset amplitudes and each also defining phase angles differing from phase angles of at least one of the rest of the energies by about a preset angle obtained by dividing 360° by the preset number, and where such harmful waves define multiple wavefronts during their propagation.

In one exemplary embodiment of this aspect of the invention, such a system may also be made by a process comprising the steps of: the first installing; extending a single transmission line arranged to transmit only one of the energies therethrough while serving as one of the wave sources including the base unit and to irradiate the harmful waves defining the different phase angles (to be referred to as the “third extending” hereinafter); and including a single counter unit which is arranged to define a configuration matching that only one of such base units and to emit counter electromagnetic waves, while matching amplitudes of the harmful waves with those of the counter waves through adjusting the configuration (or arrangement), opposing phase angles of such harmful waves with those of the counter waves and, accordingly, countering the harmful waves with the counter waves in the target space. Such including may also be replaced by the step of: including multiple counter units which are arranged to be in an arrangement matching a configuration of only one of such base units and to emit counter electromagnetic waves.

In another exemplary embodiment of this aspect of the invention, a system may be made by a process comprising the steps of: the first installing; the first extending; including a single counter unit which is arranged to define a configuration matching that of all (or at least two but not all) of the base units and to emit counter electromagnetic waves, while matching amplitudes of such harmful waves with those of the counter waves through the configuration (or arrangement), opposing phase angles of the harmful waves with those of the counter waves and, therefore, countering the harmful waves with the counter waves in the target space. Such including may be replaced by the step of: including multiple counter units at least two (or all) of which are arranged to be in an arrangement matching that of all (or at least two but not all) of the base units and to emit counter electromagnetic waves.

In another exemplary embodiment of this aspect of the invention, a system may be made by a process comprising the steps of: the first installing; the third extending; including a single counter unit which is arranged to define a preset shape, to be in a preset arrangement with respect to at least one of such base units, and to emit counter electromagnetic waves, where the shape and/or arrangement may be arranged to match at least a portion of only one (or multiple portions of at least two) of such wavefronts; and defining multiple wavefronts in the counter waves while manipulating at least one of the wavefronts of the counter waves to be similar (or to be identical) to the portion of the wavefronts of the harmful waves based on at least one of the shape and arrangement, to have phase angles at least partially opposite to those of the harmful waves and, accordingly, to counter the harmful waves due to the phase angles in the target space. The including may be replaced by the step of: including multiple counter units which are arranged to define an overall preset shape, to be formed in a preset arrangement with respect to at least one of the base units, and then to emit counter electromagnetic waves, where the overall shape and/or arrangement may be arranged to match at least a portion of only one (or multiple portions of at least two) of the wavefronts.

In another exemplary embodiment of this aspect of the invention, a system may be made by a process comprising the steps of: the first installing; the first extending; forming multiple wavefronts; including a single counter unit which is arranged to be shaped, sized, and disposed in order to emit counter electromagnetic waves capable of matching at least a portion of only one (or multiple portions of at least two) of the wavefronts of the harmful waves irradiated from only one (or at least two) of the base units; and defining multiple wavefronts in the counter waves while manipulating at least one of the wavefronts of the counter waves to be similar (or to be identical) to the portion of only one (or portions of at least two) of the wavefronts of the harmful waves based upon a shape, a size, and/or a disposition of the counter unit(s), to have phase angles which are at least partially opposite to those of the harmful waves and, therefore, to counter the harmful waves in the target space. The including may be replaced by the step of: including multiple counter units all (or at least two but not all) of which are arranged to be disposed, shaped, and sized so as to emit counter electromagnetic waves, where a sum of the counter waves is arranged to match at least a portion of only one (or multiple portions of at least two) of the wavefronts of the harmful waves irradiated by only one (or at least two) of such base units.

More product-by-process claims may be constructed by modifying the foregoing preambles of the apparatus and/or method claims and by appending thereonto such bodies of the apparatus and/or method claims. In addition, such process claims may include one or more of the above features of the apparatus and/or method claims of the present invention.

As used herein, the term “units” collectively refers to both of a “base unit” and a “counter unit” of an electromagnetically-countered power grid system of the present invention, where the system is to be abbreviated hereinafter as the “EMC power grid system,” “EMC system,” “system,” and the like. Such a classification between the “units” is primarily based upon their intended functions. That is, the “base unit” represents various parts of the “EMC power grid system” which perform various intended functions of the EMC system such as, e.g., transmitting such electrical energies therealong, minimizing undesirable interactions among its transmission lines, and the like. It is to be understood that all “base units” irradiate the harmful waves while performing the intended functions and that such “base units” are always incorporated in the above EMC power grid system and in various prior art power grids for similar purposes. In contrary, the “counter unit” refers to those parts of the EMC system which are to accomplish countering functions such as, e.g., canceling at least a portion of the harmful waves in the target space and/or suppressing (or preventing) this portion of such harmful waves from propagating toward the target space. When desirable, the “counter unit” may also be arranged to perform various functions intended for the “base unit” and, accordingly, serve as an extra “base unit” which performs such countering function. This unit, however, is to be deemed as the “counter unit” within the scope of the present invention unless otherwise specified. Within the scope of this invention, the “base unit” is, therefore, omnipresent in any prior art power grids, while the “counter unit” is neither physically not functionally present in these prior art power grids or while some (or all) of the “base units” of the prior art power grids are neither arranged nor disposed to perform the countering function.

The “base unit” is to be distinguished from a “wave source” within the scope of this invention. More particularly, the “wave source” collectively refers to portions of the EMC system irradiating such harmful waves, whereas the “base unit” specifically refers only to the portions of the “wave source” which are directly responsible for irradiating the harmful waves and/or affecting paths of propagation of the harmful waves. For example, various transmission lines of the EMC power grid system are its “wave sources,” while the “base units” of the EMC system generally include, e.g., conductive wires or strips of such lines. An insulation layer and a coupler of the EMC system, however, may qualify as portions of the “wave source” but not parts of such “base units,” for they neither irradiate the harmful waves nor affect the propagation paths of such harmful waves. Accordingly, a shape of the “wave source” is different from that of the “base unit,” where the “base unit” may define the shape simpler or more complex than that of the “wave source.” However, the “base unit” may be deemed as a subset of the “wave source” and, accordingly, the “base unit” almost always defines a size which is smaller than or at most equal to that of its “wave source.”

As used herein, the term “configuration” collectively refers a shape, size, and/or arrangement, while the term “disposition” collectively includes orientation, alignment, and/or distance. Accordingly, the “configuration” of the (counter or base) unit may refer to the shape of the unit, the size of the unit, and/or arrangement of the unit with respect to the other of the base and counter units. Similarly, the “disposition” of the unit may refer to the orientation and/or alignment of such a unit with respect to the other of the base and counter units, to the target space, to a direction of propagation of the harmful or counter waves, to a direction of the electric current flowing in or voltage applied across such a unit or the other of the base and counter units, and the like. The “disposition” of the unit may also refer to the distance to the other of the base and counter units therefrom, to the target space, and the like. When the system include multiple counter units, the “disposition” thereof may include the distance between at least two of such counter units.

Within the scope of the present invention, the term “wire” collectively refers to an article with a shape of a wire, a fiber, a filament, a rod, and/or a strand, and shapes of any other similarly elongated articles each of which may be straight or curved (i.e., curvilinear), and each of which may be formed into a loop, a coil, a roll, a spiral, a mesh, and the like. The term “strip” collectively refers to an article with a shape of a strip, a bar, a pad, and/or a tape, and shapes of any other planar or curved articles with large aspect ratios (i.e., ratios of lengths to widths or heights), each of which may be arranged straight or curved, each of which may be arranged in a two- or three-dimensional configuration, each of which may be arranged into a loop, a coil, a roll, a spiral, a mesh, and the like. In addition, the term “sheet” collectively refers to an article with a shape of a sheet, a slab, a foil, a film, a plate, and/or a layer, and shapes of any other articles which are wider than the “strip,” each of which may be planar (i.e., two-dimensional or 2-D) or curved (i.e., three-dimensional or 3-D), each of which may be formed in a segment, a roll, and the like. The term “tube” collectively refers to an article which may define any of the shapes described hereinabove and to be described hereinafter and forming at least one lumen therethrough. Such a “tube” may be arranged straight or curved, may be arranged into a loop, a coil, a roll, a spiral, a mesh, and the like. The term “coil” collectively refers to an article defining a shape of a helix and/or a spring, and shapes of any other articles winding around an object along a longitudinal or short axis of such an object at a constant distance from the object, and the like. The “coil” may be arranged straight or curved, may also be arranged into a loop (such as a toroid), a coil, a roll, a spiral, a mesh, and the like. The term “spiral” collectively refers to an article defining a shape of another helix and/or spring which may, however, expand or shrink along the longitudinal or short axis of an object, and shapes of any other articles winding around such an object at varying distances, and the like. It is appreciated that a planar “spiral” may be formed on a single curvilinear plane which is normal to the longitudinal or short axis of the object. The term “mesh” collectively refers to an article with a shape a mesh, a net, a screen, a quilt, a fabric, and/or a garment, and shapes of any other articles which may be formed into a networking structure, a woven structure, an interwoven structure, and the like. The term “bundle” collectively refers to an article defining a shape of two or more of the same or different elongated shapes which are aligned side by side or laterally in such a manner that a cross-section of the “bundle” or a “bundled article” may include at least two of such shapes therein. The term “braid” collectively refers to an article with a shape of two or more of the same of different elongated shapes which are braided in such a manner that the “braid” or a “braided article” may consist of at least two of such shapes in a cross-section normal to a longitudinal and/or short axis thereof, where examples of such articles may include, but not be limited to, a thread, a yarn, any other articles made by prior art braiding techniques, and the like. It is to be understood that at least a portion of each of such articles formed according to the above terms in this paragraph may be arranged to be solid, hollow or porous such as, e.g., a foam, a sponge, and the like. It is also appreciated that each of such articles formed according to the foregoing terms of this paragraph may be arranged to include (or define) at least one hole, gap or opening.

Similarly and as used herein, the term “mixture” collectively refers to a liquid, a solution, a sol, a gel, an emulsion, a suspension, a slurry, and/or a powder, each of which may include therein multiple particles, particulates, grains, granules, filings, fragments, and/or pellets each of which may also have shapes of spheres, ellipsoids, cylinders, flakes, “wires,” “strips,” and the like, and each of which may be in a range of millimeters, microns or nanometers. When appropriate, such a “mixture” may include at least one solvent, at least one chemically, electrically, and/or magnetically inert filler for the purpose of providing mechanical strength and/or integrity thereto, and so on.

In addition, the term “combination” refers to a collection of different shapes examples of which may include, but not be limited to, the above wire, strip, sheet, tube, coil, spiral, mesh, their braid, and their bundle. The term “array” similarly refers to the collection of such shapes. However, the “array” refers to the “collection” which in addition forms multiple holes or openings therethrough.

As used herein, the terms “axial,” “radial,” and “angular” will be used in reference to a center axis of the system. Based thereupon, the term “axial direction” refers to a direction along the center axis of the system, while the term “radial direction” means another direction which is normal to such an “axial direction” and, therefore, which represents a direction extending away and outwardly from the center of the system. It is appreciated that such a “radial direction” may be other directions which extend away and outwardly from the center of the system and may be transverse but not necessarily perpendicular to the “axial direction.” The term “angular direction” refers to another direction revolving about the “axial direction” in a clockwise or counterclockwise manner.

It is appreciated that definitions related to various electric and magnetic shields of this invention are similar to those as have been provided in the aforementioned co-pending Applications. Therefore, such definitions are deleted herein for simplicity of illustration.

Unless otherwise defined in the following specification, all technical and scientific terms used herein have the same meaning as commonly understood by one of ordinary skill in the art to which the present invention belongs. Although the methods or materials equivalent or similar to those described herein can be used in the practice or in the testing of the present invention, the suitable methods and materials are described below. All publications, patent applications, patents, and/or other references mentioned herein are incorporated by reference in their entirety. In case of any conflict, the present specification, including definitions, will control. In addition, the materials, methods, and examples are illustrative only and not intended to be limiting.

Other features and/or advantages of the present invention will be apparent from the following detailed description, and from the claims.

### BRIEF DESCRIPTION OF THE DRAWING

FIGS. 1A to 1D are various views of a prior art power grid;

FIGS. 2A to 2H are schematic cross-sectional views of a single set of exemplary transmission lines provided in various dispositions for self-countering according to the present invention;

FIGS. 3A to 3H are schematic cross-sectional views of multiple sets of exemplary transmission lines in various horizontal dispositions for self-countering according to the present invention;

FIGS. 3I to 3Q are schematic cross-sectional views of multiple sets of exemplary transmission lines in various vertical dispositions for self-countering according to the present invention;

FIGS. 4A to 4L are schematic cross-sectional views of multiple sets of exemplary transmission lines in various overlapping dispositions for self-countering according to the present invention;

FIGS. 4M to 4P are schematic cross-sectional views of multiple sets of exemplary transmission lines in various dispositions with at least one common line for self-countering according to the present invention;

FIGS. 5A to 5G are schematic cross-sectional views of exemplary transmission lines and their peak planes in various dispositions according to the present invention;

FIGS. 6A to 6F are top schematic views of exemplary electromagnetic countering mechanisms in each of which a single counter unit emits counter waves to counter harmful waves irradiated by a single base unit of a single wave source according to the present invention;

FIGS. 6G to 6L are top schematic views of exemplary electromagnetic countering mechanisms in each of which multiple counter units emit counter waves to counter harmful waves irradiated by a single base unit of a single wave source according to the present invention; and

FIGS. 7A to 7H are schematic perspective views of exemplary counter units formed in various dispositions with respect to transmission lines according to the present invention.

### DETAILED DESCRIPTION OF THE PREFERRED EMBODIMENTS

The present invention generally relates to an electromagnetically-countered power grid system which includes multiple wave sources such as multiple power transmission lines irradiating therefrom harmful electromagnetic waves but provided in various self-countering dispositions in each of which at least substantial portions of such harmful waves cancel each other. Therefore, such power lines preferably extend in various dispositions in which the power lines are spaced away from each other by similar distances, spaced around a center of a circle by similar angles on a plane defined normal to the lines, and the like. More particularly, the present invention relates to various electromagnetically-countered power grid system including at least three waves sources such as, e.g., three three-phase power transmission lines provided in various self-countering dispositions in each of which the harmful waves irradiated from one of such lines are at least substantially canceled by such waves irradiated from the rest of such lines. Accordingly, such power lines are preferably provided in an equilateral disposition in a plane which is defined perpendicular to such lines. The present invention also relates to various retainers which are disposed along such power lines and couple therewith for maintaining the self-countering dispositions. Alternatively, the present invention relates to an electromagnetically-countered power grid system which includes multiple wave sources such as multiple power lines and which also includes at least one counter unit for emitting counter electromagnetic waves in order to counter the harmful waves by the counter waves, e.g., by canceling at least a portion of the harmful waves with the counter waves in a target space, suppressing such harmful waves from propagating toward the target space with the counter waves, and the like. More particularly, the present invention relates to various counter units for the electromagnetically-countered power grid systems and also to various mechanisms for countering the harmful waves irradiated from various base units of the wave sources with the counter units. Accordingly, the counter unit may be shaped, sized, and/or arranged for matching its configuration with that of at least one of the base units of the wave sources, thereby emitting such counter waves which automatically match wave characteristics of the harmful waves. In the alternative, the counter unit may be shaped, sized, and/or disposed in an arrangement which is defined along one or more wavefronts of such harmful waves, thereby emitting such counter waves automatically matching wave characteristics of the harmful waves. The present invention also relates to various countering modes in which a single counter unit may counter a single base unit or all (or at least two but not all) of multiple base units, in which multiple counter units may counter a single base unit, a greater number of multiple base units, a less number of multiple base units, and so on. At least one of the wave sources such as the transmission line may serve as the counter unit, while the rest of the wave sources such as the rest of the power lines may serve as the base units. Alternatively, at least one of the wave sources such as the transmission line may serve as the base unit, while the rest of the wave sources such as the rest of such power lines may serve as the counter units. The present invention relates to various electric and/or magnetic shields which may be used either alone or in conjunction with at least one of the counter units to minimize irradiation of the harmful waves by at least one of the base units.

The present invention also relates to various methods of countering the harmful waves which are irradiated by an electromagnetically-countered power grid system by providing its wave sources (i.e., its transmission lines) and base units thereof (i.e., their conductive elongated wires) in the self-countering dispositions and canceling each other at least substantial portions of such harmful waves. To this end, this invention relates to various methods of spacing such power transmission lines away from each other by similar distances, spacing such lines around a center of a circle by similar angles on a plane defined perpendicular to such lines, and the like. More particularly, this invention relates to various methods of countering the harmful waves irradiated from at least three transmission lines of a three-phase electromagnetically-countered power grid system by providing such transmission lines in the self-countering dispositions and canceling at least substantial portions of the harmful waves each other. To this end, the present invention relates to various methods of disposing such power lines in the equilateral triangular dispositions defined on a plane normal to such lines and then maintaining the dispositions in the target space. In the alternative, the present invention relates to various methods of countering the harmful waves irradiated from multiple base units of the electromagnetically-countered power grid system with the counter waves by source and/or wave matchings. More particularly, the present invention relates to various methods of providing the counter unit as an analog of at least one of the base units and emitting the counter waves matching such harmful waves, various methods of approximating at least one of the base units by the simpler counter unit for the countering, and various methods of approximating at least one of the base units by multiple simpler counter units. The present invention relates to various methods of disposing the counter unit along the wavefronts of the harmful waves and emitting the counter waves matching the wavefronts of such harmful waves, and various methods of disposing multiple counter units along the wavefronts of such harmful waves and emitting by the counter units the counter waves matching the wavefronts. The present invention also relates to various methods of manipulating the wavefronts of the counter waves by disposing such a counter unit closer to or farther from the target space with respect to at least one of such base units, various methods of controlling radii of curvature of the wavefronts of the counter waves by including one or multiple counter units emitting such counter waves of the same or opposite phase angles, and various methods of manipulating such wavefronts of the counter waves by disposing one or multiple counter units defining the shape similar to or different from that of at least one of the base units. The present invention also relates to various methods of countering the harmful waves irradiated from a single or multiple base units with the counter waves emitted by a single or multiple counter units. Accordingly, this invention also relates to various methods of emitting the counter waves by a single counter unit in order to counter the harmful waves irradiated by one or more base units, various methods of emitting the counter waves by two or more counter units in order to counter the harmful waves irradiated by a single or multiple base units. The present invention relates to various methods of minimizing irradiation of such harmful waves by incorporating the electric shields, by incorporating the magnetic shields, by incorporating one or both of such shields in conjunction with the above counter units, and the like.

The present invention relates to various processes for providing various electromagnetically-countered power grid systems capable of countering the harmful waves irradiated from their multiple base units each other in various self-countering mechanisms. More particularly, the present invention relates to various processes for disposing the transmission lines of a multiphase electromagnetically-countered power grid system in the self-countering dispositions. Alternatively, the present invention relates to various processes for providing various counter units for the EMC power grid system and various EMC power grid system incorporating therein one or multiple counter units. More particularly, the present invention relates to various processes for providing such counter units capable of emitting the counter waves defining the wavefronts similar to (or different from) shapes of the counter units, various processes for providing the counter units as such analogs of at least one of such base units, various processes for forming the counter units emitting the counter waves of the similar or opposite phase angles, various processes for providing the counter units emitting the counter waves with the wavefronts shaped similar to such harmful waves, and various processes for disposing the counter units in a preset arrangement and emitting therefrom the counter waves of the wavefronts similar to such an arrangement. The present invention also relates to various processes for assigning a single counter unit for countering the harmful waves irradiated by a single base unit for the local countering or for countering the harmful waves irradiated by multiple base units for the global countering, various processes for assigning multiple counter units for countering the harmful waves irradiated by a single base unit for the global countering, and to counter the harmful waves irradiated by multiple base units for the local and/or global countering based upon numbers of the counter and base units. The present invention also relates to various processes for employing at least one of the base units as the counter units for the rest of such base units or, in the alternative, for incorporating additional counter units for countering the harmful waves irradiated from the base units. The present invention further relates to various processes for incorporating such electric and/or magnetic shields for minimizing the irradiation of the harmful waves and various processes for minimizing the irradiation of such harmful waves by employing such shields and/or the above counter units.

The basic principle of various EMC power grid systems of the present invention is to minimize the harmful waves irradiated by their base units in the target space by countering the harmful waves with the counter waves therein, e.g., by canceling the harmful waves with the counter waves in the target space, suppressing the harmful waves with the counter waves from propagating toward the target space, and the like. In one example, all of at least a substantial number of base units of the EMC power grid systems operate in the self-countering mechanisms such that each base unit operates as the counter unit of the rest of the base units, that at least one base unit operates as the counter unit of at least another base unit, and the like. In another example, at least one counter unit is incorporated into the EMC system and emits the counter waves capable of countering the harmful waves irradiated by at least one of the base units. The bottom in en either example is that such counter waves counter the harmful waves in the target space and that such counter and/or base units define configurations and are provided in dispositions allowing such countering. Accordingly, the counter units of the EMC system emit the counter waves of the wavefronts similar (or identical) to those of the harmful waves but defining the phase angles at least partially opposite to those of the harmful waves. Therefore, by propagating the counter waves toward the target space, the counter waves may effectively counter the harmful waves in the target space by, e.g., canceling at least a portion of the harmful waves with the counter waves therein, suppressing the harmful waves with the counter waves from propagating theretoward, and the like. To this end, such counter units preferably emit the counter waves defining the wavefronts matching those of the harmful waves by various mechanisms. In one example, such counter units are shaped similar (or identical) to at least one of the base units of the waves sources, or arranged similar (or identical) to the base unit and, accordingly, emit the counter waves capable of countering the harmful waves in the target space. In another example, the counter units are disposed along or across a single or multiple wavefronts of the harmful waves, emit the counter waves similar (or identical) to the harmful waves and, therefore, counter the harmful waves in the target space. In these examples, the counter units emit the counter waves forming the wavefronts similar (or identical) to the shapes of the counter units themselves, and those counter waves define the phase angles at least partially opposite to the phase angles of the harmful waves. In another example, such counter units are shaped differently from at least one of the base units, but rather disposed in an arrangement in which the counter waves emitted thereby match the harmful waves in the target space. In another example, the counter units are disposed across different wavefronts of such harmful waves but emit the counter waves similar (or identical) to the harmful waves, thereby, countering the harmful waves in the target space. In these last two examples, the counter units may be arranged to emit the counter waves defining such wavefronts which may or may not be similar (or identical) to the shapes of the counter units themselves, while the counter waves have the phase angles which are at least partially opposite to those of the harmful waves.

The above basic principle for various generic counter units of the EMC power grid system of the present invention may be implemented to various prior art power grids for minimizing irradiation of the harmful waves therefrom. For example, the counter units may be provided as (or implemented to any base units as) electrically conductive wires, coils, sheets, and the like or, alternatively, may also be provided as (or implemented into such base units as) any electrically semiconductive or insulative wires, coils, sheets, and the like, to minimize irradiation of the harmful waves through countering such harmful waves with the counter waves, where the counter units may also be made of and/or include at least one electrically conductive, insulative or semiconductive material. Such counter units may be implemented to any of the base units of the shapes which may be formed by including one or multiple wires, coils, and/or sheets, by modifying such shapes of one or multiple wires, coils, and/or sheets, where a few examples of the modified shapes may include a solenoid and toroid each of which may be formed by modifying the shape of such a coil. Therefore, such counter units may be provided as (or implemented to) various parts of the EMC power grid system such as, e.g., their transmission lines, neutral lines, support lines, couplers, bypasses, transformers, regulator banks, transmission towers, power poles, taps, and the like. Accordingly, any prior art power grids with the electromagnetically-countered transmission lines may be converted into the EMC power grid systems of this invention. In the alternative, a new power grid may be constructed in any of such self-countering mechanisms or may include any of such counter units, thereby providing the EMC power grid system of this invention.

Various aspects and/or embodiments of various systems, methods, and/or processes of such EMC power grid system of this invention will now be described more particularly with reference to the accompanying drawings and text. It is appreciated that such aspects and/or embodiments of the EMC power grid systems only represent different forms. It is also appreciated that the systems, methods, and/or processes of the present invention, however, may be embodied in many other different forms and, therefore, should not be limited to such aspects and/or embodiments which are set forth herein. Rather, various exemplary aspects and/or embodiments described herein are provided such that this disclosure will be thorough and complete, and fully convey the scope of the present invention to one of ordinary skill in the relevant art.

Unless otherwise specified, it is to be understood that various members, units, elements, and parts of various systems of the present invention are not typically drawn to scales and/or proportions for ease of illustration. It is also to be understood that such members, units, elements, and/or parts of various systems of this invention designated by the same numerals may typically represent the same, similar, and/or functionally equivalent members, units, elements, and/or parts thereof, respectively.

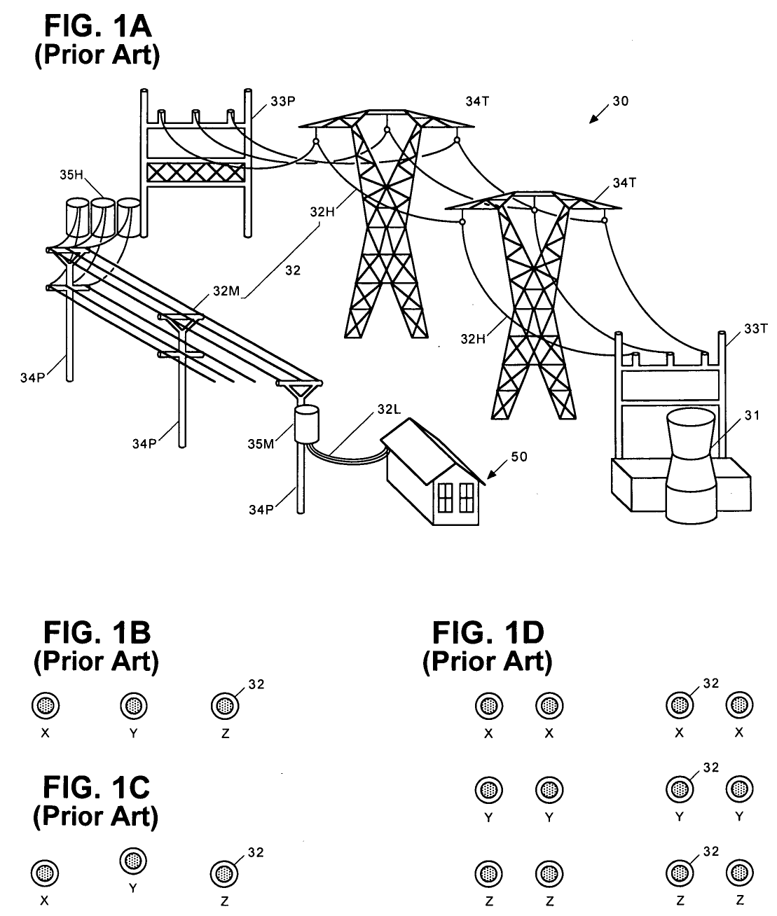

FIGS. 1A to 1D are various views of a prior art power grid, where an exemplary power grid 30 consists of a transmission grid and a distribution grid. The transmission grid starts from a power plant 31 which includes a spinning electrical generator which may be a water wheel in a hydroelectric dam, a large diesel engine, a gas turbine or a steam turbine which is operated by burning coal, oil or natural gas or which is operated from nuclear energy. A typical power plant in the U.S. generates electrical energy oscillating between −170 volts and 170 volts in 60 Hz (i.e., 60 cycles per second) and defining an effective root-mean-square voltage of about 120 volts. With such alternating electrical energy, the power grid 30 may transmit the energy through the rest of the transmission grid and through an entire distribution grid. Such a power plant 31 also produces three different phases of alternating electrical energies (which will be abbreviated as the “AC energies” hereinafter) simultaneously, where each of such three phase energies is synchronized but offset by 120° from each other. It is appreciated that there are 120 moments per second in which the AC energy crosses a zero volt line in a single-phase energy or in two-phase or dual-phase energies (or power). In the three-phase energies, however, one of the energies always nears its peak at any given moment. Therefore, the three-phase energies allow three-phase motors and three-phase welding equipment to exhibit an even power output. The typical power plant 31 provides each phase of such three-phase energies (or power) in a separate line, and further includes a fourth line which is a neutral or ground common to all of the three phases. The next part of the transmission grid is a transmission substation 33T with large transformers which convert such AC energies from the power station 31 (which are generally at a level of thousands of volts) up to extremely high voltages for long-distance transmission along the transmission grid, where typical voltages for long distance transmission are in the range of 155,000 to 765,000 volts in order to reduce line losses. The high-voltage three-phase AC energies are then carried through high-voltage power transmission lines 32H, where a typical maximum transmission distance is about 300 miles (or 483 km). In order to direct the high-voltage lines 32H along desired routes and to hold the heavy lines 32H in position, numerous transmission towers 34T are installed between the transmission substation 33T and a terminal of the transmission grid, i.e., a power substation 33P.

In order for the high-voltage three-phase AC energies to be useful in a home or in a business, such energies have to come off the transmission grid and to be stepped-down to the distribution grid. This distribution grid starts at the power substation 33P which typically performs two or three things: (1) the power substation 33P includes high-voltage transformers 35H which step the high-voltage AC energies in the tens or hundreds of thousands of volts range down to mid-voltage AC energies with a standard line voltages which are typically less than 10,000 volts (usually 7,200 volts); (2) the power substation 33P includes at least one bus (not included in the figure) which splits such mid-voltage AC energies off in multiple directions; and (3) the power substation 33P may include circuit breakers and switches such that the substation 33P may be disconnected from the transmission grid, that separate distribution lines may be disconnected from such a power substation 33P when necessary, and the like. In the embodiment show in this figure, the power substation 33P splits the incoming high-voltage AC energies into two sets of three mid-voltage transmission lines 33M, where a first set of such lines 33M runs above a second set of such lines 33M. Multiple power poles 34P are also installed along the distribution grid for guiding the mid-voltage lines 33M along desired routes and holding such lines 33M in position. This distribution grid terminates at a mid-voltage transformer 35M which steps down such mid-voltage AC energies to low household energies such as, e.g., 120 AC volts in North America, 230 AC volts in most European countries, and so on. The low-voltage AC energies are then transmitted to individual household 50 through low-voltage transmission lines 32M. In an alternative distribution grid, each house may be equipped with the mid-voltage transformer 35M and step down such mid-voltage AC energies to the low-voltage AC energies. It is to be understood that all the individual household 50 requires is only one of the three-phase AC energies. Therefore, the three-phase mid- or low-voltage AC energies may be transmitted to each household 50 in various modes, e.g., by tapping only one or two of the three-phase energies thereto, by generating desirable voltages from such energies using a variety of connections such as a delta connection, and the like. In short, the three-phase AC electrical energies which are generated in the power plant 31 are carried to each household 50 through various transmission lines 32 (i.e., including the high-voltage, mid-voltage, and low-voltage transmission lines 32H, 32M, 32L).

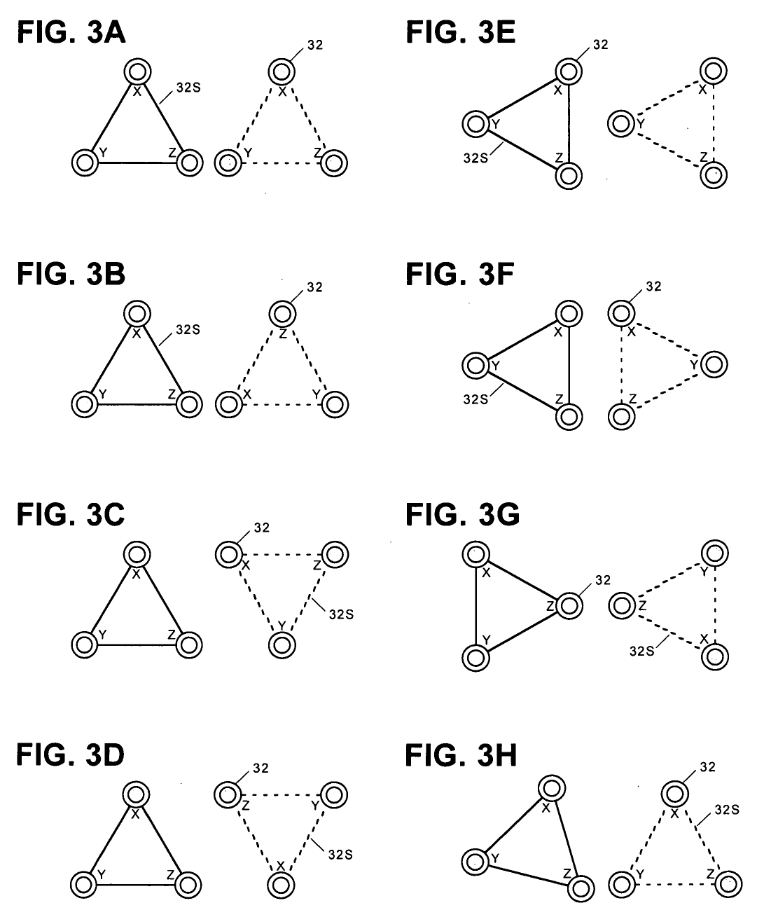

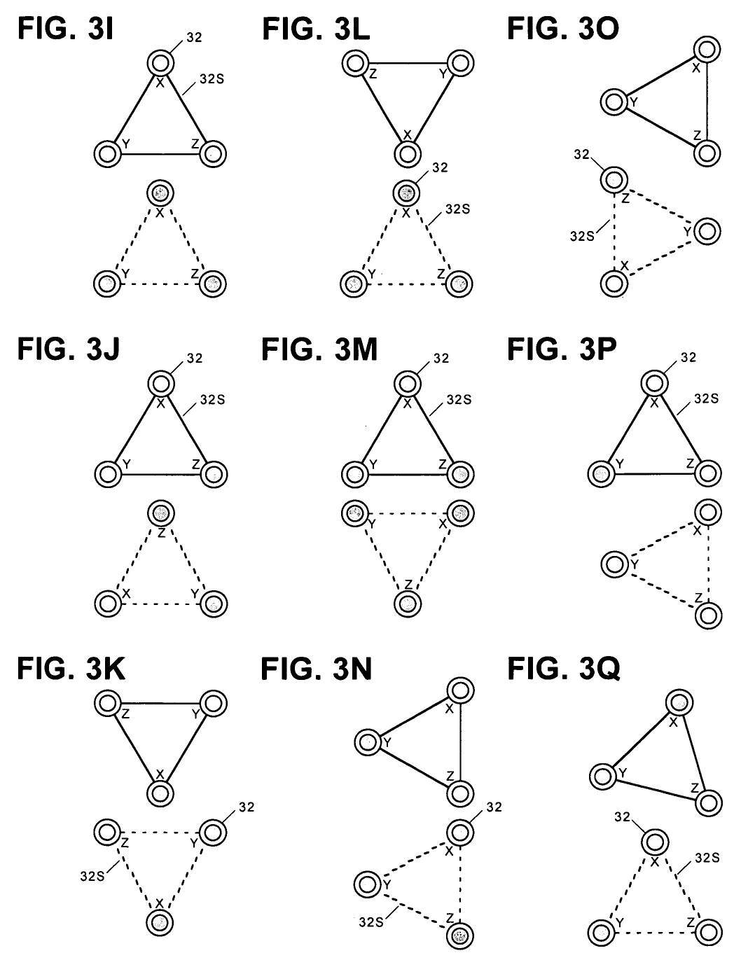

The conventional power grid 30 includes such power transmission lines 32 provided in various dispositions. FIGS. 1B to 1D describe cross-sectional diagrams of power transmission lines provided in various exemplary prior art dispositions when viewed on a plane defined perpendicular to the lines. It is appreciated in these figures that each transmission line 32 is identified as the line of an X phase, a Y-phase or a Z-phase depending upon their phase angles which are apart from each other by about 120°. As shown in FIG. 1B, all three transmission lines 32 may be arranged at the same elevation in a horizontal disposition and, therefore, define a flat plane which is also parallel to a ground. In FIG. 1C, however, the transmission lines 32 are provided in a staggered disposition where at least one line 32 is disposed in a higher elevation than at least another of such lines 32. Therefore, these lines 32 are defined not on a two-dimensional plane as those of FIG. 1B but on a three-dimensional curved plane. In FIG. 1D, the transmission lines 32 are provided in a vertical disposition while being stacked one over the other. These lines 32 also define another flat plane which is normal to the ground. In contrary to those lines of FIGS. 1B and 1C where the system includes a single set of three transmission lines 32, the system of FIG. 3D includes multiple sets of lines, where each set includes three transmission lines 32 disposed in the vertical disposition.

As described above, the three-phase power grid allows transmission of the three-phase AC energies along a longer distance with less loss thereof compared with the single- and dual-phase AC energies. Such three-phase energies inherently include additional desirable properties. Firstly, phase currents accompanying the three-phase energies tend to cancel one another (summing to zero in the case of a linear balanced load). This makes it possible to eliminate neutral conductors on some power transmission lines. Secondly, energy transfer into a linearly balanced load is constant, which helps to reduce generator and motor vibrations at each terminal of the three-phase power grid system. Finally, the three-phase energies produces magnetic fields rotating in a specified direction, thereby simplifying design of electric motors. In addition, three is the lowest phase order to exhibit all of these properties. Most household loads are single phase. Generally, three phase energies either do not enter individual households at all, or where they do, they are split out at a main distribution board.

As described above, the EMC power grid system includes various power transmission lines carrying therealong AC energies over a wide range of AC voltages. Accordingly, electric conductors inside the power transmission lines inevitably irradiate strong electromagnetic waves (to be referred to as the “harmful waves” hereinafter) which are believed to be hazardous to living organisms. That is, such transmission lines constitute wave sources of the power grid, and electric conductors inside the transmission lines serve as the base units thereof. In addition, other parts of such an EMC power grid system such as, e.g., the power station, generators, transmission substation, power substation, and transformers, where these parts generally constitute the “primary base units” of the EMC power grid system. In contrary, other energy-carrying parts of such an EMC system may then constitute the “secondary base units” of the system. It is appreciated that the harmful waves irradiated by the base units of the EMC power grid system are typically extremely low-frequency electromagnetic waves in the frequency ranges of several ten Hz such as, 50 Hz, 60 Hz, and their harmonics. Depending upon configurational and/or operational characteristics, such harmful waves may define the frequencies in the ranges less than 100 Hz, 1 kHz, 5 kHz, 10 kHz, 20 kHz, and the like. Therefore, when the counter unit is arranged to simplify or approximate only one of the above primary base units, the counter unit may be shaped as one or more of various analogs simplifying or approximating one of the base units and counter the harmful waves irradiated from only one of such primary base units. When desirable, two or more of such analogs may be disposed in various locations around at least one of the primary base units or, alternatively, may mechanically and/or electrically couple with each other, supplied with the electrical energy in a preset pattern, disposed in a preset location to counter such harmful waves irradiated by two or more of the primary base units, and the like. Such counter units may be provided as an unitary article which approximates two or more of such primary base units as well.

In order to counter such harmful waves irradiated by various primary and/or secondary base units of the EMC power grid system, at least one counter unit may be selected from the base units or may be incorporated in the system and emit counter electromagnetic waves (to be abbreviated as the “counter waves” hereinafter) in order to counter such harmful waves therewith, e.g., by canceling at least a portion of the harmful waves with such counter waves in a target space and/or suppressing the harmful waves with the counter waves from propagating toward the target space. Thereby, any conventional power grids incorporated with one or more of such counter units may then be converted into the EMC power grid systems of the present invention. Various counter units and their countering mechanisms are now to be enumerated. It is to be understood, however, that following counter units and countering mechanisms of the present invention may be embodied in many other different forms and, accordingly, should not be limited only to the following units and/or mechanisms which are to be set forth hereinafter. Rather, various exemplary counter units and countering mechanisms described hereinafter are provided so that this disclosure is thorough and complete, and fully conveys the scope of this invention to one of ordinary skill in the art. It is also appreciated that various counter units and their countering mechanisms which have been described hereinabove and which are to be disclosed hereinafter may be applied to any conventional power grids exemplified in the above figures, to other prior art power grids which have not been exemplified in the above figures but have been disclosed in conjunction therewith as modifications and/or variations thereof, and the like. Therefore, any of these conventional power grids may be converted into the EMC power grid systems of the present invention by selecting one or more counter units from the base units and/or incorporating thereinto one or more counter units which are to operate in one or more of various countering mechanisms.

In one aspect of the present invention, the EMC power grid system may include multiple power transmission lines provided in various self-countering dispositions and countering the harmful waves irradiated by each other based upon various self-countering mechanisms. More particularly, the self-countering mechanisms aim to minimize averaged and/or peak amplitudes of the harmful waves in the target space, where such amplitudes may be temporally or spatially averaged values or instantaneous values over a time interval or across a preset area or volume (e.g., the target space) and where such peak amplitudes may be temporally or spatially averaged values or instantaneous values over the time interval or across the preset area or volume. Optimum self-countering mechanisms for a given set of power transmission lines may generally be obtained by selecting suitable configurations of such lines (e.g., their longitudinal and/or cross-sectional shapes, sizes, arrangements, and the like), by selecting suitable dispositions of such lines (e.g., their alignments, orientations, distances therebetween in the hypothetical plane, angles therebetween about a center of a hypothetical circle defined by such lines and also defined on the plane, distances to the target space in the plane, angles with respect to such a target space defined on the plane, and the like, where details of these self-countering mechanisms will be disclosed hereinafter. It is appreciated that such optimal self-countering mechanisms generally are those minimizing such averaged or peak amplitudes of the harmful waves in the target space and that there may exist multiple optimal self-countering mechanisms for a given set of transmission lines.

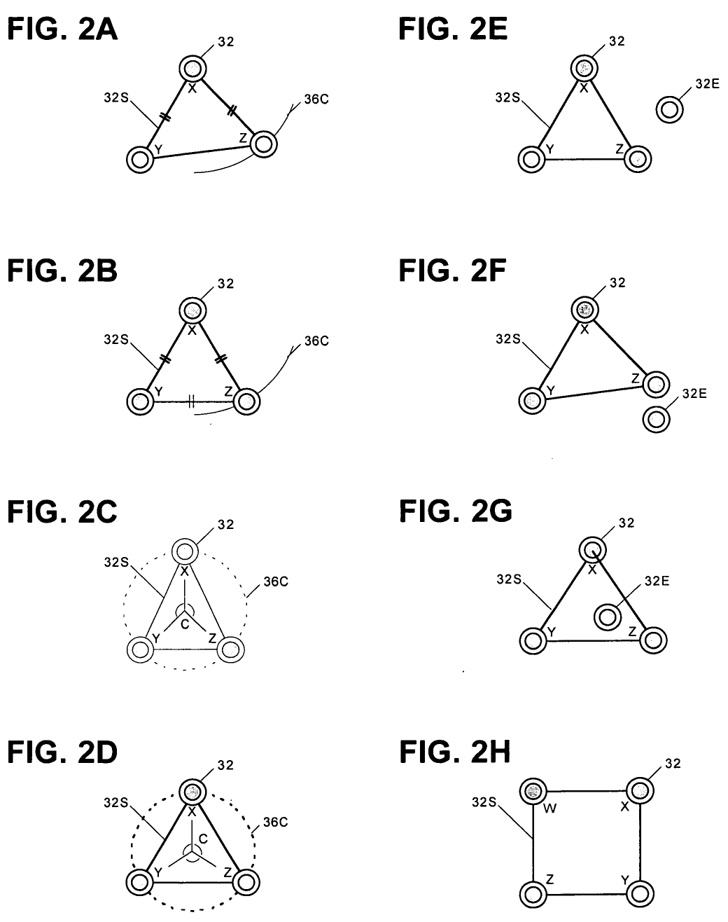

In another aspect of the present invention, various criteria may be developed to assess such optimal self-countering mechanisms for a given set of power transmission lines. In one example, such optimal self-countering mechanisms may be assessed as those minimizing averaged amplitudes of the harmful waves which are irradiated by a single sets of lines in the target space. In one example, the self-countering mechanisms may be accomplished when at least some or all of the transmission lines may be spaced away from one another by a similar (or identical) distance. In another example, such mechanisms may be attained when at least some or all of such lines may be disposed around a center of a circle which is defined by the lines in the plane perpendicular to all of such lines. FIGS. 2A to 2H are schematic cross-sectional views of a single set of exemplary power transmission lines provided in various dispositions for the self-countering according to the present invention. It is appreciated that the cross-sectional views of these figures are viewed on a hypothetical plane which is defined to be perpendicular to all of such transmission lines. It is also appreciated that the figures exemplify various self-countering dispositions for the three-phase power transmission lines but that identical or similar dispositions may further be applied to other multiphase power transmission lines such as, e.g., two-phase, four-phase, five-phase, six-phase, and the like.

In one exemplary embodiment of this aspect of the invention and as also embodied in FIGS. 2A and 2B, three three-phase power lines 32 may be disposed in a triangular disposition where each line 32 serves as a counter unit for other two lines 32, thereby irradiating such harmful waves serving as counter waves which are capable of countering the harmful waves irradiated by other two lines 32. It is hereinafter appreciated in this and other following self-countering dispositions that at least one of such transmission lines (i.e., base units) may be referred to as the counter unit, and that such harmful waves irradiated from the base unit also serving as the counter unit may be referred to as the counter waves. In FIG. 2A, the X-phase and Y-phase lines 32 of a given set 32S of lines are disposed away from each other by a preset distance. A hypothetical circle 36C is then drawn centered around the X-phase line 32 with a radius corresponding to the distance between the X- and Y-phase lines 32. The third Z-phase line 32 is disposed in a location which is defined along an arc of the circle 36C, thereby guaranteeing that a first distance between the X- and Y-phase lines 32 becomes identical to a second distance between the X- and Z-phase lines 32. Accordingly, this self-countering disposition reduces the amplitudes of the harmful waves in the target space, although such a reduction may not be minimal when a distance between such Y- and Z-phase lines deviate from the first and second distances. In FIG. 2B, the X- and Y-phase lines 32 are similarly selected, while the Z-phase line 32 is disposed in an equal distance from both of the X- and Y-phase lines 32 along the arc of the circle 36C. Accordingly, this self-countering disposition may minimize the amplitudes of the harmful waves in the target space, particularly when such transmission lines 32 carry the AC energies of the similar or same amplitudes. It is appreciated that the less efficient disposition of FIG. 2A may become useful when such lines 32 may carry the AC energies of different amplitudes, when the system includes at least one unbalanced line, and the like.

In another exemplary embodiment of this aspect of the invention and as also embodied in FIGS. 2C and 2D, three three-phase power lines 32 may be disposed in another triangular disposition where at least one of the transmission lines may serve as the counter unit while emitting the counter waves. In FIG. 2C, a hypothetical circle 36C is drawn on the plane normal to all transmission lines 32, while the X- and Y-phase lines 32 of a given set 32S of lines are disposed on the circle 36C and spaced away from one another by a preset angle about a center of the circle 36C. The third Z-phase line 32 is then disposed in a location which is also defined on the circle 36C and away from the X-phase line 32 by the same angle about the center of the circle 36C but on an opposite side thereof, thereby forming an isosceles triangle with the set 32S of lines on the plane. Accordingly, this self-countering disposition reduces the amplitudes of the harmful waves in the target space, although such a reduction may not be minimal as the distance between such Y- and Z-phase lines may deviate from the first and second distances. In FIG. 2D, the X- and Y-phase lines 32 are similarly selected around the similar circle 36C, while the Z-phase line 32 is disposed to define the same angle with respect to both of such X- and Y-phase lines 32 along the same circle 36C. Therefore, such a self-countering disposition may minimize the amplitudes of the harmful waves in the target space, particularly when such transmission lines 32 are to carry the AC energies of the similar or same amplitudes. It is appreciated that the less efficient disposition of FIG. 2C may become useful when such lines 32 may carry the AC energies of different amplitudes, when the system includes at least one unbalanced line, and the like.

Other criteria may also be used based upon the foregoing distanced-based and angle-based criteria. For example and as shown in FIG. 2A, such transmission lines may be disposed away from each other by similar but not identical distances, where such distances may deviate from others by no more than a preset length, by no more than a preset percentage, and the like, where the preset length may be 1 cm, 5 cm, 10 cm, 20 cm, 30 cm, 40 cm, 50 cm, 60 cm, 70 cm, 80 cm, 90 cm, 1 m, 2 m, 3 m, 4 m, 5 m, 7 m, 10 m, 15 m, and the like, and where the preset percentage may be 1%, 2%, 3%, 4%, 5%, 7%, 10%, 12%, 14%, 16%, 20%, 25%, and the like. In another example and as shown in FIG. 2C, such lines may be disposed away from each other by similar but not identical angles around the circle, where such angles may deviate from others by no more than a preset angle, by no more than a preset percentage, and the like, where the preset angle may be 1°, 3°, 5°, 7°, 10°, 12°, 15°, 17°, 20°, 25°, 27°, 30°, 35°, 40°, 45°, and the like, and where the preset percentage may be 1%, 2%, 3%, 4%, 5%, 7%, 10%, 12%, 15%, 20%, 25%, and the like. In another example, such transmission lines may be disposed close to each other but not within a preset distance for minimizing undesirable interference among the AC energies carried along such lines, where this preset distance may be similarly selected as the previous distances described in this paragraph. It is appreciated that suitable distances and/or angles may be fixed regardless of the amplitudes of the AC energies transmitted along the lines or that the distances and/or angles may be selected depending on the amplitudes of the AC energies, where shorter distances and/or less angles may be selected as the amplitudes of the AC energies increase or vice versa. It is also appreciated that suitable distances and/or angles may be defined between at least two of such lines or may instead be defined with respect to the target space as well.

In another exemplary embodiment of this aspect of the invention and as embodied in FIGS. 2E to 2G, the system may include a single set of transmission lines and at least one unbalanced line while minimizing the harmful waves irradiated from all of such lines. In FIG. 2E, a single set 32S of lines are arranged in the triangular disposition of FIGS. 2B and 2D, and an unbalanced extra line 32 is disposed away from the set 32S of lines in any arbitrary dispositions. When such an extra line 32E is a neutral line, disposition of the extra line 32E may not affect at all the amplitudes of such harmful waves which are irradiated toward the target space. When the extra line 32E carries the AC energy, however, the disposition of FIG. 2D may allow at least a non-negligible portion of the harmful waves irradiated from the extra line 32E to propagate toward the target space, unless the lines 32 of the given set 32S may transmit the AC energies with different amplitudes, and a sum of such harmful waves irradiated from the set 32S of lines may be countered by the harmful waves irradiated from the extra line 32E. In FIG. 2F, a single set 32S of lines are arranged in the disposition of FIG. 2A, while an unbalanced extra line 32E is disposed close to the Z-phase line 32. By adjusting the distance between the Y- and Z-phase lines 32 of the set 32S, the harmful waves irradiated from the extra line 32E may be countered by the residual harmful waves irradiated by all of the lines 32 of the set 32S but left out due to an ineffective countering among the set 32S of three lines 32. In FIG. 2G, a single set 32S of lines are also arranged in the triangular disposition of FIGS. 2B and 2D, while an unbalanced extra line 32E is disposed inside the set 32S of lines. When the extra line 32E carries the AC energy, the disposition of FIG. 2F allows at least a non-negligible portion of the harmful waves irradiated from the extra line 32E to propagate to the target space, unless the lines 32 of the given set 32S may transmit the AC energies with different amplitudes, and a sum of such harmful waves irradiated from the set 32S of lines may be countered by the harmful waves irradiated from the extra line 32E.

As described above, such self-countering mechanisms for the three-phase transmission lines may be applied to other multiphase transmission lines. In FIG. 2H, a set 32S of four transmission lines 32 are disposed in a rectangular disposition on the plane defined perpendicular to such lines 32 so as to counter the harmful waves one another. Similar to various variations for such three-phase lines 32 of FIGS. 2A to 2G, the four-phase transmission lines 32 may instead be arranged in other quadrilateral dispositions which may include, but not limited to, a rectangular disposition, a parallelogram disposition, a trapezoidal disposition, and the like. Such a set 32S of four-phase lines may further be used with at least one unbalanced extra line as exemplified in the cases of the three-phase lines of FIGS. 2A to 2G. In addition, any of the above criteria described in terms of distances and/or angles may be modified to suit this four-phase transmission lines or other multiphase lines as well. Other configurational and/or operational characteristics of the self-countering mechanisms for these multiphase transmission lines are similar or identical to those of such mechanisms for the three-phase transmission lines.

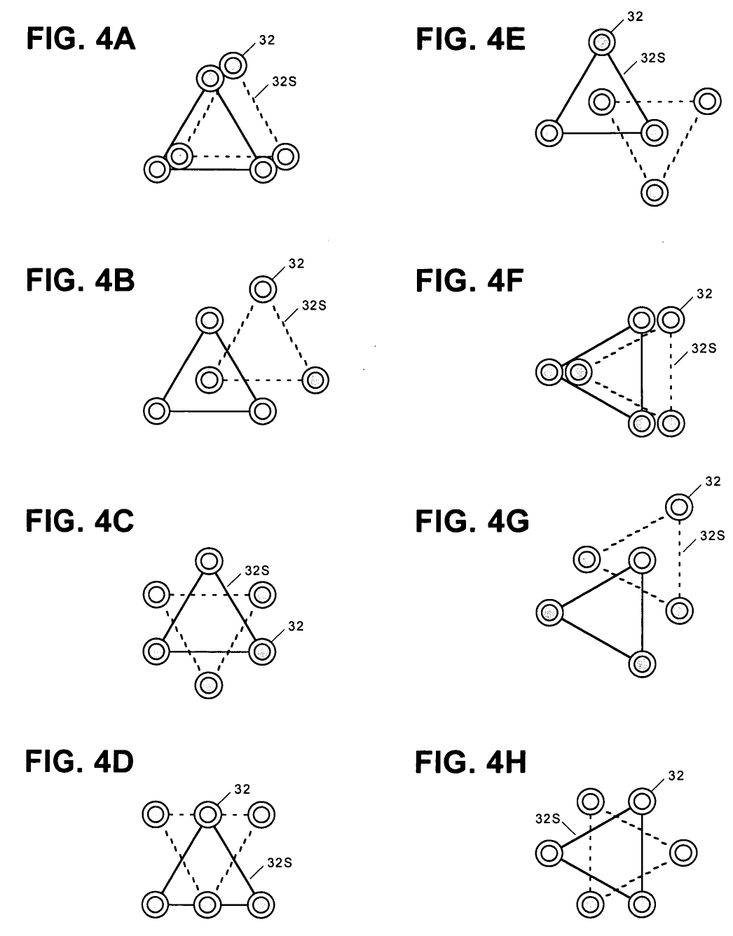

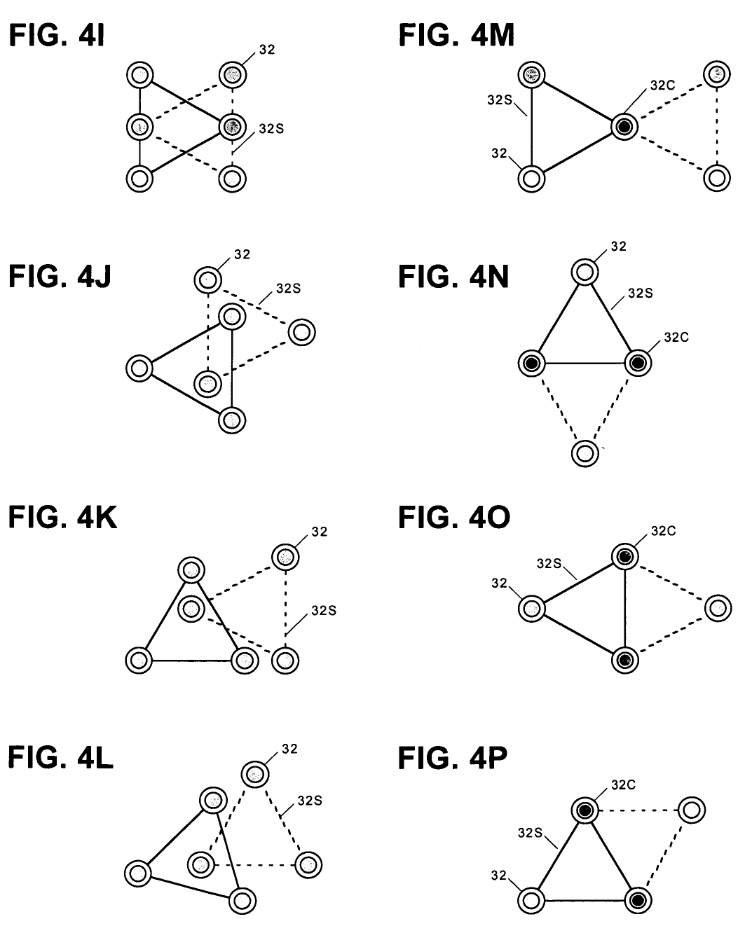

In another aspect of the present invention, various criteria may be developed to assess such optimal self-countering mechanisms for multiple sets of power transmission lines. In one example, the optimal self-countering mechanisms may be assessed as those minimizing averaged amplitudes of the harmful waves which are irradiated from at least two or all sets of the transmission lines in the target space. In another example of FIGS. 3A to 3Q, the optimal self-countering mechanisms may be attained as at least two or all sets of such lines may be spaced away from each other by preset distances. In another example of FIGS. 4A to 4L, the optimal self-countering mechanisms may be obtained when at least two or all sets of the lines may overlap each other in the plane perpendicular to all of the power lines. In another example of FIGS. 4M to 4P, the optimal self-countering mechanisms may be attained as at least two or all sets of lines may be arranged to share at least one common line therebetween. It is appreciated that the cross-sectional views of all of these figures are viewed on the hypothetical plane which is defined to be perpendicular to all of such transmission lines. It is also appreciated that the figures exemplify various self-countering dispositions for multiple sets of the three-phase power transmission lines but that identical or similar dispositions may also be applied to multiple sets of other multiphase power lines such as, e.g., two-phase, four-phase, five-phase, six-phase, and the like. It is further appreciated that various self-countering dispositions developed for a pair of sets of multiphase transmission lines of these figures may readily be expanded to more sets of such transmission lines.

In one exemplary embodiment of this aspect of the invention, multiple sets of multiphase power transmission lines may be provided in horizontal non-overlapping dispositions. FIGS. 3A to 3H show schematic cross-sectional views of multiple sets of exemplary transmission lines in various horizontal dispositions for self-countering according to the present invention. In examples described in FIGS. 3A and 3B, two sets 32S of transmission lines 32 are provided in a horizontal non-overlapping disposition or, more particularly, in a lateral or side by side symmetrical disposition while defining a vertical axis of symmetry therebetween. It is appreciated that such transmission lines of each set 32S in FIG. 3A are arranged in the identical alignment in which the X-phase line 32 of each set is assigned to an apex of each triangular disposition, but that such transmission lines of each set 32S in FIG. 3B are arranged in different alignments. In other examples of FIGS. 3C and 3D, two sets 32S of lines 32 are provided in another horizontal non-overlapping disposition. More particularly, such sets 32S are provided laterally (or side by side) and symmetrically relative to a point of symmetry defined between opposing vertices of such sets 32S. It is appreciated that the X-phase lines 32 of such sets 32S in FIG. 3C are assigned to top portions of the triangular dispositions, while the X- and Z-phase lines 32 of the sets 32S oppose each other in the disposition of FIG. 3D. In other examples of FIGS. 3E to 3G, each set 32S of power transmission lines is in an non-overlapping tilted triangular disposition while assigning one line 32 at its top and another line 32 at its bottom. All sets 32S of lines are disposed in the lateral (or side by side) disposition, where middle lines 32 of both sets 32S point the same side in the triangular disposition of FIG. 3E, point opposite sides in the triangular disposition of FIG. 3F, oppose each other in the triangular disposition of FIG. 3G, and the like. As are the cases in FIGS. 3A to 3D, such transmission lines 32 of each set 32S may further be provided in any of the above alignments. In another example of FIG. 3H, two sets 32S of lines may be disposed in an arbitrary, asymmetrical horizontal disposition.

In another exemplary embodiment of this aspect of the invention, multiple sets of the multiphase power transmission lines may be provided in vertical non-overlapping dispositions. FIGS. 3I to 3Q are schematic cross-sectional views of multiple sets of exemplary transmission lines provided in various vertical dispositions for the self-countering according to the present invention. In examples of FIGS. 3I to 3K, two sets 32S of transmission lines 32 are provided in a vertical non-overlapping disposition or, more particularly, in a vertical or stacked disposition while defining a vertical axis of symmetry running across centers of triangular dispositions. It is appreciated that the transmission lines 32 of each set 32S in FIG. 3I are arranged in the identical upright triangular alignment in which the X-phase line 32 of each set 32S is assigned to an apex of each triangular disposition, but that such transmission lines of each set 32S in FIG. 3J are arranged based on different alignments. In addition, the transmission lines 32 of each set 32S of FIG. 3K are aligned in an inverted triangular disposition. In other examples of FIGS. 3L to 3M, two sets 32S of lines 32 are provided in another vertical non-overlapping disposition. More particularly, such sets 32S are stacked vertically and define a line of symmetry across centers of the triangular disposition of each set 32. It is to be understood that a single line 32 of a top set 32S in an inverted triangular disposition opposes a single line of a bottom set 32S in an upright triangular disposition in FIG. 3L, that a pair of lines 32 of a top set 32S in an upright triangular disposition abut a pair of lines 32 of a bottom set 32S in an inverted triangular disposition in FIG. 3M, and that a single line 32 of a top set 32S in a tilted triangular disposition oppose another single line 32 of a bottom set 32S in a similar tilted triangular disposition in FIG. 3N. In other examples of FIG. 3O, two sets 32S of lines 32 are aligned in opposite tilted triangular disposition while defining a point of symmetry therebetween. In another example of FIG. 3P, a top set 32S of lines is in an upright triangular disposition, while a bottom set 32S of lines is rather in a tilted triangular disposition. In another example of FIG. 3Q, two sets 32S of lines may be disposed in an arbitrary, asymmetrical vertical disposition.

In another exemplary embodiment of this aspect of the invention, multiple sets of the multiphase power transmission lines may be provided in various overlapping dispositions as well. FIGS. 4A to 4L represent schematic cross-sectional views of multiple sets of exemplary transmission lines in various overlapping dispositions for such self-countering according to the present invention. In examples of FIGS. 4A and 4B, two sets 32S of transmission lines 32 are provided in non-overlapping dispositions, where a first set 32S of lines is in an upright triangular disposition, while a second set 32S of lines is in another upright triangular disposition which, however, is misaligned with the first set 32S of lines by a preset distance and by a preset angle. It is appreciated that the transmission lines 32 of such sets 32S are disposed closer to each other in FIG. 4A but that the lines 32 of different sets 32S are spaced away from each other in FIG. 4B. In other examples of FIGS. 4C to 4E, such sets 32S of lines 32 are provided in different overlapping dispositions, where a first set 32S of lines is in an upright triangular disposition, whereas a second set 32S of lines is in an inverted triangular disposition. In addition, the sets 32S of lines overlap each other while defining a hexagonal overall disposition in FIG. 4C, the sets 32S of lines overlap each other while maintaining the same elevations and also defining a rectangular disposition in FIG. 4D, and such sets 32S of lines are misaligned from each other by a preset distance and by a preset angle in FIG. 4E. In other examples of FIGS. 4F and 4G, two sets 32S of transmission lines 32 are provided in other non-overlapping dispositions, where a first set 32S of lines is in a tilted triangular disposition, while a second set 32S of lines is in another triangular disposition tilted along the same direction as that of FIG. 3F which, however, is misaligned with the first set 32S of lines 32 by a preset distance and angle. It is to be understood that the transmission lines 32 of such sets 32S are disposed closer to each other in FIG. 4F but that the lines 32 of different sets 32S are rather spaced away from each other in FIG. 4G. In other examples of FIGS. 4H to 4J, such sets 32S of lines 32 are provided in other overlapping dispositions, where a first set 32S of lines is in a triangular disposition tilted to one direction, while a second set 32S of lines is in a triangular disposition tilted to an opposite direction. In addition, the sets 32S of lines may overlap each other while defining a hexagonal overall disposition in FIG. 4H, the sets 32S of lines overlap each other while maintaining the same widths and also defining a rectangular disposition in FIG. 4I, and such sets 32S of lines are misaligned from each other by a preset distance and by a preset angle in FIG. 4J. In other examples of FIGS. 4 and 4L, two sets 32S of lines provided in other overlapping dispositions, where such sets 32S are overlapping but also misaligned from each other by a preset distance and angle.

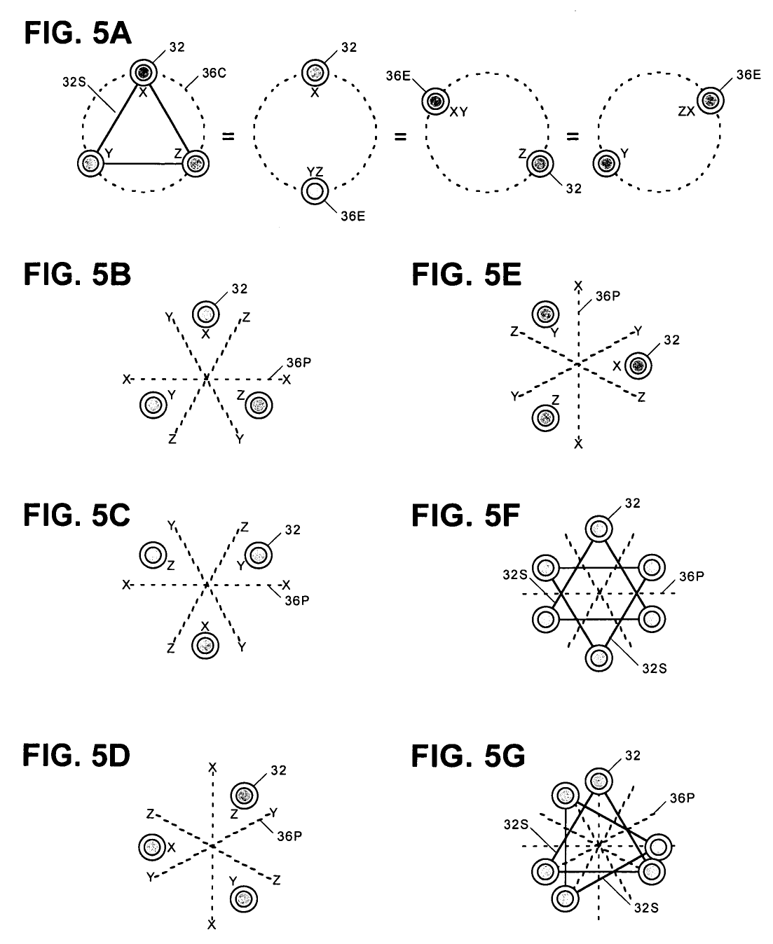

It is appreciated in the foregoing self-countering dispositions of FIGS. 3A to 3Q and FIGS. 4A to 4L that orientation of each set of lines may not be material to such self-countering mechanisms and/or dispositions as long as the transmission lines of each set are provided in any of such self-countering dispositions. In other words, as long as the harmful waves irradiated by at least one transmission line of a given set of lines are effectively countered with the harmful waves irradiated by at least another transmission line of the same set and the overall amplitudes of such harmful waves of the given set of lines are minimized in the target space, such multiple sets of lines may be provided in any of the above horizontal, vertical, non-overlapping or overlapping dispositions. There are a few exceptions to such a generalization. The first exception applies to the sets of lines in which the harmful waves may not be effectively countered in each set of lines. In this case, multiple sets of lines may then be arranged in a suitable disposition where the residual harmful waves irradiated by at least one of such sets may be countered with the residual harmful waves irradiated from at least another of such sets. Another exception relates to peak planes of the harmful waves in which such harmful waves define maximum amplitudes. As will be further described in conjunction with FIGS. 5A to 5G, orientation of each set of lines may become material when it is important to suitably orient such peak planes in the target space for various reasons.

In another exemplary embodiment of this aspect of the invention, multiple sets of the multiphase power transmission lines may be provided in various dispositions in which at least two sets of such transmission lines share at least one common transmission line therebetween. FIGS. 4M to 4P show schematic cross-sectional views of multiple sets of exemplary transmission lines provided in various dispositions and including at least one common line for such self-countering according to the present invention. In one example of FIG. 4M, two sets 32S of transmission lines are provided in an opposing disposition similar to those of FIGS. 3G and 3L in which such sets 32S are provided in the dispositions tilted along opposite directions. In addition, such sets 32S further to share one common transmission line 32C which is arranged to participate in countering the harmful waves irradiated by other two lines of a first set 32S of lines as well as in countering the harmful waves irradiated by other two lines of a second set 32S of lines. Such a shared countering may be attained in a few different embodiments. In one exemplary embodiment, the common line 32C is arranged to transmit one of the multiple phase energies, and other lines 32 of each set 32S are to carry the rest of such multiple phases. Therefore, in the case of the three-phase system of this figure, the common line 32C are to transmit the X-phase energy, whereas other two lines 32 of each set 32S carry the Y- and Z-phase energies. In this case, the common line 32C may have to carry the energy with the amplitudes which are sufficient to counter the harmful waves irradiated from the rest of the lines 32, i.e., four lines 32 in total in the case of this figure. In another exemplary embodiment, two unshared lines 32 of such sets 32S may carry any of multiple phase energies, and the common line 32C may carry a combination of two different energies. In the case of the figure, when the unshared lines 32 carry the X- and Y-phase energies in the first set 32S and the X- and Z-phase energies in the second set 32S, the common line 32C is arranged to transmit the energy which is a combination of the Z-phase energy for the first set 32S and Y-phase energy for the second set 32S. As a result, the common line 32C in this embodiment may transmit the energy of which the amplitudes are different from those of other lines of each set 32S and of which the phase angles are offset from those of the other lines 32 by another angle. In other examples of FIGS. 4N to 4P, two sets 32S of transmission lines 32 are provided in the dispositions in which at least two lines 32 of each set 32S oppose each other, similar to those of FIGS. 3C, 3D, 3F, 3M, and 3O. In addition, such sets 32S also share at least two common transmission lines 32C which are arranged to participate in countering the harmful waves irradiated by an unshared line 32 of a first set 32S as well as in countering the harmful waves irradiated by another unshared line 32 of a second set 32S. More particularly and in FIG. 4N, a first set 32S of lines is in an upright triangular disposition, while a second set 32S of lines is in an inverted triangular disposition, similar to that of FIG. 3M. Furthermore, a pair of common lines 32C are shared by the sets 32S, thereby forming the shared self-countering disposition. In FIG. 4O, a first set 32S of lines is in a tilted triangular disposition, while a second set 32S of lines is in another triangular disposition tilted along an opposite direction similar to that of FIG. 3F, where a pair of common lines 32S are shared by such sets 32S to form another shared self-countering disposition. In FIG. 4P, a first set 32S of lines is in an upright triangular disposition, a second set 32S of lines is in an inverted triangular disposition similar to those of FIGS. 3C and 3D, and a pair of common lines 32C are shared by such sets 32S to form yet another shared self-countering disposition. Similar to that of FIG. 4M, the common lines 32C may transmit a variety of energies depending upon the type of energy carried by the single unshared lines 32 of the first and second sets 32S. When the unshared lines 32 of different sets 32S transmit the energy of the same phase angle, the common lines 32C may transmit the energies of the rest of the phase angles. However, when the unshared lines 32 of different sets 32S transmit the energies with different phase angles, the common lines 32C may have to be adjusted in order to accomplish optimal countering in both sets 32S of lines.

It is to be understood in the foregoing shared self-countering dispositions of FIGS. 4M through 4P that each set may include any number of lines, where the exact number may be determined by the number of phases employed by a given multiphase EMC power grid system. Therefore, each set may then include two, three, four, five, six, and the like. When desirable or when necessary, at least one set of such lines may define the disposition which may not be equilateral triangular, rectangular, and the like. Such common lines may be constructed between two sets of lines, where each set includes a different number of transmission lines. In addition, such common lines may be constructed between different pairs of sets of lines as the system includes more than two of such sets, where each pair of such sets may define an identical or different number of common lines. Other configurational and/or operational characteristics of the shared self-countering dispositions of FIGS. 4M to 4P may be similar or identical to those of the unshared self-countering dispositions of FIGS. 4A to 4L.

It is appreciated in the foregoing unshared and shared self-countering dispositions of FIGS. 3A to 3Q and FIGS. 4A to 4P that such sets may include the same number of transmission lines having the same (or at least substantially similar) shapes and/or sizes as exemplified therein, that such sets may include the same number of transmission lines but defining different shapes and/or sizes. When the EMC power grid system employs more than two sets of transmission lines, all (or at least two) of the sets may include the same number of transmission lines of the same or different shapes and/or sizes. Alternatively, all (or at least two) of such multiple sets may include different numbers of lines with the same or different shapes and/or sizes. The EMC system with multiple sets of transmission lines may also include at least one unbalanced transmission line, where the harmful waves irradiated from the unbalanced line may be countered by one or more sets of the system in various modes as described in conjunction with the system with the single set as in FIGS. 2A to 2H. Other configurational and/or operational characteristics of the self-countering dispositions of multiple sets of lines in FIGS. 3A to 3Q and FIGS. 4A to 4P may be similar or identical to those of the self-countering dispositions of the single set of lines of FIGS. 2A to 2H.

In another aspect of the present invention, additional criteria may be developed to assess such optimal self-countering mechanisms for a given set of power transmission lines. In one example, such optimal self-countering mechanisms may be assessed as those capable of minimizing peak amplitudes of such harmful waves irradiated by a single set of lines in the target space, e.g., by disposing planes of such peak amplitudes as far away from the target space. In another example, such self-countering mechanisms may be assessed as those also capable of minimizing the peak amplitudes of the harmful waves irradiated from multiple sets of lines in the target space, e.g., by disposing the peak planes as far away from the target space or, alternatively, by evenly disposing the peak planes while preventing concentration of such peak planes in the target space. FIGS. 5A to 5G are schematic cross-sectional views of exemplary transmission lines and their peak planes in various dispositions according to the present invention. It is appreciated that the cross-sectional views of these figures are viewed upon a hypothetical plane defined normal to all of the transmission lines. It is also appreciated that the figures exemplify various self-countering dispositions for such three-phase power transmission lines but that identical or similar dispositions may also be applied to other multiphase power transmission lines such as, e.g., two-phase, four-phase, five-phase, six-phase, and the like.

In order to assess spatial dispositions of amplitudes of such harmful waves, the amplitudes of the harmful waves irradiated by all of the lines have to be analyzed. An alternative to such individual analyses is to employ an equivalent transmission line which effectively simulates the wave irradiation from at least two individual transmission lines. FIG. 5A illustrates various modes of constructing such equivalent transmission lines in the setting of the three-phase power transmission lines. In this figure, the X-, Y-, and Z-phase lines 32 of a single set 32S of transmission lines are in a triangular disposition or, more particularly, in an equilateral disposition. Because the AC energies transmitted by the Y- and Z-phase lines 32 are offset from each other by about 120°, a sum of such energies forms another AC energy offset (denoted as “YZ” in the figure) from another AC energy transmitted by the X-phase line 32 by about 180° while defining the amplitudes similar or identical to those of the AC energy carried by the X-phase line 32. Accordingly, an additional transmission line 32E which is equivalent to the sum of the Y- and Z-phase lines 32 may be constructed along a perimeter of a circle which passes through all of such lines 32 on the plane and which is disposed opposite to the X-phase line 32, as exemplified in the panel second to the left. Similarly, another equivalent line 32E for a sum of the X- and Y-phase lines 32 (denoted as “XY” in the figure) may be similarly constructed on the perimeter of the circle and opposite to the Z-phase line 32, as exemplified in the panel second to the right. In addition, yet another equivalent line 32E for the X- and Z-phase lines 32 (denoted as “ZX” in the figure) may be constructed on the perimeter of the circle and opposite to the Y-phase line 32, as illustrated in the rightmost panel. With these equivalent lines, dispositions of the peak planes of such harmful waves may be assessed easily. When the three-phase transmission lines 32 are in the equilateral upright disposition as in FIG. 5B, a first peak plane 36P X-X may be assessed to be disposed horizontally between the X- and YZ-phase lines 32, 32E, a slanted second peak plane 36P Y-Y may be assessed to be disposed between the Y- and ZX phase lines 32, 32E, and another slanted third peak plane 36P Z-Z may be assessed to be disposed between the Z- and XY phase lines 32, 32E. In short, these three peak planes 36P are disposed at every 60° around the set of lines and extend along with the transmission lines 32. In FIG. 5C, the three-phase lines 32 are in the equilateral inverted disposition, while defining the peak planes 36P in the identical dispositions as those shown in FIG. 5B. In FIG. 5D, the three-phase lines 32 are in the equilateral tilted disposition, while defining such peak planes 36P which are disposed at every 60° around the set of lines, extend along with the transmission lines 32, and offset from those of FIGS. 5A and 5B by about 30°. In FIG. 5E, the three-phase lines 32 are in another equilateral tilted disposition but tilted in a direction which is opposite to that of FIG. 5D, while defining the peak planes 36P in the same disposition as those of FIG. 5D. Accordingly, a suitable disposition of the transmission lines 32 may be selected based on the disposition of the target space with respect to those lines 32.

The peak planes of the harmful waves irradiated by multiple sets of transmission lines may be assessed in similar algorithms. For example and as shown in FIG. 5F, a first set 32S of transmission lines is in the equilateral upright disposition, and a second set 32S of lines is in the equilateral inverted disposition. By overlapping the first set 32S over the second set 32S, both sets 32S of lines irradiate the harmful waves defining the peak planes 36P overlapping each other. Accordingly, such sets 32S of lines may be oriented so as to dispose the peak planes 36P as far away from the target space. In another example of FIG. 5G, a first set 32S of transmission lines is in the equilateral upright disposition, while a second set 32S of lines is in the equilateral tilted disposition. By overlapping the first set 32S of lines over the second set 32S, the peak planes 36P formed by the harmful waves irradiated by both sets 32S may be evenly distributed around the lines 32S. This latter embodiment may be useful when it is not feasible to dispose the peak planes 36P away from the target space, for the target space may be wider, for the amplitudes of the peak planes 36P augmented by multiple sets 32S of such lines 32 may exceed threshold amplitudes of the harmful waves.

Configurational and operational variations and/or modifications of the EMC power grid systems and various self-countering mechanisms and dispositions as exemplified in FIGS. 2A to 2H, FIGS. 3A to 3Q, FIGS. 4A to 4P, and FIGS. 5A to 5G and/or as disclosed hereinabove without any accompanying figures also fall within the scope of the present invention.

Various criteria for assessing the optimal self-countering mechanisms and/or dispositions may be calculated in various modes, where amplitudes of the harmful waves measured in the target space over a specific period of time and/or over a specific area or volume may be used as the most popular criteria. In one example, the self-countering criteria may be calculated by averaging such amplitudes over the preset time interval (i.e., temporal averages), by averaging such amplitudes over the preset area or volume (i.e., spatial averages), and the like. In another example, such self-countering criteria may be obtained by identifying peak values of such amplitudes over the preset interval (i.e., temporal peaks) or by identifying the peak values of the amplitudes over the preset area or volume (i.e., spatial peaks). In another example, the self-countering criteria may be obtained by identifying other nominal values of such amplitudes over the preset interval, area or volume, where such nominal values may include, but not be limited to, various wave characteristics of the amplitudes of such harmful waves propagated to or measured in the target space, averages of the wave characteristics averaged over the preset time interval or over the preset area or volume, peak values of such wave characteristics over the preset time interval or over the preset area or volume instantaneous values of such wave characteristics for a specific landmark of such waves, and the like. Additional criteria for assessing such optimal self-countering mechanisms and/or their dispositions may further be obtained in terms of various dispositions of the peak planes on which amplitudes of such harmful waves exhibit maximum amplitudes, where the peak values of the harmful waves may be obtained as one of such averages or instantaneous values as described in this paragraph and as also have been disclosed heretofore.

The aforementioned criteria may be used to assess the optimal self-countering mechanisms or dispositions in various modes. For example, the criteria may be applied to a single set of transmission by assessing the amplitudes and/or peak planes of the residual harmful waves irradiated from the set as a whole after imperfect self-countering. In another example, the criteria may be applied to each set of multiple sets of transmission lines of the system by assessing the amplitudes and/or peak planes of such harmful waves irradiated by each set. Alternatively, such criteria may be applies to at least two or all of such sets of the EMC system as a whole by assessing the residual harmful waves irradiated from such sets after the self-countering in each set and/or after the self-countering among such sets. As described above, one or multiple equivalent lines may be constructed from a greater number of the transmission lines, and the optimal self-countering mechanisms and/or dispositions may be assessed, where the resulting mechanisms and/or dispositions should be identical whether or not employing the equivalence analyses. It is appreciated that the equivalence analyses may refer to the processes of obtaining the equivalent line for multiple transmission lines carrying the AC energies of different phase angles, the processes of obtaining the equivalent line for multiple transmission lines carrying such AC energies of the same phase angle and also of the same or different amplitudes. When desirable or as necessary, different criteria may be employed depending on various factors described hereinabove. With such equivalence analyses, the optimal self-countering mechanisms and/or their dispositions may be easily assessed for any EMC power grid systems which employ any multiphase transmission lines, which include any number of power transmission lines, and/or which also include any number of sets of such lines. It is appreciated that the above equivalence analyses may also be performed based on other wave characteristics other than the amplitudes of the harmful waves and peak planes thereof.

Once assessing the optimal self-countering mechanisms and/or dispositions therefor, the EMC power grid system may then maintain the optimal dispositions among its transmission lines by various means. For example, various retainers may be incorporated along various locations of the system for the purpose of holding and keeping the transmission lines in desirable positions and dispositions with respect to themselves and/or target space. These retainers may be provided in various shapes and sizes as long as they may couple with and retain therein such transmission lines. Accordingly, such retainers may be planar articles defining therein multiple holes through which such lines pass, articles with multiple wings (or arms) defining preset lengths, disposed about preset angles, and coupling with such lines, articles capable of coupling to the transmission towers and/or power poles and coupling with one or multiple lines, and the like. Such retainers may be fixedly coupled to the transmission lines or to preset locations of the transmission towers and/or power poles, thereby always maintaining the lines in fixed locations with respect to the target space. Alternatively, such retainers may instead be arranged to move along such transmission lines, transmission towers, and/or power poles in order to couple with and retain therein such lines in each of multiple locations with respect to the target space. In addition, such retainers may employ various coupling means of fixed shapes and/or sizes, thereby coupling with and retaining therein such transmission lines of preset configurations. In the alternative, such retainers may also include various coupling means of adjustable shapes and/or sizes, thereby coupling with and retaining therein such transmission of different configurations, of different numbers, and the like. Various numbers of such retainers may be incorporated into the EMC power grid system so that the retainers may be disposed in fixed intervals, in varying intervals depending upon weights of the lines and/or amplitudes of the AC energies carried by the lines, and the like. Alignments of such retainers may also depend on those of the transmission lines. Therefore, such retainers are arranged to allow the transmission lines extending straight, helically winding each other, and so on. In addition, such retainers may maintain the transmission lines in different self-countering dispositions depending on various factors described hereinabove, thereby retaining such lines in different dispositions along different portions of the EMC power grid system.

Such retainers may be perform other functions as well. For example, the retainers may retain therein not only those power transmission lines but also other auxiliary lines including the ground (or neutral) lines or wires. A single retainer may retain therein only those transmission lines carrying the AC energies of the same or similar amplitudes. In the alternative, a single retainer may retain therein multiple transmission lines carrying the AC energies of different amplitudes. Such a retainer may also retain therein one or multiple auxiliary lines. Such retainers may be made of and/or include electrically insulative materials and incorporated along the EMC system. Alternatively, any preexisting parts of the EMC system may be modified as the retainers, where examples of such parts may include, but not be limited to, such neutral lines, insulators, mechanical couplers, dividers, taps, bypasses, and the like. Such retainers may also be made of and/or include other materials and define various configurations as long as they perform the desired retaining functions.

In another generic aspect of the present invention, an EMC power grid system includes therein multiple wave sources and at least one counter unit, and counters the harmful waves irradiated from the wave sources with the counter waves emitted by the counter unit. Each of such wave sources includes therein at least one base unit which is a real source of the harmful waves, i.e., irradiating the harmful waves, affecting propagation paths of such harmful waves while maintaining or altering their amplitudes and/or phase angles, and the like, where examples of such base units may include, but not be limited to, a conductive and/or semiconductive article such as a wire, a strip, a plate, a sheet, a ring thereof, a coil thereof, a spiral thereof, a mesh thereof, and the like, all of which irradiate such harmful waves as the electrical energy is supplied thereto, an insulative article such as a wire, a strip, a plate, a sheet, a ring thereof, a coil thereof, a spiral thereof, and a mesh thereof all of which may not carry the electric current but emit the harmful waves when electric voltage is applied thereacross, and the like. Each wave source may include at least one optional part mechanically supporting or retaining its base units but neither irradiating nor affecting the propagation paths of such harmful waves, where examples of the optional parts may include, but not be limited to, a case enclosing one or more of its base units, a protective cover, a coupler, any parts thereof through which such electric current does not flow, any parts thereof across which such voltage is not applied, and the like. The counter unit is arranged to emit the counter waves capable of countering such counter waves, e.g., by canceling the harmful waves and/or by suppressing the harmful waves from propagating in a specific direction. The counter unit may be arranged to counter the harmful waves in every direction from at least one of the base units of the wave source, e.g., above, below and around at least one of the base units. This embodiment, however, may be costly, may not be feasible, and/or may not be necessary, particularly as the EMC power grid system is to be disposed in a specific orientation by an user to be protected from the harmful waves. In such a case, the counter is arranged to counter the harmful waves only in or around a specific target space (or area) which is generally defined between at least one of the base units and the user (or a specific body part thereof).

In order for the counter waves to counter (i.e., cancel and/or suppress) such harmful waves, there are a few prerequisite which the counter waves must satisfy. The first is the phase angles of the counter waves. In general, the counter waves preferably define the phase angles which are at least partially or substantially opposite to those of the harmful waves so that the counter waves may cancel and/or suppress the harmful waves when propagated to the target space from the same side as at least one of the base units. In the alternative, the counter waves may define the phase angles at least partially similar (or identical) to those of the harmful waves so that the counter waves cancel and/or suppress the harmful waves when propagated to the target space from an opposite side of at least one of the base units. When the EMC power grid system includes multiple counter units, each of the counter units may emit the counter waves which have the same, similar or different phase angles. The next is the amplitudes of the counter waves. In contrary to their phase angles which must satisfy the preset relation to those of the harmful waves, the counter waves may have any amplitudes which effectively counter the harmful waves in the target space. When disposed closer to the target space than at least one of the base units, e.g., the counter unit has only to emit such counter waves with the amplitudes less than those of the harmful waves. Conversely, the counter unit disposed farther from at least one of the base units has to emit such counter waves of the amplitudes greater than those of the harmful waves, whereas the counter unit disposed flush with at least one of the base units with respect to the target space has to emit the counter waves with the similar or same amplitudes as the harmful waves. When the EMC system includes multiple counter units, all of its counter units may be disposed in similar distances from at least one of the base units and/or target space or, alternatively, at least two of the counter units may be disposed in different distances from at least one of the base units and/or target space. In addition to the distances and/or dispositions thereof, the counter waves may have various intensities depending upon whether the counter waves counter the harmful waves throughout an entire portion of the target space or only in preset positions inside such a target space. For example, the counter unit preferably emits such counter waves capable of countering the harmful waves throughout the target space as the user may be situated anywhere therein. When the user is to be situated only in preset positions of the target space, however, the counter may then be shaped, sized, arranged, and disposed to emit the counter waves which best counter the harmful waves only in such positions but not with such an efficiency in other positions of the target space.

Once the counter unit is arranged to emit the counter waves defining proper phase angles and amplitudes, such a counter unit may be shaped, sized, arranged, and disposed in order to counter the harmful waves depending on detailed countering mechanisms.

In one example, the counter unit may be shaped, sized, and/or arranged similar (or identical) to at least one of such base units, where such a mechanism is to be referred to as a “source matching” hereinafter. The basic concept of the “source matching” is that the counter unit may emit the counter waves defining wavefronts similar to its configuration (i.e., its shape, size, and/or arrangement), that wavefronts of such counter waves may automatically match wavefronts of the harmful waves, and that the counter waves counter the harmful waves due to the similarity between the configurations of the counter unit and at least one of such base units. When the system includes multiple base units, a single counter unit may then be arranged to emit the counter waves capable of countering the harmful waves irradiated by one of the base units or, alternatively, capable of countering a sum of the harmful waves irradiated by all (or at least two but all) of such base units. When the system includes multiple counter units, the counter units may emit the counter waves capable of countering the harmful waves irradiated by a single base unit or multiple base units. When the system includes multiple counter units and multiple base units, the counter waves emitted by each counter unit may also counter the harmful waves irradiated by each base unit, a sum of the counter waves emitted by at least two counter units may counter the harmful waves irradiated by one of the base units, the counter waves emitted by a single counter unit may counter a sum the harmful waves irradiated by at least two base units, a sum of the counter waves from all of the counter units may counter a sum of the harmful waves irradiated by all (or at least two but not all) of the base units, and so on. It is preferred in this “source matching” that the counter unit emit the counter waves defining the wavefronts with a configuration (or pattern) similar to the configuration (or pattern) of itself. However, it is also possible that the counter unit emits the counter waves defining the wavefronts with a configuration (or pattern) different from that of the counter unit, that the wavefronts of a sum of the counter waves emitted by multiple counter units may form the configuration different from that of each counter unit and/or define the arrangement different from that of multiple counter units, as long as the counter waves may effectively counter the harmful waves in the target space.

In another example, the counter unit may be disposed (i.e., oriented, aligned, and/or positioned) in a manner that at least one wavefront of such counter waves may match at least one wavefront of the harmful waves, where this mechanism is to be referred to as a “wave matching” hereinafter. The basic concept of the “wave matching” lies in the fact that the counter waves may counter the harmful waves when the counter unit is incorporated in a disposition to match the wavefronts of the counter waves with the wavefronts of the harmful waves as far as the configuration of the counter unit may be properly manipulated so as to operate on the “wave matching.” When the EMC power grid system includes multiple base units, a single counter unit may be arranged to emit the counter waves which are capable of matching and countering the harmful waves irradiated by only one of the base units or, alternatively, matching and countering a sum of the harmful waves irradiated by all (or at least two but not all) of the base units. When the system includes multiple counter units, the counter units may emit the counter waves capable of countering the harmful waves irradiated by a single base unit or all (or at least two but not all) of the base units. When the system includes multiple counter units and multiple base units, the counter waves emitted by each counter unit may counter the harmful waves irradiated by each base unit, a sum of the counter waves emitted by at least two counter units may counter the harmful waves irradiated by one of the base units, the counter waves from a single counter unit may counter a sum the harmful waves irradiated by at least two base units, a sum of the counter waves emitted by all of the counter units may then counter a sum of the harmful waves irradiated by all of the base units, and the like, as long as at least a portion of at least one of such wavefronts of the counter waves may match and then counter at least a portion of at least one of the wavefronts of the harmful waves in the target space.

Various counter units constructed based on the source matching and/or wave matching are to be disclosed hereinafter. It is appreciated in the source matching that there does not exist any one-to-one correlations between the configuration of such a counter unit and the configuration of the counter waves emitted thereby. That is, the counter waves of certain configuration (or wave characteristics) may be obtained by a single counter unit which defines a certain shape and size and is provided in a certain arrangement, by another counter unit which defines a similar shape and size but is provided in another arrangement, by another counter unit which has a different shape and size but is provided in a similar arrangement, by at least two counter units defining preset shapes and sizes and provided in a preset arrangement, by the same number of counter units defining different shapes and/or sizes or in a different arrangement, by a different number of counter units defining similar shapes and/or sizes or in a similar arrangement. It is similarly appreciated in the above wave matching that there does not exist an one-to-one correlation between the disposition of the counter unit and the wavefronts of the counter waves emitted by the counter unit. In other words, the wavefronts with certain shapes may be obtained by a single counter unit which defines a certain configuration and is disposed in a certain position with respect to at least one of such base units and/or target space, by another single counter unit defining another configuration and also disposed in another position, by at least two counter units defining preset configurations and disposed in preset positions, by the same number of counter units defining different configurations and disposed in different positions, by a different number of counter units defining different configurations and disposed in different positions, and the like. Therefore, it is appreciated that such counter units may be embodied in many other different forms and should not be limited to following aspects and/or their embodiments which are to be set forth herein. Rather, various exemplary aspects and/or embodiments described herein are provided so that this disclosure will be thorough and complete, and fully convey the scope of the present invention to one of ordinary skill in the relevant art.

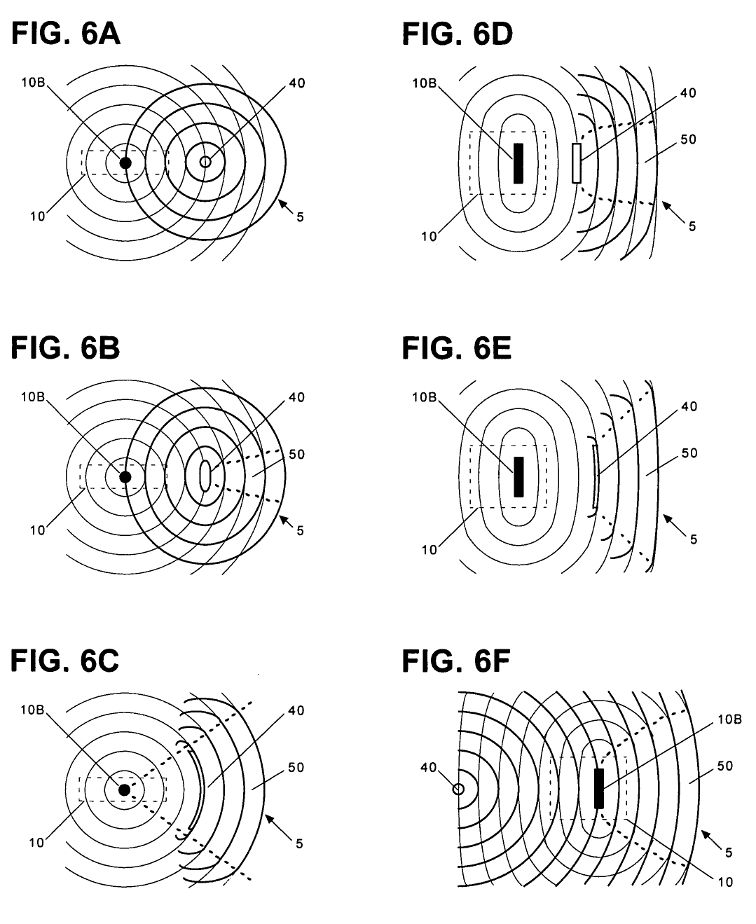

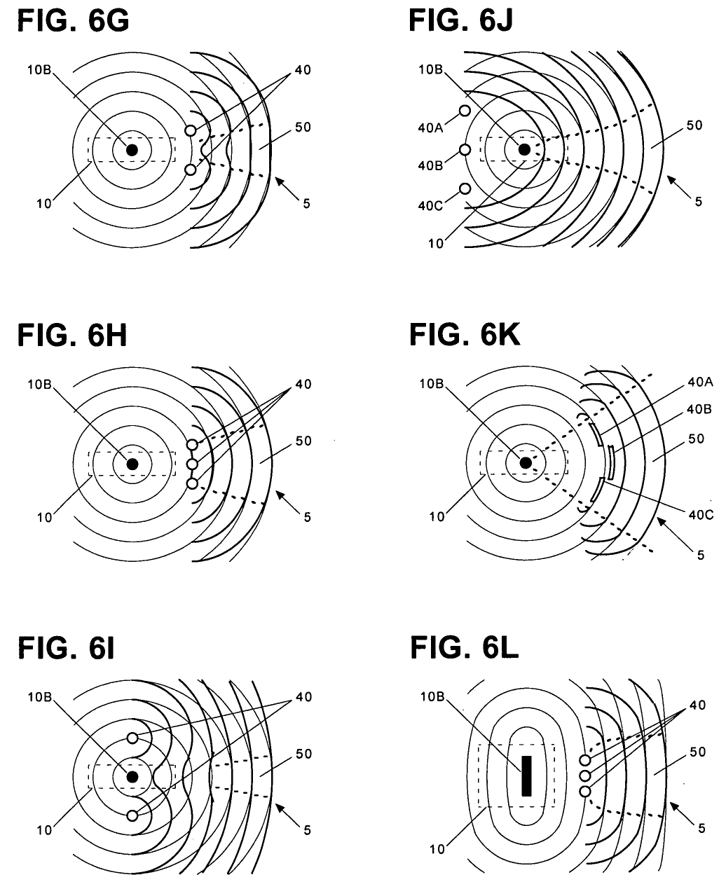

In another aspect of the present invention, a single generic counter unit may be provided for a single generic base unit to counter the harmful waves from the base unit by the counter waves from the counter unit. FIGS. 6A to 6F show top schematic views of exemplary electromagnetic countering mechanisms in each of which a single counter unit emits the counter waves capable of countering the harmful waves which are irradiated from a single base unit of a single wave source according to the present invention, where the base unit is a point source in FIGS. 6A to 6C and 6F, while the base unit is an elongated source in FIGS. 6D and 6E. It is appreciated that these figures, however, may also be interpreted in different perspectives. For example, such figures may be interpreted as the top cross-sectional views, where the base units of FIGS. 6A to 6C and 6F are wires extending perpendicular to the sheet, and the base units of FIGS. 6D and 6E are strips or rectangular rods also extending normal to the sheet. In another example, the figures may be interpreted as sectional views of more complex articles, where the base units of FIGS. 6A to 6C and 6F may correspond to sections of coils, spirals, meshes, and the like, while the base units of FIGS. 6D and 6E may similarly correspond to sections of curvilinear rods or strips. It is also appreciated in these figures that such base units are enclosed in the wave sources which may be cases or other parts of such a system which do not irradiate such harmful waves. It is further appreciated in all of these figures that the EMC systems are disposed in such a way that the target space is formed to the right side of the counter and base units.

In one exemplary embodiment of such an aspect of the invention and as described in FIG. 6A, an EMC system 5 includes a single rectangular wave source 10 and a single counter unit 40, where the source 10 includes therein a single base unit 10B defining a shape of a point source. The counter unit 40 is similarly shaped as another point source and disposed to the right side of the base unit 10B. In this arrangement, the counter unit 40 emits the counter waves of which wavefronts are identical to those of the harmful waves irradiated by the base unit 10B. Because the counter unit 40 is disposed closer to a hypothetical target space on the right side of the figure, such counter wavefronts always define radii of curvature smaller than those of the harmful wavefronts. Accordingly, the counter unit 40 may counter (i.e., cancel or suppress) the harmful waves only along a line connecting the counter and base units 40, 10B or in its vicinity. It is appreciated that such an embodiment corresponds to the source matching which turns out to be ineffective due to a discrepancy in the radii of curvature of the wavefronts of the counter and harmful waves.

In another exemplary embodiment of this aspect of the invention and as depicted in FIG. 6B, an EMC system 5 includes a single counter unit 40 and a single rectangular wave source 10 with a single base unit 10B disposed therein. The base unit 10B is similar to that of FIG. 6A, however, the counter unit 40 is elongated, oriented vertically along its length, and disposed on the right side of the base unit 10B. Due to its elongated shape, the counter unit 40 emits the counter waves whose wavefronts are also elongated vertically and, therefore, define the radii of curvature which are greater than those of FIG. 6A and which match those of the harmful waves. Accordingly, such a counter unit 40 defines a target space 50 across which the counter waves counter the harmful waves to a preset extent. It is to be understood that such an embodiment corresponds to the wave matching mechanism in that the counter unit 40 is shaped similar to one of the harmful wavefronts.

In another exemplary embodiment of this aspect of the invention and as depicted in FIG. 6C, an EMC system 5 includes a single counter unit 40 and a single rectangular wave source 10 with a single base unit 10B disposed therein. The base unit 10B is similar to that of FIG. 6A, however, the counter unit 40 is shaped and sized to conform to one wavefront of such harmful waves. That is, the counter unit 40 is shaped as an arc and disposed in an orientation concave to the right side of the figure or to the target space 50. Because of its arcuate shape, such a counter unit 40 emits the counter waves of which wavefronts are also arcuate and, therefore, define the radii of curvature which are similar or identical to those of the harmful waves. Therefore, the counter unit 40 defines a target space 50 across which the counter waves counter the harmful waves to a preset extent. It is appreciated that such an embodiment corresponds to another wave matching mechanism and that the counter waves emitted form this arcuate counter unit 40 better match such harmful wavefronts and define the target space 50 which expands over a wider angle around the base unit 10B than those of FIGS. 6A and 6B.

In another exemplary embodiment of this aspect of the invention and as depicted in FIG. 6D, an EMC system 5 includes a single counter unit 40 and a single rectangular wave source 10 with a single base unit 10B. Contrary to those of the above, this base unit 10B is rectangular and oriented vertically along its length or its long axis, and irradiates the harmful waves of which wavefronts define vertical and relatively straight portions which are attributed to the length or long axis of the base unit 10B. The counter unit 40 is shaped and sized similar or identical to the base unit 10B, and disposed in the same orientation as the base unit 10B. This orientation may be viewed to dispose the counter unit 40 along the vertical straight portions of the wavefronts of the harmful waves. The counter unit 40 also emits the counter waves whose wavefronts define vertical and relatively straight portions, similarly due to the length or long axis thereof. Because such portions of the counter wavefronts match those of the harmful wavefronts, the counter unit 40 forms the target space 40 to the right side. This embodiment corresponds to the source matching, wave matching or their combination. It is to be understood that the counter unit of FIG. 6A is shaped and sized as the base unit but ineffective due to a discrepancy in the radii of curvature between the wavefronts of the counter and source waves. The counter unit 40 of this embodiment is similarly shaped and sized as the base unit 10B but efficiently counter such harmful waves in the target space 50. The primary reason of this countering lies in the fact that both of the harmful and counter waves define along their wavefronts the vertical straight portions which generally do not depend upon the radii of curvature thereof. Otherwise, configuring the counter unit 40 similar to the base unit 10B and then disposing such a counter unit 10 between the base unit 10B and target space generally do not provide an efficient countering, where further details of this front arrangement are to be provided below. It is appreciated that such an embodiment corresponds to the source matching in which the counter unit 40 is shaped, sized, and/or arranged similar (or identical) to the base unit 10B.

In another exemplary embodiment of this aspect of the invention and as depicted in FIG. 6E, an EMC system 5 includes a single counter unit 40 and a single rectangular wave source 10 with a single base unit 10B which is similar to that shown in FIG. 6D. The counter unit 40, however, is shaped and sized to conform to one wavefront of such harmful waves. Similar to that of FIG. 6C, the counter unit 40 is shaped as an arc and disposed in an orientation concave to the right side of the figure or target space 50. Because of its arcuate shape, such a counter unit 40 emits such counter waves of which wavefronts are also arcuate and, therefore, define the radii of curvature which are similar or identical to those of the harmful waves, not only along their vertical straight portions but also along their curved portions, mainly due to the arcuate shape of the counter unit 40. Accordingly, such a counter unit 40 defines a target space 50 which also expands over a wide angle therearound and across which the counter waves effectively counter such harmful waves. It is to be understood that this embodiment corresponds to another wave matching mechanism.

In another exemplary embodiment of this aspect of the invention and as depicted in FIG. 6F, an EMC system 5 includes a single counter unit 40 and a single rectangular wave source 10 which has a single base unit 10B therein. Both of the counter and base units 40, 10B are identical to those of FIG. 6A. However, the counter unit 40 is disposed on an opposite side of a target space 50 with respect to the base unit 10B and aligned with the base unit 10B as are the cases with the preceding figures. In this arrangement, the counter unit 40 emits the counter waves of which wavefronts are identical to those of the harmful waves irradiated by the base unit 10B. Because the counter unit 40 is disposed farther away from the target space 50, such counter wavefronts define the radii of curvature which approach and then match those of the harmful wavefronts when disposed at a proper distance from the base unit 10B. Accordingly, the counter unit 40 disposed in this rear arrangement may effectively counter the harmful waves and defines the target space 50 expanding over a wide angle around the base unit 10B. It is appreciated that the sole difference between the counter units of FIGS. 6A and 6F is their dispositions, i.e., one disposed in the “front arrangement” of FIG. 6A and another disposed in the “rear arrangement” of FIG. 6F. It is also appreciated that the rear arrangement is not necessarily superior to the front arrangement and that further details of selecting the proper arrangement are to be provided below. It is further appreciated that this embodiment corresponds to the wave matching in which the counter unit 40 is disposed at the position for matching the harmful wavefronts with the counter wavefronts.

Although not included in the figures, a single counter unit may be disposed in an arrangement flush with the base unit with respect to the target space, flush with a direction of propagation of the harmful waves, flush with another direction along which electric current flows in the base or counter unit, flush with another direction in which electric voltage is applied across the base or counter units, and so on. In this “lateral” arrangement, the radii of curvature of the counter wavefronts automatically match those of the harmful wavefronts and, therefore, the counter waves effectively match and then counter the harmful waves in the target space. For this arrangement, however, the wave source has to provide a space in which the counter unit may be incorporated. Therefore, the counter unit may be implemented inside the wave source and close to the base unit thereof when applicable. Otherwise, the counter unit may instead be disposed over, below or beside the wave source and as close to the base unit as possible. It is appreciated, however, that the counter unit disposed next to the base unit may propagate the counter waves onto the base unit and obstruct normal operation of the base unit. Accordingly, the lateral arrangement is preferably selected only when such an arrangement may not obstruct the normal operation of the base unit, wave source including such or EMC system including such. When the lateral arrangement does not affect the operation of the base unit but the counter unit may not be disposed close to the base unit due to space limitations, two or more counter units may be disposed on opposing sides (e.g., left and right, top and bottom, front and rear, and the like) of such a base unit and as close to the base unit as possible. Such counter units may also be arranged to emit the counter waves a sum of which may be symmetric or skewed toward a preset direction based on the wave characteristics of the harmful waves.

In another aspect of the present invention, multiple generic counter unit may be provided for a single generic base unit for countering the harmful waves irradiated by the base unit with the counter waves emitted by all of such counter units or emitted by at least two but not all of such counter units. FIGS. 6G to 6L are top schematic views of exemplary electromagnetic countering mechanisms in each of which multiple counter units emit counter waves to counter harmful waves irradiated from a single base unit of a single wave source according to the present invention, where the base unit is a point source in FIGS. 6G to 6K, while the base unit is an elongated source in FIG. 6L. It is appreciated that these figures, however, may also be interpreted in different perspectives. For example, such figures may be viewed as the top cross-sectional views, where the base units of FIGS. 6G to 6K are wires extending perpendicular to the sheet, and the base unit of FIG. 6L is a strip or a rectangular rod also extending normal to the sheet. In another example, the figures may be interpreted as sectional views of more complex articles, where the base units of FIGS. 6G to 6K may correspond to sections of coils, spirals, meshes, and the like, whereas the base unit of FIG. 6L may similarly correspond to sections of curvilinear rods or strips. It is also appreciated in these figures that such base units are enclosed in the wave sources which may be cases or other parts of such a system which do not irradiate such harmful waves. It is further appreciated in all of these figures that the EMC systems are disposed in such a way that the target space is formed to the right side of the counter and base units.

In one exemplary embodiment of such an aspect of the invention and as described in FIG. 6G, an EMC system 5 includes two counter units 40 and a single wave source 10 including a single base unit 10B. The base unit 10B is similar to those of FIGS. 6A to 6C, while a pair of counter units 40 are disposed between the base Ni 10B and a target space 50. Such counter units 40 are also disposed symmetric to the base unit 10B and flush with each other with respect thereto, i.e., the counter units 40 are disposed at an equal distance from the base unit 10B and/or target space 50. Such counter units 40 are arranged to emit the counter waves of the same phase angles so that the wavefronts of the counter waves from each counter unit 40 are superposed onto each other while increasing their amplitudes. As the counter waves propagate, their wavefronts which correspond to a sum of each set of wavefronts from each counter unit 40 increase their radii of curvature as if they are emitted by the elongated counter units of FIGS. 6B to 6E. Therefore, the counter wavefronts match the harmful wavefronts, and the pair of counter units 40 match and counter the base unit 10B while defining the target space 50 expanding over a limited angle therearound. It is to be understood that disposing two or more counter units 40 result in flattening the wavefronts of the counter waves and increasing the radii of curvature of the superposed portions of the counter wavefronts. It is further appreciated that this arrangement corresponds to the wave matching in which multiple counter units 40 are disposed along one wavefront of the harmful waves.

In another exemplary embodiment of this aspect of the invention and as depicted in FIG. 6H, an EMC system 5 includes three counter units 40 and a single wave source 10 enclosing therein a single base unit 10B. The base unit 10B is similar to those of FIGS. 6A to 6C, while the counter units 40 are similar to those of FIG. 6G such that all counter units 40 are disposed between the base unit 10B and target space 50 and flush with the base unit 10B. However, the system 5 includes one more counter unit 40 so that an array of three counter units 40 approximate the wavefronts of such harmful waves better than those of FIG. 6G. Accordingly, the counter units 40 emit the counter waves which better counter the base unit 10B and define the target space 50 expanding over a wider angle therearound than those of FIG. 6G. It is appreciated that disposing three counter units 40 result in further flattening the superposed wavefronts of the counter waves and also result in increasing the radii of curvature of such portions of the wavefronts of the counter waves. It is also appreciated that this arrangement is another wave matching where all three counter units 40 are disposed along one wavefront of the harmful waves.

In another exemplary embodiment of this aspect of the invention and as depicted in FIG. 6I, an EMC system 5 includes two counter units 40 and a single wave source 10 including a single base unit 10B which is similar to those of FIGS. 6A to 6C. Two counter units 40 are disposed on opposite sides of the base unit 10B at an equal distance therefrom and also flush with the base unit 10B with respect to a target space 50. Similar to those of all of the preceding embodiments, such counter units 40 emit the counter waves defining the similar or identical phase angles so that the counter waves emitted by each of such counter units 40 superpose onto each other for not only increasing their amplitudes but also flattening the superposed portions of their wavefronts while increasing the radii of curvature of such wavefronts. Accordingly, the counter units 40 counter the harmful waves and define the target space 50 spanning around a rather limited angle therearound. It is appreciated that this arrangement is rather the source matching than the wave matching in that the counter units 40 are disposed in the symmetric arrangement and effect the elongated counter unit arranged flush with the base unit 10B.

In another exemplary embodiment of this aspect of the invention and as depicted in FIG. 6J, an EMC system 5 includes three counter units 40 and a single wave source 10 enclosing therein a single base unit 10B which is similar to those of FIGS. 6A to 6F. Contrary to those of FIG. 6H, three counter units 40 are disposed on an opposite side of a target space 50 with respect to the base unit 10B. The counter units 40 are arranged flush with each other relative to the base unit 10B and target space 50 and also spaced away from each other at an equal distance. Similar to those of FIGS. 6G to 6I, both of outer counter units 40A, 40C are arranged to emit the counter waves defining the phase angles at least partially opposite to those of the harmful waves so that superposed portions of the wavefronts of the counter waves are flattened while increasing their radii of curvature. Contrary to those of the preceding figures, a middle counter unit 40B is arranged to emit the counter waves defining the phase angles which are at least partially similar to those of such harmful waves and opposite to those of the counter waves emitted by the outer counter units 40A, 40C. Therefore, a net effect of incorporating the middle counter unit 40B is to sharpen the curvature of the superposed portions of the wavefronts of a sum of the counter waves and to define the target space 50 expanding around a narrower angle around the base unit 10B, as manifest in a comparison between the target spaces 50 of FIGS. 6F and 6J. That is, by incorporating multiple counter units 40A-40C emitting the counter waves of the phase angles opposite to each other, it is feasible to precisely manipulate the wavefronts of the sum of such counter waves and their radii of curvature for better matching the wavefronts of the harmful waves. It is appreciated that such an embodiment may corresponds to the source matching, wave matching or a combination thereof.

The counter units 40A-40C of this embodiment may be incorporated in different arrangements. For example, only two counter units may be included to emit the counter waves with opposite phase angles, where resulting wavefronts of the sum of the counter waves are not symmetric but skewed to one or an opposite side. In addition, the distances between the counter units may be manipulated to adjust the wavefronts of a sum of the counter waves regardless of the number of the counter units. Moreover, the counter units emitting the counter waves defining the phase angles similar to those of the harmful waves may be employed as the outer units to further sharpen the superposed portions of the counter waves.

In another exemplary embodiment of this aspect of the invention and as depicted in FIG. 6K, an EMC system 5 includes three counter units 40 and a single wave source 10 enclosing therein a single base unit 10B which is similar to those of FIGS. 6A to 6C. The counter units 40A-40C are also similar to those of FIG. 6H so that all of such counter units 40A-40C are disposed between the base unit 10B and target space 50 and similar to each other, that the counter units 40A-40C emit the counter waves of the same or similar phase angles, and so on. However, each counter unit 40A-40C is arranged to form an arcuate article shaped and sized to match a portion of a wavefront of the counter waves. In addition, both of upper and lower counter units 40A, 40C are spaced away from each other and also disposed along one wavefront of the harmful waves, whereas a middle counter unit 40B is disposed between the upper and lower counter units 40A, 40C and along an adjacent wavefront of the harmful waves in such a manner that superposed portions of the wavefronts of a sum of the counter waves are flattened while defining larger radii of curvature and match the wavefronts of the harmful waves, thereby forming a target space 50 which expands over a wide angle around the base unit 10B. It is to be understood that this arrangement is another wave matching where all three counter units 40A-40C are disposed along multiple wavefront of the harmful waves.

In another exemplary embodiment of this aspect of the invention and as depicted in FIG. 6L, an EMC system 5 includes three counter units 40 and a single wave source 10 enclosing therein a single base unit 10B. While the base unit 10B is similar to those of FIGS. 6D and 6E, the counter units 40 are similar to those of FIG. 6H and emit the counter waves which are flattened and define vertical straight portions therealong. Therefore, the counter waves match the vertical straight portions of the harmful waves and define a target space 50 similar to that of FIG. 6D. It is appreciated that this embodiment is another source matching in which three counter units 40 approximate the elongated base unit 10B.

In another aspect of the present invention, a single generic counter unit may also be provided for multiple generic base units for countering the harmful waves from such base units by the counter waves from the counter unit. In one example, such a counter unit may be arranged to counter a sum of the harmful waves irradiated by each base units, where detailed disposition of the counter unit may depend upon configurations and/or dispositions of the base units, amplitudes and/or directions of the harmful waves irradiated by such base units, and the like. Based thereupon, the counter unit may be disposed symmetrically to all or at least some of the base units, may be incorporated in the front, rear or lateral arrangement, and the like, where such arrangements are generally referred to an “global or overall countering” hereinafter. In another example, the counter unit is rather arranged to counter the harmful waves irradiated by only one of multiple base units, where such an arrangement is generally referred to as “local or individual countering” hereinafter. This local countering may only be effective when other uncountered base units irradiate negligible amounts of such harmful waves, when other uncountered base units irradiate non-negligible amounts of the harmful waves to other directions than the target space, and the like. Otherwise, it is preferred to manipulate the counter unit to counter the harmful waves of the uncountered base units, to include additional counter units for countering those harmful waves, and the like.

It is appreciated that various countering mechanisms described hereinabove for a single base unit may equally be applied to the system with multiple base units in the global countering mechanism. That is, the above countering mechanisms may be applied not to such harmful waves irradiated by the single base unit but to a sum of the harmful waves irradiated by multiple base units. When the system is to operate in the local countering mechanism, the aforementioned mechanisms may also be applied to each of multiple base units regardless of an exact number of such base units.

In another aspect of the present invention, multiple counter units may be provided for multiple base units for countering the harmful waves irradiated from such base units with the counter waves emitted by the counter units. In one example, multiple counter units are provided in the same number as the base units and each counter unit is arranged to counter only one of such base units in the local countering mechanism. Alternatively, at least one of such counter units may counter only one of such base units in the local countering mechanism, whereas at least one another of such counter units may counter at least two of the base units in the global countering mechanism. In another example, a less number of counter units are provided so that each counter unit is arranged to counter at least two of the base units in the global countering mechanism, that at least one of the counter units counters one of such base units in the local countering mechanism while at least one another of such counter units counters at least two of such base units in the global countering mechanism, and the like. In another example, a greater number of counter units are provided so that each base unit may be countered by at least two of the counter units, that at least one of the counter units counters one of the base units in the local countering mechanism while at least one another of the counter units may counter at least two of such base units in the global countering mechanism, and so on. In all of these examples, any of the above front, rear, and lateral countering mechanisms may be used by the counter units, where such countering mechanisms may be same or different for each counter unit.

Configurational and/or operational variations of such EMC systems and their counter units as well as configurational and/or operational modifications of such EMC systems and their counter units as exemplified in FIGS. 6A to 6L and/or as disclosed hereinabove without any accompanying figures also fall within the scope of the present invention, and have already been disclosed in detail in the co-pending Applications. Accordingly, such variations and modifications are to be omitted herein.

The EMC power grid systems of the present invention may typically be designed for countering the harmful waves in a carrier frequency range or an extremely low frequency range from about 50 Hz to about 60 Hz or another frequency range of less than about 300 Hz including harmonics of such carrier frequencies. Therefore, in the preferred embodiment of this invention, various counter units of the EMC power grid systems are arranged to emit the counter waves in such carrier frequency range or extremely low frequency range of from about 50 Hz to about 60 Hz or the frequency range of less than about 300 Hz, thereby effectively countering the harmful waves falling in the frequency ranges. Considering various medical findings and/or presumptions that a main culprit of the harmful waves are those in these frequency ranges, the counter units are believed to effectively eliminate those harmful frequency components of the harmful waves irradiated from the base units of the systems, including their transmission lines carrying the AC energies of high voltages. When desirable, the counter units of such systems may be arranged to emit the counter waves in an ultra low frequency range of less than about 2 kHz or about 3 kHz, in a very low frequency range of less than about 30 kHz, in a low range of less than about 300 kHz, and the like, to counter the harmful waves in the similar frequency ranges.

In another aspect of the present invention, various counter units may also be implemented into various prior art power grids and convert such into the EMC power grid systems in which the harmful waves irradiated by their base units may be countered by the counter waves.

In one exemplary embodiment of this aspect of the present invention, the counter units may be implemented into any base units shaped as electrically conductive wires, strips, sheets, tubes, coils, spirals, and/or meshes or, in the alternative, to any electrically semiconductive and/or insulative wires, strips, sheets, tubes, coils, spirals, and/or meshes for minimizing the irradiation of the harmful waves by countering such harmful waves by the counter waves, e.g., by canceling at least a portion of the harmful waves in the target space and/or suppressing the harmful waves from propagating to such a target space. Such counter units may be made of and/or include at least one material which may then be electrically conductive, insulative or semiconductive. The counter units may be implemented to any of the base units which have the shapes formed by one or multiple wires, strips, sheets, tubes, coils, spirals, and/or meshes, by modifying the shapes of one or multiple wires, strips, sheets, tubes, coils, spirals, and/or meshes, where a few examples of the modified shapes may be a solenoid and a toroid each formed by modifying the shape of the coil. In general, the counter units of this embodiment may be disposed in any of the foregoing arrangements and may counter the harmful waves by any of the foregoing mechanisms. Accordingly, a similarly or identically shaped and/or sized counter unit may be disposed lateral or side by side to one or more base units, may be axially, radially or angularly aligned with one or more base units, may enclose therein one or more base units, may be enclosed by one or more base units, may wind around one or more base units, may be wound by one or more base units, and the like, based on the source matching. In the alternative, a similarly or differently shaped and/or sized counter unit may be disposed along one or more wavefronts of the harmful waves irradiated by one or more base units for the wave matching. In addition, such counter units may be employed in a proper number and/or arrangement to counter the harmful waves according to the local countering or global countering.

In another exemplary embodiment of this aspect of the present invention, the counter units may also be implemented into any conventional electric and/or electronic elements such as, e.g., resistors, inductors, capacitors, diodes, transistors, amplifiers, fuses, triacs, and other signal processors and/or regulators in order to counter the harmful waves irradiated by the elements, where the electric and/or electronic elements function to manipulate at least one input signal supplied thereto and to produce at least one output signal at least partially different from the input signal. All of the above electric and/or electronic elements may qualify as the base units within the scope of the present invention when the unsteady current flows therein or when the unsteady voltage is applied thereacross. In addition, the above elements may also qualify as the base units within the scope of this invention when any of the elements produces the unsteady output signal (i.e., the electric current or voltage) in response to the input signal which may be steady or unsteady. Therefore, any of the above prior art elements and/or shaving devices including such elements may be converted to the EMC elements and/or EMC power grid systems by incorporating various counter units which define any of the above configurations in any of the above dispositions and/or arrangements, thereby countering such harmful waves in any of such mechanisms. It is appreciated that such counter units may be provided in any dimension so that the EMC elements may be provided in a range of microns, nanometers, and the like. It is appreciated that these EMC elements may be readily incorporated into various primary and secondary base units of the EMC power grid systems, excluding their transmission lines. Accordingly, the harmful waves irradiated by the power station, transmission substation, power substation, and transformers may be reduced to a satisfactory level.

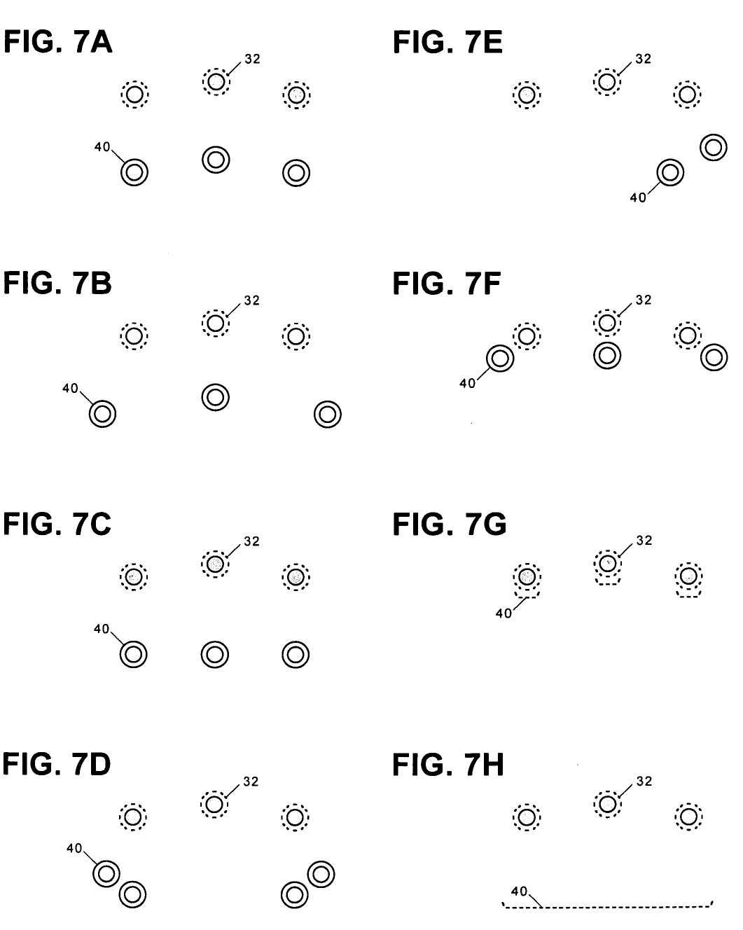

In another exemplary embodiment of this aspect of the invention, various counter units may be incorporated into the EMC power grid system for countering such harmful waves irradiated by various base units of the EMC system, where examples of the base units may include, but not be limited to, the power transmission lines carrying therethrough electric voltages of various ranges, transformers and other electric elements in its power stations, transmission substations, power substations, and so on. Such counter units may also be implemented into any conventional power grids and convert such into the EMC power grid systems. FIGS. 7A to 7H are schematic perspective views of exemplary counter units incorporated into various dispositions with respect to transmission lines according to the present invention. It is appreciated in all of these figures that three transmission lines of a single set of lines in the three-phase mode are included therein as the primary base units of the EMC power grid system. It is, therefore, appreciated that other conductive, semiconductive, and insulative parts of such an EMC power grid system irradiating the harmful waves are omitted therein but that, when necessary, such parts may be properly countered by resorting to any of the counter units as described heretofore and hereinafter.

In examples of FIGS. 7A to 7C, each EMC power grid system has three transmission lines 32 carrying three-phase AC energies therethrough, where such lines 32 serve as the primary base units irradiating the harmful waves therefrom. The EMC system includes the same number of counter units 40 disposed below (or above) the base units 32. More particularly, such counter units 40 are shaped and sized according to the source matching such that each counter unit 40 is shaped as an elongated conductive material and extends along each transmission line 32. In addition, the counter units 40 may also be disposed based upon the wave matching. In the example of FIG. 7A, the counter units 40 are provided in a disposition identical to that of such lines 32 and also at an uniform distance thereto. As described above, the counter units 40 may be supplied with the counter energies of which amplitudes depend upon the location of the target space in order to emit the counter waves of greater amplitudes when the target space is disposed on the opposite side of such base units 32 or, alternatively, to emit such counter waves of less amplitudes when the target space is defined thereunder. In the example of FIG. 7B, the counter units 40 define the configurations and are provided in the disposition which are similar to those of FIG. 7A, except that such counter units 40 are disposed away from each other in a greater distance. As described in conjunction with FIGS. 6A to 6L, the counter units 40 may be more effective in countering such harmful waves when the target space is defined thereunder. In another example of FIG. 7C, such counter units 40 define the configurations and are provided in the disposition which are also similar to those of FIG. 7A, except that such counter units 40 are disposed at the same level. It is appreciated that the counter units 40 may be provided in various dispositions depending on various factors which may include, but not be limited to, the configurations and/or dispositions of such base units, counter AC energies supplied thereto, and size and/or disposition of the target space.

In other examples of FIGS. 7D and 7E, each of such EMC power grid systems similarly includes three transmission lines identical to those of FIGS. 7A to 7C and multiple counter units countering such harmful waves in the source and/or wave matching. Such EMC systems, however, include different numbers of the counter unit. In the example of FIG. 7D, the system includes four counter units which are grouped into two sets one of which is disposed on a far right corner below the lines 32, whereas another of which is disposed on a far left corner therebelow. Similar to those of FIGS. 7A to 7C, the counter units 40 are in the disposition symmetric with respect to a vertical center line passing through the center base unit 32. It is appreciated that the counter units 40 of each set may be arranged in any disposition depending on various factors described above. In another example of FIG. 7E, the system includes multiple counter units 40 disposed in only one corner defined below the base units 32. Such an asymmetric disposition may be utilized when the target space is defined only in one corner of such base units 32, e.g., in the far right corner in which the counter waves emitted by the counter units 40 define the amplitudes less than those of the harmful waves, in the far left corner where such counter waves define the amplitudes greater than the harmful waves, and the like.

In another example of FIG. 7F, another EMC power grid system has therein three transmission lines identical to those of FIGS. 7A to 7E and three counter units 40 similar to those of FIG. 7C but each of which is disposed closer to or immediately below each base unit 32. Contrary to those of FIGS. 7A to 7D which typically operate in the global countering mechanism, these counter units 40 are disposed closer to the base units 32 and counter the harmful waves irradiated by each thereof according to the local countering mechanism.

In other examples of FIGS. 7G and 7H, each of such EMC power grid system similarly includes three transmission lines identical to those of FIGS. 7A to 7F as well as at least one counter unit which may define a configuration different from those of such base units 32 while being provided in various dispositions which may be identical to, similar to or different from those of the base units 32. It is to be understood that these counter units 40 may form various configurations defining the shapes such as, e.g., a strip, a sheet, a tube, a spiral of a single or multiple of such shapes, a coil of a single or multiple of such shapes, a mesh of a single or multiple of such shapes, an array of a single or multiple of such shapes, a combination of the above, and the like. For ease of illustration, however, the counter units of following figures may be regarded to define the shape of the mesh, although the counter units may define other shapes as well. In one example of FIG. 7G, three counter units 40 are disposed close to and immediately below the base units 30 in order to counter the harmful waves in the local countering mechanism. In another example of FIG. 7H, a single counter unit 40 is disposed at a distance in order to counter the harmful waves in the global countering mechanism. It is appreciated in both examples that such counter units 40 may emit the counter waves of various amplitudes which may depend on various factors described above. It is also appreciated in FIGS. 7A to 7H that the configurations and dispositions of all of such figures may be used interchangeably so that a preset configuration and/or disposition disclosed in conjunction with one figure may be applied to other EMC systems disclosed in the rest of such figures.

As manifest in FIGS. 7A to 7H, almost all counter units are shaped as the elongated articles. In this respect, all of such counter units may operate on the source matching. However, such counter units may be modified in order to operate on the wave matching or on a combined mode of both of the source matching and wave matching. By disposing such counter units in a proper position, alignment, and/or disposition, such counter units may counter such harmful waves based on the wave matching mechanism. Other details of the counter units operating in the local and global countering mechanisms have also been provided in the co-pending Application entitled “Generic Electromagnetically-Countered Systems and Methods,” filed on Aug. 28, 2006, and bearing the Serial Number, U.S. Ser. No. 11/510,667 as incorporated herein in its entirety by reference.

In addition, each of such counter units of FIGS. 7A to 7H is generally disposed to abut a single base unit, thereby operating in the local countering mechanism. Each of such counter units, however, may also be arranged to counter such harmful waves irradiated by multiple base units and operate in the global countering mechanism. Further details of various counter units which operate in the local as well as global countering mechanism have also been provided in the co-pending Application entitled “Generic Electromagnetically-Countered Systems and Methods,” filed on Aug. 28, 2006, and bearing the Serial Number, U.S. Ser. No. 11/510,667 which is also incorporated herein in its entirety by reference.

It is appreciated that any of the counter units described hereinabove may not be supplied with the electric energy and, therefore, may not actively emit the counter waves in response to the energy. Rather, the counter units may define the above configurations and may be in the above disposition so that the harmful waves irradiated by various base units may be absorbed into such counter units and converted to the electric voltage and/or current, thereby reducing the amount of such harmful waves propagating to the target space. Therefore, the EMC system may include one or multiple counter units all of which may serve as the passive counter units (i.e., those not receiving the electric energy), may include at least one passive counter unit and at least one active counter unit (i.e., one receiving such electric energy) or may include one or multiple counter units all of which serve as the active counter units. When desirable, at least one counter unit may also be arranged to serve as both of the active and passive counter units from time to time.

Various counter units may be used for any EMC power grid systems described heretofore and hereinafter and for any parts of such systems, where examples of such parts may include, but not be limited to, their transmission lines, transformers and/or other parts of the power station, transmission substation, power substation, and the like. Such counter units may be incorporated into the systems regardless of the levels of amplitudes of the AC energies carried along the systems, disposition and area of the target space, number of phases employed by the systems, and the like. In addition, such counter units may find better use when the system includes at least one unbalanced transmission line (i.e., unbalanced base unit), when the transmission lines of a given set may not exactly counter each other, when the system includes multiple sets of lines which may or may not be balanced, and the like.

As described above, the EMC power grid systems having any number of power transmission lines and employing any number of phase angles may be analyzed by constructing the equivalent lines for multiple base units thereof. Such equivalence analysis may be used to reduce the number of lines for easier analysis of the system and easier assessment of optimal self-countering mechanisms and dispositions. In the alternative, the equivalence analysis may be employed to increase the number of lines for conceptually providing additional lines for easier grouping of multiple lines to a preset number of sets of lines. Such an equivalence analysis allows easy quantitative analysis of multiphase power transmission, e.g., by reducing higher-phase lines into lower-phase lines (e.g., 6 to 2, 6 to 5 to 4 to 3 to 2, 6 to 4 to 2, 6 to 3 to 2, and the like) or by increasing lower-phase lines to higher-phase lines (e.g., 2 to 3 (i.e., 1+2), 2 to 4 (i.e., 1+3 or 2+2), and the like. The equivalent analysis may be applied not only to grouping multiple lines of different phase angles but also to grouping multiple lines of identical phase angles. Accordingly, when the system includes multiple lines at least two of which define the same phase angle, such lines may be grouped into an equivalent line of the same phase angle but defining different amplitudes. Similarly, when the system includes, e.g., two sets of three-phase power lines, each pair of lines of the same phase angle may be grouped into a single equivalent line, and resulting three equivalent lines may be analyzed for assessing the optimal self-countering mechanism.

In another aspect of the present invention, any of such EMC power grid systems may include at least one electric shield (to be abbreviated as the “ES” hereinafter), at least one magnetic shield (to be referred to as the “MS” hereinafter), and the like. In one example, the ES and/or MS may preferably be implemented into, on, over or below various portions of the EMC system. In another example, such ES and/or MS may be implemented as described above and used in conjunction with any of the above self-countering mechanisms and/or their dispositions or in conjunction with any of the above counter units. In general, the ES may be made of and/or include at least one electrically conductive material so that the electric waves of the harmful waves may be absorbed therein and then rerouted therealong. When desirable, the ES may also be grounded to eliminate the absorbed and rerouted electric waves therefrom. The MS may be made of and/or include at least one magnetically permeable path member which may be able to absorb the magnetic waves of the harmful waves thereinto and then to reroute such magnetic waves therealong. When desirable, the MS may include a magnet member which may be magnetically coupled to the path member and terminate the absorbed and rerouted magnetic waves in at least one magnetic pole of the magnet member. The MS may include at least one optional shunt member which may also be magnetically permeable and shield its magnet member, thereby confining magnetic fields from the magnet member closer thereto. Other details of the ES and MS have already been provided in the co-pending Applications such as, e.g., “Shunted Magnet Systems and Methods” which bears a Ser. No. 11/213,703, “Magnet-Shunted Systems and Methods” which also bears a Ser. No. 11/213,686, and “Electromagnetic Shield Systems and Methods” which bears a Serial Number U.S. Ser. No. 60/723,274. It is appreciated that the details of these co-pending Applications may be modified so that the heating elements of such co-pending Applications may be replaced by various counter units of the present invention and that the ES and/or MS may be incorporated to the counter units of this invention as such ES and/or MS have been incorporated into various heating elements of the above co-pending Applications. It is appreciated that the ES and/or MS may also be incorporated into various portions of the EMC systems of this invention as the counter units are incorporated into such portions of the EMC systems of this invention.

The ES and/or MS may be provided to define the configuration which is identical to or similar to those of various counter units of this invention. The ES and/or MS may also be disposed in, on, over, around, and/or through the base and/or counter units. The ES and/or MS may have the configuration at least partially conforming to that of such base and/or counter units or, in the alternative, may define the configuration at least partially different from those of the ES and/or MS.

The path member of the MS may define the relative magnetic permeability greater than 1,000 or 10,000, 100,000 or 1,000,000. The shunt member may be arranged to directly or indirectly contact the magnet member and to define a relative magnetic permeability greater than 1,000, 10,000, 100,000 or 1,000,000. The ES and/or MS described hereinabove or disclosed in the co-pending Applications may further be incorporated into any of the prior art devices with or without any of the above counter units and define such EMC systems of this invention. The ES and/or MS may define the configuration which may be maintained to be uniform along the longitudinal or short axis of the base and/or counter units or which may vary therealong. Such configurations of the ES and/or MS may be identical to, similar to or different from those of the base and/or counters. The EMC shaving system may have therein multiple ES and/or MS, where at least two of the MS and/or ES may shield against the magnetic waves and/or electric waves defining the same or different frequencies in same or different extents. The ES and/or MS may be disposed over at least a portion (or entire portion) of the base and/or counter units. The EMC system may also include one or more of any of such counter units and ES and/or MS, where the base units operate on AC, while the counter units may operate on AC or DC.

As described above, such EMC power grid systems of the present invention may be provided with multiple defense mechanisms against the harmful waves irradiated by various base units of such systems. In one example, at least one of the base units may be utilized as the counter unit for the rest of the base units through the self-countering mechanisms and their dispositions. In another example, the counter unit may be incorporated into various portions of such EMC systems as described above. Therefore, a single or multiple counter units may be provided in any of such configurations and/or may be incorporated into any of the above dispositions. In another example, the electric shield (ES) and/or magnetic shield (MS) may be incorporated into various portions of the EMC systems and shield against the electric and/or magnetic waves of the harmful waves, respectively, where dispositions of the ES and/or MS have been described in the above co-pending Applications. In another example, not only the counter units but also at least one of the ES and/or MS may be implemented into the EMC systems so that the counter unit may counter at least a portion of such harmful waves and that the ES and/or MS may absorb and reroute the rest thereof.

It is to be understood that any of the above self-countering mechanisms and their dispositions and counter units therefor are provided while using the least amount of such electrically conductive, semiconductive, and/or insulative materials, while minimizing a volume, a size, and/or a mass of such counter units. Accordingly, such counter units may be fabricated with less materials at lower costs and may be easily implemented into various locations of the EMC power grid system. In this respect, using at least one of the transmission lines as the counter unit for the rest of the lines is beneficial for not incorporating any additional parts into the system. It is further appreciated that any of the counter units are provided to emit the counter waves while using the least amount of the AC energy, e.g., by drawing the least amount of the electric current or voltage.

Unless otherwise specified, various features of one embodiment of one aspect of the present invention may apply interchangeably to other embodiments of the same aspect of this invention and/or embodiments of one or more of other aspects of this invention. Therefore, any of the self-countering mechanisms and dispositions for the single set of power transmission lines of FIGS. 2A to 2H may be implemented to any number of sets of such lines of the EMC power grid systems. Similarly, such self-countering mechanisms and dispositions of at least two sets of power transmission lines of FIGS. 3A to 3Q, FIGS. 4A to 4P, and FIGS. 5A to 5G may also be implemented into any EMC power grid systems with three or more sets of power transmission lines, where each set of lines may employ the same or different number of phase angles, where each set of lines may carry the AC energies of the same or different voltages or currents, and the like. In addition, any transmission lines used as the counter unit for the other lines may be used as the base unit, while one or more of the rest of such lines may then be used as the counter unit. Moreover, any self-countering mechanisms and dispositions based upon the source matching may then be converted to operate on the wave matching or vice versa, where the source-matched counter units may be disposed along (or across) one or more wavefronts of the harmful waves irradiated by at least one of the base units or where the wave-matched counter units may similarly be disposed in the preset relation to at least one of the base units or may be disposed in the arrangement similar to that of at least one of the base units. In addition, any of the electric and/or magnetic shields which have been disclosed hereinabove and also described in the above co-pending Applications may be incorporated into any of the above base units and/or counter units.

Although the above figures and descriptions focus upon various self-countering mechanisms and their dispositions for high-voltage power transmission lines, such mechanisms and dispositions may be applied mid- and low-voltage power transmission lines along the EMC power grid system and lower-voltage lines along various power lines installed for individual households, industrial complexes, and the like.

It is to be understood that, while various aspects and/or embodiments of the present invention have been described in conjunction with the detailed description thereof, the foregoing description is intended to illustrate and not to limit the scope of the invention, which is defined by the scope of the appended claims. Other embodiments, aspects, advantages, and modifications are within the scope of the following claims as well.

What is claimed is:

1. An electromagnetically-countered power grid system which is configured to include a preset number of a plurality of wave sources each having therein at least one base unit and to be capable of countering harmful electromagnetic waves irradiated from said base units by at least one of canceling said harmful waves in a target space and suppressing said harmful waves from propagating toward said target space, wherein said base units are configured to include only those portions of said wave sources which are responsible for at least one of irradiating said harmful waves and affecting paths of propagation of said harmful waves therealong, wherein said target space is defined between said base units and an user of said system, and wherein said system includes at least one power station capable of generating electrical energies each of which defines preset amplitudes and each of which defines phase angles differing from phase angles of at least one of the rest of said energies by about a preset angle obtained by dividing 360° by said preset number comprising:
said preset number of power transmission lines each of which is configured to carry each of said energies therealong while serving as one of said wave source with said base unit and irradiating said harmful waves thereby, and to extend at least substantially parallel to the rest of said lines in said target space,
wherein said lines are configured to be in a disposition at least partially opposite to each other when viewed upon a hypothetical plane defined perpendicular thereto and to maintain said disposition in said target space, whereby said harmful waves irradiated from each of said lines are configured to define phase angles at least substantially opposite to those of a sum of said harmful waves irradiated by the rest of said lines, to define amplitudes at least substantially similar to those of said sum of said harmful waves and, accordingly, to counter said harmful waves irradiated from the rest of said lines in said target space.

2. The system of claim 1, wherein said lines are configured to be spaced apart from each other by at least substantially similar distances in said disposition when viewed upon said plane.

3. The system of claim 1, wherein said lines are configured to be spaced apart from each other by at least substantially similar angles about a center of a circle defined by all of said lines upon said plane in said disposition.

4. The system of claim 1, wherein said lines are configured to define a plurality of peak planes on which said harmful waves have maximum amplitudes and wherein said peak planes are configured to be in an alignment capable of aligning said peak planes in said target space as far away therefrom in said disposition.

5. The system of claim 1, wherein said lines are configured to define a plurality of peak planes on which said harmful waves have maximum amplitudes and wherein said peak planes are configured to be disposed as evenly as possible in said target space in said disposition.

6. The system of claim 1, wherein said number of said lines is only one of two, three, four, five, and six, wherein said angle is 180° when said number is two, wherein said angle is 120° when said number is three, wherein said angle is 90° when said number is four, wherein said angle is 72° when said number is five, and wherein said angle is 60° when said number is six.

7. The system of claim 1 further comprising at least one retainer which is configured to be placed along said lines and to maintain said lines in said disposition.

8. The system of claim 1, wherein said lines are configured to be grouped into at least two sets, wherein said lines of one of said sets are configured to carry said electrical energies of first electric voltages, and wherein said lines of another of said sets are then configured to transmit said electrical energies of second electric voltages which are different from said first electric voltages.

9. An electromagnetically-countered power grid system which is configured to include therein at least three wave sources each having therein at least one base unit and to be capable of countering harmful electromagnetic waves irradiated by said base units by at least one of canceling said harmful waves in a target space and suppressing said harmful waves from propagating to said target space, wherein said base units are configured to include only portions of said wave sources responsible for at least one of irradiating said harmful waves and affecting propagation paths of said harmful waves therealong, wherein said target space is formed between said base units and an user of said system, and wherein said system includes at least one power station capable of generating electrical energies each having preset amplitudes and each also defining phase angles differing from phase angles of at least one of the rest of said energies by about 120° comprising:
at least three power transmission lines each of which is configured to carry therealong each of said energies while serving as one of said wave source having said base unit and while irradiating said harmful waves thereby, and to extend at least substantially parallel to the rest of said lines in said target space,
wherein said lines are configured to be in an equilateral triangular disposition when viewed on a hypothetical plane which is defined perpendicular to all of said lines and to maintain said disposition in said target space, whereby said harmful waves irradiated from each of said lines are configured to define phase angles at least substantially opposite to those of a sum of said harmful waves irradiated by the rest of said lines, to define amplitudes at least substantially similar to those of said sum of said harmful waves and, accordingly, to counter said harmful waves irradiated from the rest of said lines in said target space.

10. The system of claim 9, wherein said lines are configured to be spaced apart from each other by at least substantially similar distances in said disposition when viewed upon said plane.

11. The system of claim 9, wherein said lines are configured to be spaced apart from each other by about 60° about a center of a circle defined by all of said lines upon said plane in said disposition.

12. The system of claim 9, wherein said lines are configured to define a plurality of peak planes on which said harmful waves have maximum amplitudes and wherein said peak planes are configured to be in an alignment capable of aligning said peak planes in said target space as far away therefrom in said disposition.

13. The system of claim 9, wherein said lines are configured to define a plurality of peak planes on which said harmful waves have maximum amplitudes and wherein said peak planes are configured to be disposed as evenly as possible in said target space in said disposition.

14. The system of claim 9 further comprising at least one retainer which is configured to be placed along said lines and to maintain said lines in said disposition.

15. The system of claim 9, wherein said lines are configured to be grouped into at least two sets, wherein each of said sets of said lines is configured to have at least three of said lines, wherein said lines of one of said sets are configured to carry said electrical energies of first electric voltages, and wherein said lines of another of said sets are configured to carry said electrical energies of second electric voltages which are different from said first electric voltages.

16. An electromagnetically-countered power grid system which is configured to include therein a preset number of a plurality of wave sources each including at least one base unit irradiating harmful electromagnetic waves, to include therein at least one counter unit emitting counter electromagnetic waves, and to be capable of countering said harmful waves with said counter waves by at least one of suppressing said harmful waves with said counter waves from propagating toward a target space and canceling said harmful waves with said counter waves in said target space, wherein said base units are configured to include only those portions of said wave sources which are responsible for at least one of irradiating said harmful waves and affecting paths of propagation of said harmful waves therealong, wherein said target space is defined between an user of said system and base units, and wherein said system also includes at least one power station for generating electrical energies each of which has preset amplitudes and each of which defines phase angles differing from phase angles of at least one of the rest of said electrical energies by about a preset angle obtained by dividing 360° by said preset number comprising:
at least one transmission line which is configured to transmit therealong one of said electrical energies while serving as one of said wave sources with said base unit and irradiating said harmful waves therefrom; and
at least one counter unit which is configured to transmit therealong another of said electrical energies while emitting said counter waves therefrom,
wherein a total number of said transmission line and counter unit corresponds to said preset number, wherein said transmission line and counter unit are configured to extend at least substantially parallel to each other in said target space, and wherein said counter unit is also configured to define a configuration identical (or similar) to said base unit of said transmission line,
whereby said counter waves are configured to define phase angles at least partially opposite to those of said harmful waves irradiated from said base unit, to define wave characteristics at least partially similar to those of said harmful waves irradiated from said base unit due to said configuration and, accordingly, to counter said harmful waves irradiated by said base unit due to said phase angles in said target space.

17. The system of claim 16, wherein said system includes a plurality of said transmission lines and said counter unit, wherein each of said transmission lines is configured to carry therealong each of said energies while serving as one of said wave sources including said base unit and irradiating said harmful waves therefrom, whereby said counter waves are configured to have phase angles which are at least partially opposite to those of said harmful waves irradiated from at least one of said base units, to have wave characteristics at least partially similar to those of said harmful waves which are irradiated by said at least one of said base units due to said configuration and, accordingly, to counter said harmful waves irradiated by said at least one of said base units due to said phase angles in said target space.

18. The system of claim 16, wherein said system includes said transmission line and a plurality of said counter units each of which is configured to transmit therealong each of said electrical energies while emitting said counter waves therefrom, whereby said counter waves emitted from at least one of said counter units are configured to define phase angles at least partially opposite to those of said harmful waves irradiated by said base unit, to define wave characteristics at least partially similar to those of said harmful waves irradiated by said base unit due to said configuration and, accordingly, to counter said harmful waves which are irradiated from said base unit due to said phase angles in said target space.

19. The system of claim 16, wherein said system includes a plurality of said transmission lines and a plurality of said counter units, wherein each of said transmission lines is configured to transmit each of said electrical energies therealong while serving as one of said wave sources including said base unit and irradiating said harmful waves thereby, and wherein each of said counter units is configured to transmit therealong another of said electrical energies while emitting said counter waves therefrom, whereby said counter waves emitted from at least one of said counter units are configured to define phase angles at least partially opposite to those of said harmful waves irradiated from at least one of said base units, to define wave characteristics at least partially similar to those of said harmful waves irradiated by said at least one of said base units due to said configuration and, accordingly, to counter said harmful waves which are irradiated from said at least one of said base units due to said phase angles in said target space.

20. The system of claim 16, wherein said lines are configured to form a plurality of peak planes on which said harmful waves have maximum amplitudes and wherein said peak planes are configured to be in one of a first alignment and a second alignment, wherein said peak planes are configured to be aligned in said target space as far away therefrom based upon said first alignment, and wherein said peak planes are configured to be aligned as evenly as possible in said target space in said second alignment.
